(19) United States
(12) Patent Application Publication
(10) Pub. No.: US 2010/0169030 A1
(43) Pub. Date: Jul. 1, 2010

(54) MACHINE CONDITION ASSESSMENT THROUGH POWER DISTRIBUTION NETWORKS

(76) Inventor: Alexander George Parlos, College Station, TX (US)

Correspondence Address: ANTHONY ENGLAND, LAW OFFICE OF ANTHONY ENGLAND, P.O. BOX 5307, AUSTIN, TX, 78763, US

(21) Appl. No.: 12/601,262

(22) PCT Filed: May 24, 2008
(86) PCT No.: PCT/US08/64810

§ 371 Date: Nov. 22, 2009

Related U.S. Application Data
(60) Provisional application No. 60/931,616, filed on May 24, 2007.

(51) Int. Cl. G01R 31/34

(52) U.S. Cl. 702/58

(57) ABSTRACT

A device, which is preferably embedded in a power distribution enclosure, enables analysis of conditions of electromechanical machines and, alternatively, also their driven or driver devices. The analysis uses operating voltages and currents supplied to or from the electromechanical machines. Since these voltages and currents are available at the enclosure, wiring or any other communication means to any sensors on the electromechanical machines or on the driver or driven devices are not necessary. The embedded device may optionally transmit its results to a computing or monitoring device remote from the enclosure, preferably wirelessly. The embedded device may receive all its power from an existing, conventional potential transformer in the enclosure, so that the embedded device may be retrofitted to the enclosure without the addition of any wiring external to the enclosure.

### CROSS REFERENCE TO RELATED APPLICATIONS

The present application is related to, claims the benefit of priority of, and hereby incorporates herein by reference, U.S. Patent Application No. 60/931,616, filed May 24, 2007. The present application also hereby incorporates herein by reference U.S. Pat. No. 6,590,362, issued Jul. 8, 2003; U.S. Pat. No. 6,713,978, issued Mar. 30, 2004; and U.S. Pat. No. 7,024,335, issued Apr. 4, 2006.

### FIELD OF THE INVENTION

The present invention relates, in general, to early assessment of operating conditions in electric motors and generators and, optionally, their connected, mechanical, driven or driving devices; and, in particular, to the use of operating voltages and currents supplied to or from such electromechanical machines for the assessment.

### BACKGROUND AND DESCRIPTION OF INVENTION

Previously known methods for detecting machine faults make use of detailed machine models or design parameters that are typically not available to others except the machine designer. Furthermore, the available prior art systems use speed sensors, accelerometers and/or other sensors for detecting mechanical failures. For the detection of faults in multiple machines, existing approaches detect early faults primarily via the use of speed or vibration sensors at each machine, which may be cabled via instrumentation wiring in raceway to a central analysis device. Even with regard to methods that include the use of operating electrical voltage and current measurements, these methods are dependent upon individual measurements obtained at each machine's terminals, even if the same bus supplies all the machines.

It is known to use hand-held instruments with additional sensors such as speed, vibration, temperature, as well as portable potential transformers (PT's) and current transformers (CT's) at the electromechanical machines. Furthermore, these available hand-held systems generally do not have extensive on-board computing capabilities for performing all the monitoring and diagnostics functions locally prior to transmitting the equipment condition or health information. Separate desktop analysis software is needed along with human interpretation to perform the machine health diagnosis.

The present invention involves a recognition that measurement transformers, including PT's and CT's, are conventionally included in switchgear that feeds most industrial electrical equipment, including electromechanical machines, and that it is possible to provide fault diagnosis of rotating machines supplied through the same power distribution network (voltage bus), using only the electromechanical machine electrical characteristics (voltage and current) measured via the PT's and CT's at the switchgear bus.

An embodiment of the present invention advantageously measures current and voltage at the switchgear bus, either via existing PT's and CT's or by adding them at the switchgear, and provides software or hardware responsive to the measured bus current and voltage that functions according to algorithms disclosed in related applications and herein for early automatic detection of rotating electromechanical machine faults and otherwise automatically assessing the electromechanical equipment condition without the use of a speed sensor, such as a tachometer, or vibration sensors, such as accelerometers. That is, in an embodiment of the invention, voltages and currents for the electromechanical machines are the only measured, time-series data received by the software or hardware of the present device, i.e., data that is captured in real-time operation of machines.

The present invention also involves a recognition that a group of electromechanical machines are conventionally supplied through the same power distribution network (voltage bus) and that not only the individual currents and voltages for the electromechanical machines may be conveniently measured at respective switchgear breakers for fault diagnosis of the respective machines, but that fault diagnosis may be enabled according to the present invention via mere time series measurement of aggregate currents and voltages of the machines, as measured on their common bus. Accordingly, in another aspect of an embodiment of the invention, the present device provides fault diagnosis of a group of rotating machines supplied through the same power distribution network (voltage bus), using only the electromechanical machine electrical characteristics (voltage and current) measured at the switchgear bus, instead of at the individual machines or at the individual load terminals to the respective machines. The measurements at the switchgear bus are by the above-mentioned existing or added PT's and CT's and may also be by transducers coupled to the PT and CT secondaries. That is, in an embodiment of the invention, the only measured, time-series data received by the software is aggregate voltage and current for the group of machines, i.e., measurements at the voltage bus level instead of at the individual machine terminals or individual switchgear breaker load terminals. (In addition to the time-series data, for an embodiment of the invention the software is also initialized with static data that includes so-called “nameplate” machine information for each machine, such as operating voltage, full load rated horsepower and current, locked rotor current, etc.)

It should also be understood that even if only one electromechanical machine on the switchgear bus is running, it is inevitable that there will be other active loads too, albeit loads of non-machines or else at least loads not for machines that are monitored by the embedded fault detection device. So the measured bus current is still an aggregate of the current for the one running and monitored electromechanical machine on the switchgear bus and currents for other loads on the bus. Thus, it should be understood that the present invention is applicable even for a single electromechanical machine and its corresponding mechanical driver and driven device.

Bus level voltage time series and bus level aggregate current time series can be used to assess the individual conditions of a group of electromechanical machines energized by a common voltage bus, and also assess the mechanical machines they drive in the form of mechanical loads (where the electromechanical machines include motors) or that drive them in the form of prime movers (where the electromechanical machines include generators). The disaggregation of the current time series, and the detection and localization of individual faulty electromechanical and mechanical machine characteristics can be accomplished by various algorithmic approaches available in the literature and used for such purposes. For example, the method of blind source separation could be used for this signature disaggregation and fault detection problem. See, for example, i) Lee, T.-W., Lewicki, M. S., Girolami, M., and Sejnowski, T. J., (1999) “Blind Source Separation of More Sources Than Mixtures Using Overcomplete Representations,” IEEE Signal Processing Letters, Vol. 6, No. 4, pp. 87-90; and ii) Choi, S., Cichocki, A., Park, H.-M, and Lee, S.-L., (2005) “Blind Source Separation and Independent Component Analysis: A Review,” Neural Information Processing—Letters and Reviews, Vol. 6, No. 1, pp. 23-42, both of which are hereby incorporated herein by reference.

The condition of an electromechanical device and other pertinent information that are automatically determined by the software or hardware of the present invention may be communicated through a wireless interface to other embedded or desktop computing devices or directly to qualified personnel tasked with the maintenance and operations of machines. In other words, one embodiment of the present invention includes a computing and communication hardware platform enabled by software and hardware to provide a “sensorless” fault diagnosis device, i.e., completely eliminating the need for cabling, i.e., wiring in raceway, from one electromechanical machine or electrical enclosure to another for electromechanical machine sensors.

From the foregoing, it should be appreciated that an embedded device is described herein, i.e., a device for analyzing conditions of electromechanical machines and their driven or driver devices and that may be embedded in switchgear. It is particularly notable that in an embodiment of the invention, the embedded device not only detects the conditions of electromechanical machines and alternatively also their driven or driver devices located remotely from the switchgear without wiring or any other communication means to any sensors on the electromechanical machines or their driven or driver devices external to the switchgear, and not only wirelessly transmits its analysis results to a remote device, such as a remote device for presenting a report about the results to a user, but, in addition, receives all its power from existing, conventional by PT's in the switchgear, so that the embedded device may be retrofitted to the switchgear without the addition of any external wiring whatsoever for the embedded device, i.e., without the addition of any wiring external to the switchgear.

In other embodiments of the invention, the embedded device does not perform the ultimate detection of the conditions of electromechanical machines and alternatively also their driven or driver devices. Instead, the embedded device performs signal processing and transmits the processed signals, preferably wirelessly, to a remote computing system. In these embodiments of the invention, the remote computing system detects the conditions, or at least contributes to the detecting along with the embedded device.

All analog and digital circuitry of this device may be housed on a single printed circuit board (PCB). An on board processor provides capability to perform functions needed for monitoring and diagnosis of machine condition, allowing remote monitoring, diagnosis and prognosis, and transmission of machine condition information. This diagnosis device may include a wireless interface for the information transmission, completely eliminating the need for cabling on the sensor side and two-way communication of information between the device and other similar or dissimilar devices.

There are alternate embodiments for the current invention, depending on the interface available at the power input of the electrical machines. The disclosed device can be interface with any combination of 1-phase, 3-phase or other multi-phase motors and/or generators. As previously mentioned, measurement transformers, including PT's and CT's, are conventionally supplied. The primary connections of these measurement transformers are conventionally coupled to the relatively high voltage switchgear bus that supplies the electromechanical machines. The secondary connections are available in a low voltage portion of the switchgear enclosure for connection to monitoring devices, protective relaying, etc. In the event that PTs and CTs are not available for the bus (in the aggregate voltage and current measurement embodiment of the invention) or for the individual electromechanical machine breakers (for the individual machine voltage and current measurement embodiment of the invention), an appropriate number of current and voltage transducers (1-voltage and 1-current for 1-phase system, 2-voltage and 3-current for 3-phase system) can be incorporated within the present device for use in isolating it from the power lines and for monitoring the electrical voltages and currents. Additional embodiments of this invention, including its embodiment at a centralized location for health management of a large number of electrical and mechanical equipment from a single embedded device installation, are described herein.

In one aspect of the invention, mechanical conditions are detected for electromechanical machines and mechanical devices that drivers for or are driven by those machines. This includes supplying electrical power, including voltage and current, from a bus enclosed in a switchgear enclosure to a group of electromechanical machines remote from the switchgear enclosure. Each electromechanical machine is coupled to a respective mechanical device and the mechanical device drives or is driven by its electromechanical machine. During operation of the group of electromechanical machines, a time series of voltage and aggregated current is measured at the switchgear bus for the group of electromechanical machines. A device mounted at the switchgear enclosure, i.e., an “embedded device” receives the measured time series of voltage and aggregated current. Logic of the device embedded at the switchgear detects whether each respective electro-mechanical machine and corresponding driving or driven mechanical device has a mechanical condition, including a predetermined speed and vibration pattern, wherein the detecting is responsive to the received bus voltage and aggregated current time series measurements, but the detecting is not responsive to time series measurements of operating speed and vibration for the electromechanical machines and their corresponding driving or driven mechanical devices. Alternatively, the embedded device performs signal processing for the received measurements and transmits the processed signals, preferably wirelessly, to a remote computing system. In this embodiment of the invention, the remote computing system detects the conditions, or at least contributes to the detecting along with the embedded device.

In another aspect, one or more signals is sent by the embedded device indicating whether the mechanical conditions are detected for each of the electromechanical machines for presenting to a user or saving in a storage device. In an alternative, a signal is presented to a user by the device, indicating whether the mechanical conditions are detected for each of the electromechanical machines. In another alternative, an indication of whether the mechanical conditions are detected for each of the electromechanical machines is stored responsive to receiving the one or more signals sent by the device.

One form of the invention includes supplying electrical power, including voltage and current, from a bus enclosed in a switchgear enclosure to a group of electromechanical machines remote from the switchgear enclosure, wherein each electromechanical machine is coupled to a respective mechanical device and the mechanical device drives or is driven by its electromechanical machine. During operation of the group of electromechanical machines, a time series of voltage and aggregated current is measured at the switchgear bus for the group of electromechanical machines. The measured, time series of voltage and aggregated current is received by an “embedded” device, i.e., a device mounted at the switchgear enclosure. Logic of the embedded device at the switchgear detects whether each respective electro-mechanical machine and corresponding driving or driven mechanical device has an anomalous or faulty mechanical or electrical condition. The condition includes predetermined or learned fault signature patterns and is in response to the received bus voltage and aggregate current time series measurements. But the detection is not responsive to individual load current time series measurements for the respective electro-mechanical machines and not responsive to any other series measurements besides the received bus voltage and aggregate current time series measurements. Alternatively, the embedded device performs signal processing for the received measurements and transmits the processed signals, preferably wirelessly, to a remote computing system. In this embodiment of the invention, the remote computing system detects the conditions, or at least contributes to the detecting along with the embedded device.

One form of the invention includes supplying electrical power, including voltage and current, from a bus enclosed in a switchgear enclosure to a group of electromechanical machines remote from the switchgear enclosure and measuring, during operation of the group of electromechanical machines, a time series of voltage and aggregated current at the switchgear bus for the group of electromechanical machines. The measured time series of voltage and aggregated current is received by an “embedded” device, i.e., a device mounted at the switchgear enclosure. Logic of the embedded detects whether each respective electro-mechanical machine has an anomalous or faulty mechanical or electrical condition, wherein the condition includes predetermined or learned fault signature patterns. The detection is in response to the received bus voltage and aggregate current time series measurements, but the detection is not responsive to individual load current time series measurements for the respective electro-mechanical machines and not responsive to any other time series measurements besides the received bus voltage and aggregate current time series measurements. Alternatively, the embedded device performs signal processing for the received measurements and transmits the processed signals, preferably wirelessly, to a remote computing system. In this embodiment of the invention, the remote computing system detects the conditions, or at least contributes to the detecting along with the embedded device.

One form of the invention includes supplying electrical power, including voltage and current, from a bus enclosed in a switchgear enclosure to a single monitored electromechanical machine and also to other loads, which may include no monitored machines. At least the monitored electromechanical machine is remote from the switchgear enclosure. During operation of the monitored electromechanical machine, respective time series of voltage and aggregated current are measured are measured at the switchgear bus for the electromechanical machine and the other loads. The measured, time series of voltage and aggregated current are received by an “embedded” device, i.e., a device mounted at the switchgear enclosure. Logic of the embedded device detects whether the electromechanical machine has an anomalous or faulty mechanical or electrical condition, wherein the condition includes a predetermined or learned fault signature pattern, wherein the detection is in response to the received bus voltage and aggregate current time series measurements. Alternatively, the embedded device performs signal processing for the received measurements and transmits the processed signals, preferably wirelessly, to a remote computing system. In this embodiment of the invention, the remote computing system detects the conditions, or at least contributes to the detecting along with the embedded device.

One form of the invention includes supplying electrical power, including voltage and current, from a bus enclosed in a switchgear enclosure to a single monitored electromechanical machine and also to other loads, which may include no monitored machines. The monitored electromechanical machine is coupled to a mechanical device and the mechanical device drives or is driven by its electromechanical machine. The monitored electromechanical machine is remote from the switchgear enclosure. During operation of the monitored electromechanical machine, a time series of a voltage, which may be the bus voltage or a voltage nearer to conductors at the switchgear that feed the individual monitored machine, is measured at the switchgear for the electromechanical machine. Also, a time series of the individual load current for the monitored machine is measured at the switchgear. The measured, time series of voltage and load current are received by an “embedded” device, i.e., a device mounted at the switchgear enclosure. Logic of the embedded device detects whether the electromechanical machine and its coupled mechanical device have an anomalous or faulty mechanical or electrical condition, wherein the condition includes a predetermined or learned fault signature pattern, wherein the detection is in response to the received voltage and load current time series measurements. Alternatively, the embedded device performs signal processing for the received measurements and transmits the processed signals, preferably wirelessly, to a remote computing system. In this embodiment of the invention, the remote computing system detects the conditions, or at least contributes to the detecting along with the embedded device.

Additional features and advantages are realized through the techniques of the present invention. Other embodiments and aspects of the invention are described in detail herein and are considered a part of the claimed invention. For a better understanding of the invention with advantages and features, refer to the drawings listed below and their accompanying description.

### BRIEF DESCRIPTION OF FIGURES

The subject matter regarded as the invention is particularly pointed out and distinctly claimed in the claims at the conclusion of the specification. The foregoing and other objects, features, and advantages of the invention are apparent from the description herein taken in conjunction with the accompanying drawings, in which:

FIG. 1 illustrates an embedded device block diagram, according to an embodiment of the invention.

FIG. 2 illustrates metal box casing for an embedded device showing control panel mounting and wiring exit locations, according to an embodiment of the invention.

FIG. 3A illustrates a back view for a metal box casing for an embedded device showing control panel mounting and wiring exit locations, according to an embodiment of the invention.

FIG. 3B illustrates a computer system suitable for including in the embedded device or for a remote device for receiving data from the embedded device, according to an embodiment of the invention.

FIG. 4 illustrates front and side views of metal box casing for an embedded device, according to an embodiment of the invention.

FIG. 5 illustrates a back view of a metal enclosure for an embedded device showing printed circuit board locations, according to an embodiment of the invention.

FIG. 6 illustrates a front, back and side view of the embedded device control panel, according to embodiment of the invention.

FIG. 7 illustrates embedded device control mounting on electrical equipment switchgear, according to an embodiment of the invention.

FIG. 8 illustrates an embedded device circuit diagram for open-delta 3-phase potential transformer (PT) connections, according to an embodiment of the invention.

FIG. 9 illustrates an embedded device circuit diagram for Y-neutral 3-phase PT connections, according to an embodiment of the invention.

FIG. 10 illustrates an embedded device circuit diagram with 1-phase PT and current transformer (CT) connections, according to an embodiment of the invention.

FIG. 11 illustrates an embedded device for single-phase equipment configuration with no current or voltage transformers, according to an embodiment of the invention.

FIG. 12 illustrates an embedded device installation on distribution transformer switchgear and formation of wireless sensorless monitoring network, according to an embodiment of the invention.

FIG. 13 illustrates architecture of a wireless network of sensorless embedded devices, according to an embodiment of the invention.

FIG. 14 illustrates system architecture having an 802.11b/g WLAN wireless network of sensorless embedded devices, according to an embodiment of the invention.

FIG. 15 illustrates another view of system architecture having an 802.11b/g WLAN wireless network of sensorless embedded devices, according to an embodiment of the invention.

FIG. 16 illustrates system architecture having an 802.11b WLAN wireless network of sensorless bedded devices, according to an embodiment of the invention.

FIG. 17 illustrates fault detection scenarios, according to an embodiment of the invention.

FIG. 18 illustrates a signal-based fault detection method, according to an embodiment of the invention.

FIG. 19 illustrates a model-based fault detection framework, according to an embodiment of the invention.

FIG. 20 illustrates a generalized system for pump fault detection, according to an embodiment of the invention.

FIG. 21 illustrates a proposed model-based fault detection method, according to an embodiment of the invention.

FIG. 22 illustrates a histogram of model prediction error at 20% of rated load level, according to an embodiment of the invention.

FIG. 23 illustrates a histogram model of prediction error at 40% of rated load level, according to an embodiment of the invention.

FIG. 24 illustrates an overall schematic of a proposed fault detection and isolation method, according to an embodiment of the invention.

FIG. 25 illustrates an induction motor modulator model, according to an embodiment of the invention.

FIG. 26 illustrates modulation frequency detection using bispectrum, according to an embodiment of the invention.

FIG. 27 illustrates modulation frequency detection using the modified bispectrum or the amplitude modulation detector, according to an embodiment of the invention.

FIG. 28 illustrates ball bearing dimension, according to an embodiment of the invention.

FIG. 29(a) illustrates an incorrect detection of amplitude modulation relationship using bispectrum, according to an embodiment of the invention.

FIG. 29(b) illustrates a correct detection of amplitude modulation relationship using the AMD, according to an embodiment of the invention.

FIG. 30 illustrates a voltage spectrum comparison, according to an embodiment of the invention.

FIG. 31 illustrates a current spectrum comparison, according to an embodiment of the invention.

FIG. 32 illustrates a VSI controlled induction motor drive, according to an embodiment of the invention.

FIG. 33 illustrates voltage PWM waveforms, according to an embodiment of the invention.

FIG. 34 illustrates voltage versus frequency under the constant V/Hz principle, according to an embodiment of the invention.

FIG. 35 illustrates an open-loop constant V/Hz controller, according to an embodiment of the invention.

FIG. 36 illustrates a closed-loop constant V/Hz controller, according to an embodiment of the invention.

FIG. 37 top illustrates a VSI driven voltage spectrum, according to an embodiment of the invention.

FIG. 37 bottom illustrates a narrow frequency band of the voltage spectrum, according to an embodiment of the invention.

FIG. 38 top illustrates a VSI driven current spectrum, according to an embodiment of the invention.

FIG. 38 bottom illustrates a narrow frequency band of the current spectrum, according to an embodiment of the invention.

FIG. 39 top illustrates the induction motor modulator model, according to an embodiment of the invention.

FIG. 39 bottom illustrates a narrow frequency band of the voltage spectrum, according to an embodiment of the invention.

Element numbers in the following refer to elements that are, if shown in more than one figures, numbered the same in the various figures.

Headers herein are not intended to limit the invention.

Device Functionality

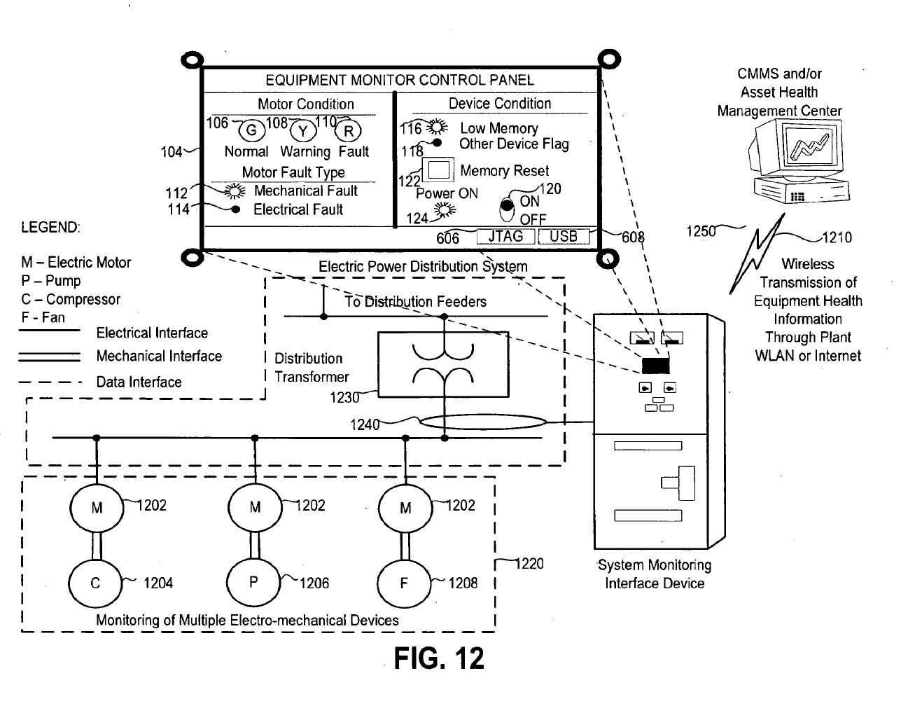

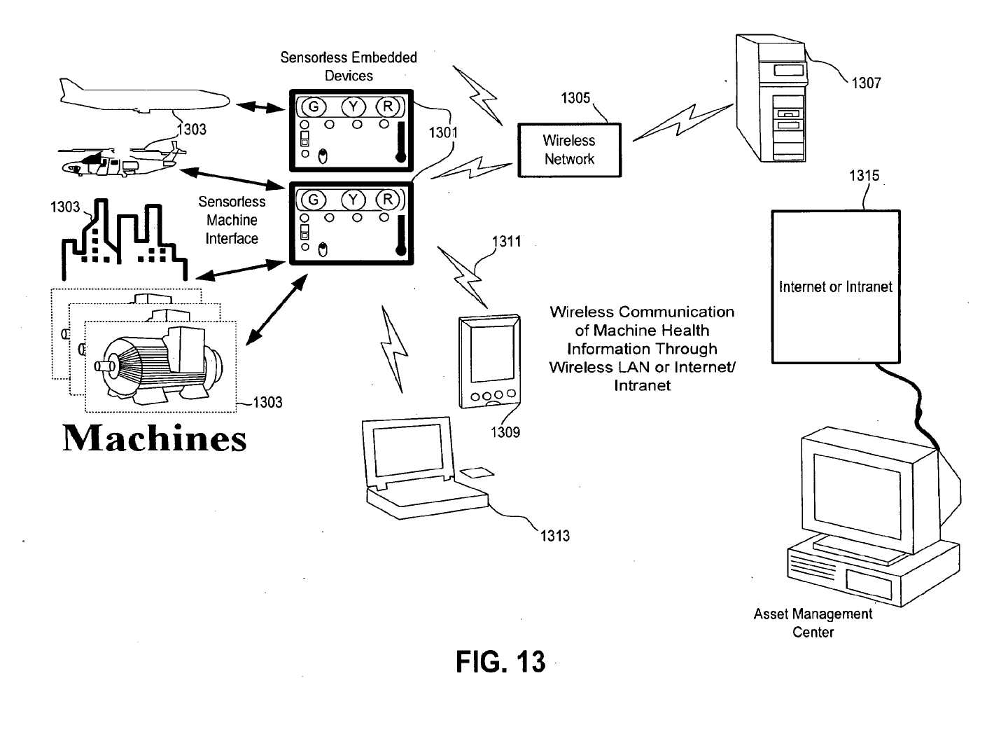

Embedded device 102 (also referred to herein as NIML03 or NIML05) is intended to serve as a “sensorless” condition monitoring and condition assessment device for electro-mechanical systems, such as electromechanical machines 1202, e.g., motor drivers, and electric generators, i.e., driven machines, that includes a wireless communication interface 1210. The same wireless device 1210 can be used to assess the condition of mechanical systems, such as pumps 1206, compressors 1204, and fans 1208, driven by electrical machines 1202, or turbines and engines driving electric generators, in a “sensorless” manner where the electrical machines 1202 are being utilized as transducers, and while there is no direct sensing available from the mechanical systems. The embedded device 102 can be used in condition monitoring, condition assessment and end-of-life prediction of a large number of machines 1220 by wirelessly communicating 1210 the condition information and other detailed data from the embedded device 102 disclosed, to a central embedded device (not shown) or another computing platform, such as a server 1307, 1407, for remote management of industrial assets, as shown in FIG. 13. Finally, the embedded device NIML03 102 can be used to assess the individual condition of a group of electro-mechanical and mechanical systems 1220, by having the embedded device 102 installed at the electrical bus 1240 (distribution transformer PT secondaries 1230 and CT secondaries 1220) supplying electrical power to the group of electro-mechanical and mechanical systems 1220, as shown in FIG. 12.

The embedded device box 202 with PCB board 500 is mounted on the inside door 704 of the electrical equipment (motor 1202, generator (not shown) or distribution transformer 1230) switchgear 702, while being interfaced to the three-phase potential transformer (PT) terminals 810 and 910 and three-phase current transformer (CT) secondary terminals and 820 and 920. The same device 102 with minor internal modifications can be used in the absence of PTs and CTs, by using an appropriate number of voltage and current transformers, internal to the device 102, for electrical isolation. Outputs 152 from the embedded device 102 are displayed on the front view of the device in the form of a control panel 104 using LEDs or they are wirelessly communicated 1210 to other devices, embedded or otherwise, and displayed with other software applications (not shown), as shown in FIG. 12. The control panel 104 includes LEDs for the
Monitored system condition indicators (OK 106, warning 108 and fault 110),
Fault type (mechanical 112 or electrical 114),
Problem related to mechanical load and/or power supply,
Embedded device indicators of OK (power on) 124, low memory 116 and other device flag 118.

Additional LEDs could be included to denote the specific electromechanical system problem, i.e. bearing fault, stator fault, etc. (not shown), or if more than one electromechanical system is being monitored, the identity of the faulty system and the nature of the fault. The front panel also includes a power switch 120 for the embedded device power (on and off) and two switches for memory reset 122 and for CPU reset (not shown), respectively. Finally, the control panel 104 includes the communication ports of the embedded device 102, such as a USB port for programming 608, a USB port for manual data communication 608 and a wireless port for direct two-way communication with other embedded devices (not shown), such as hand-held devices or cell phones 1309, or desktop computing devices 1313. The wireless communication 1311 can be used for both programming and/or data transfer.

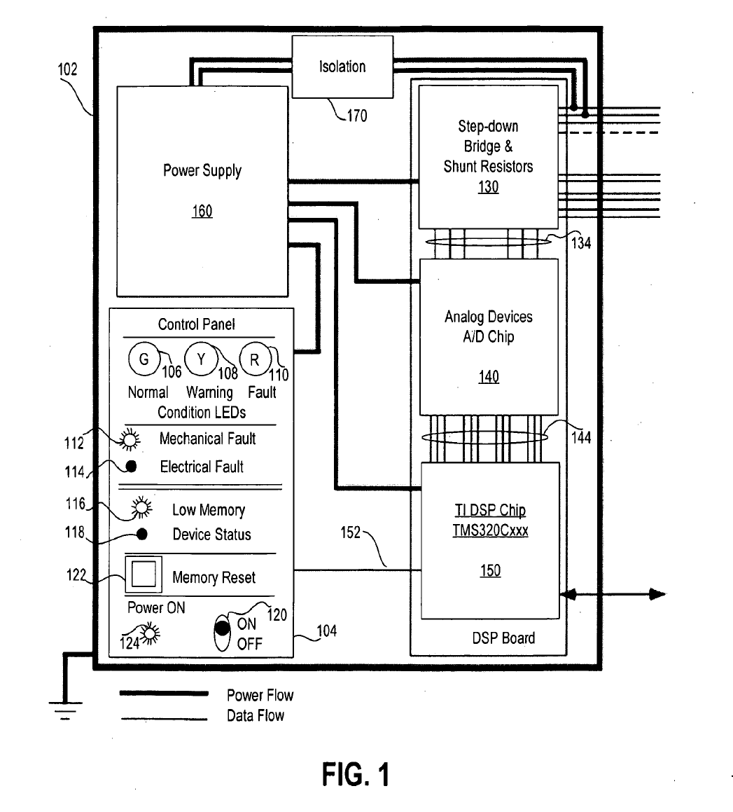

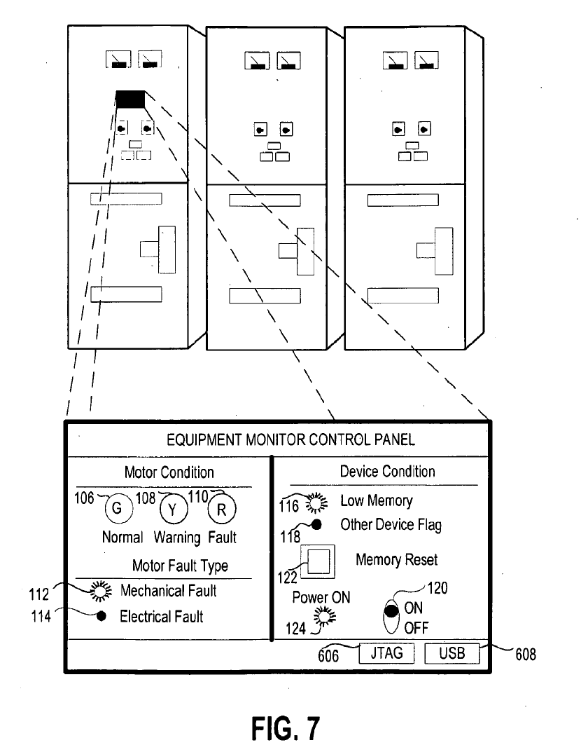

According to a desired operating mode, the embedded device box 202 with PCB board 500 is mounted in a manner that the control panel 104 is seen from the outside door 704 of the electrical equipment switchgear 702. As such information can be accessed without the need to open the switchgear door 704, as shown in FIG. 7. Wiring the control panel 104 from the embedded PCB device 500 shall be passed through a drilled opening (not shown) on the switchgear door 704. FIG. 1 depicts a simplified schematic block diagram of the embedded device 102.

Visual indicators such as LED's etc. are shown in various figures herein. In another embodiment of the present invention a computer display device implements visual indicators for a user.

Mechanical Specifications

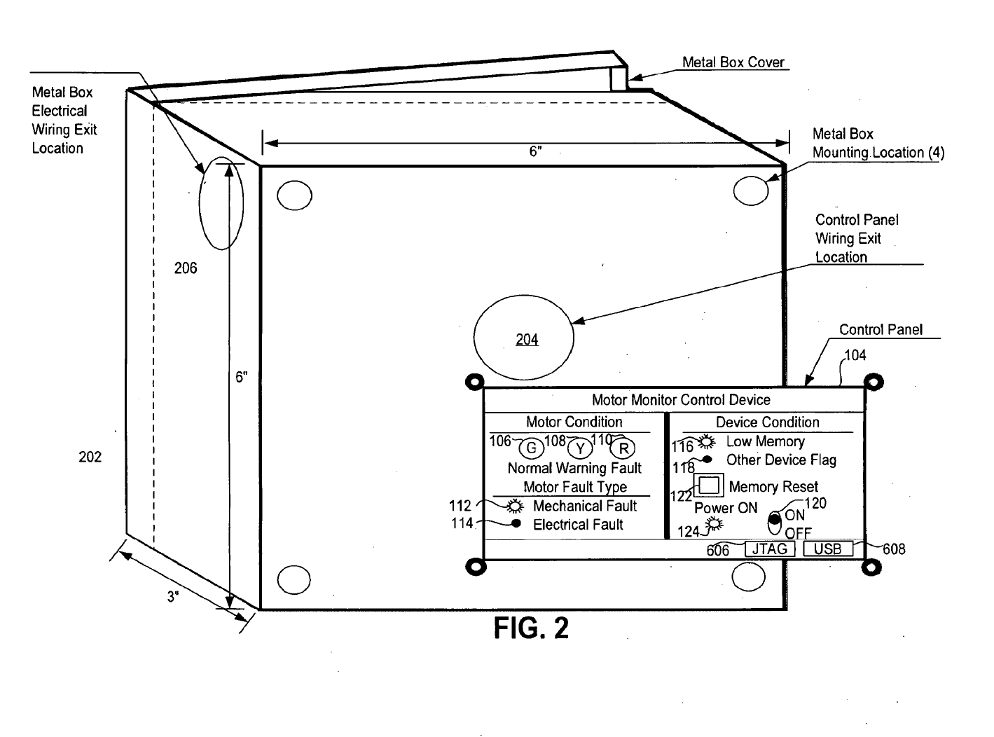

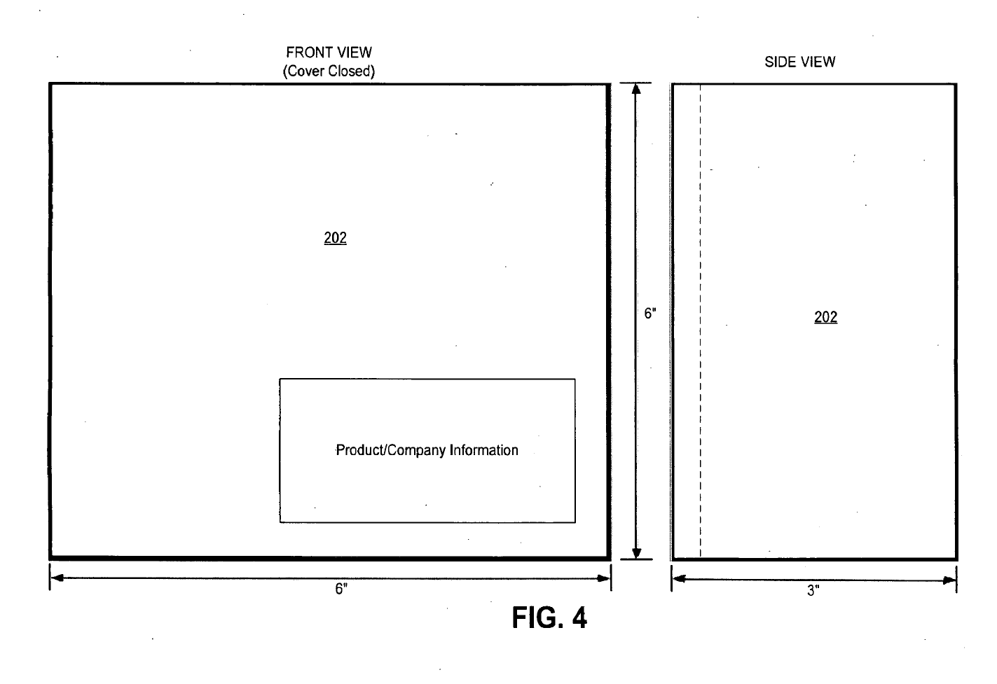

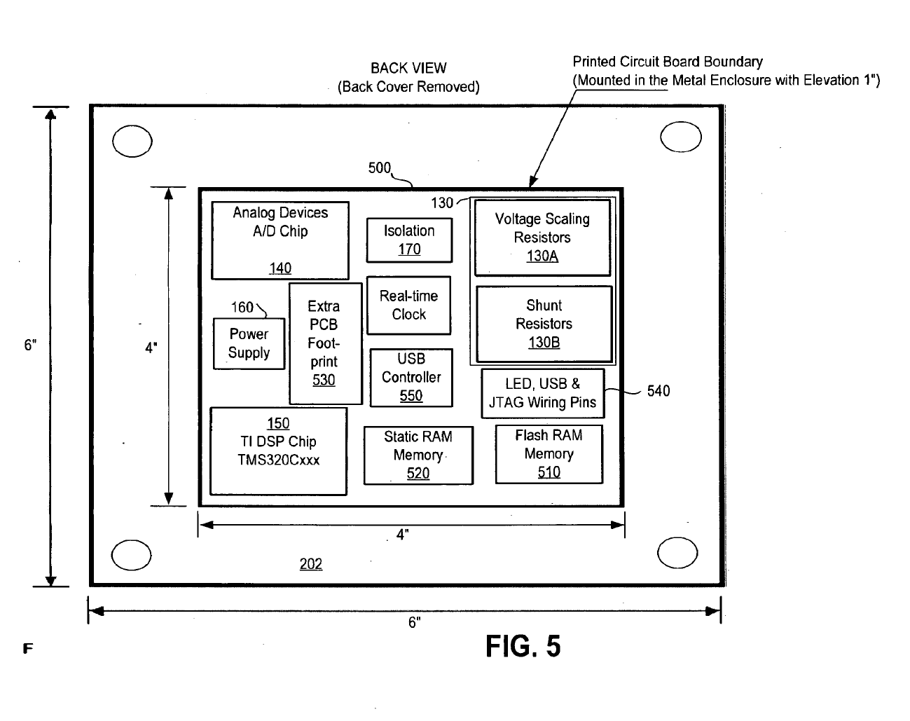

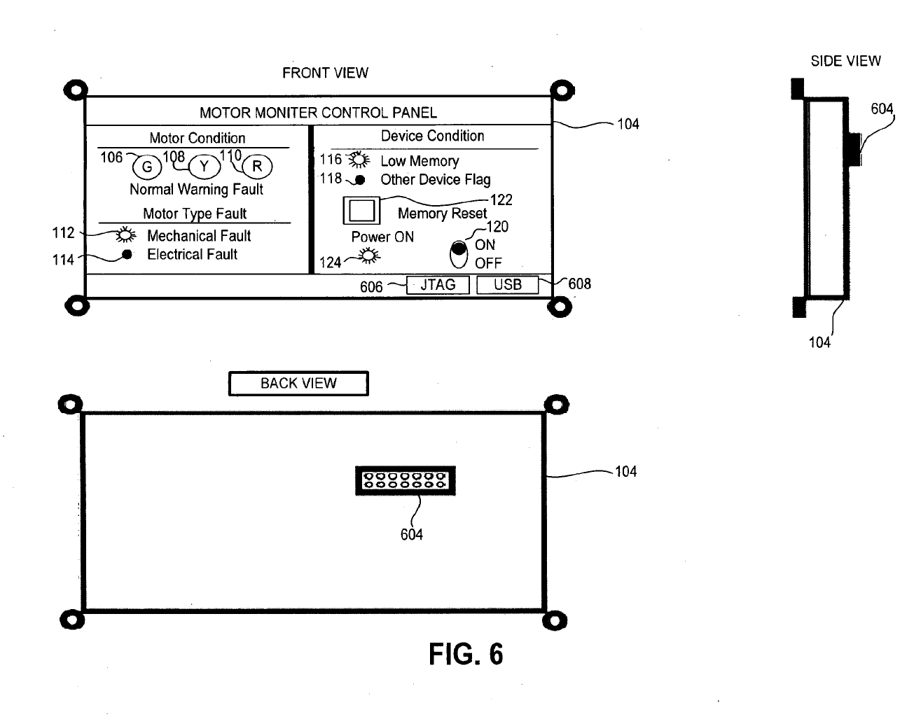

According to one embodiment of the invention, mechanical specifications of the embedded device NIML03 102 are as follows:
Physical enclosure—A standard small metal box 202 with example dimensions of 6″×6″×3″ or 4″×4″×2″ is needed to hold the printed circuit board (PCB) 500. There is no need for specialized NEMA enclosure. FIGS. 2, 3, and 4 show a 3D depiction of the metal box and some elementary mechanical drawings, respectively. FIG. 5 depicts the PCB layout 500 and its relative placement within the metal box 202.
Control Panel Indicators—The control panel with LED indicators 104 is a separate physical entity of the embedded PCB device 500, as shown in FIG. 6. The embedded device box 202 is mounted on the switchgear door 704 such that the control panel 104 is visible from the outside of the switchgear enclosure 702 without opening it, as seen in FIG. 7
Physical location—The embedded device 102 will be mounted on the door of the equipment switchgear 702 (control panel with LED indicators 104 must be visible without opening the switchgear door 704 and will be mounted on the outside of the switchgear door 704) through an opening equal to the cross-sectional area of the embedded device box 202.
Operating environment—industrial, outdoors, but protected by the switchgear enclosure.
Operating temperature—32 F-150 F. (In one embodiment, parts are provided having an operating temperature range of −20 C to +70 C.)

Software and Computer System

In an embodiment of the present invention, at least portions of logic of device 102 are implemented by software. Such logic for the present invention is further described in the above referenced and incorporated patents. There are no special hardware specifications required for operation of such software. However, CPU utilization might be an issue if the software is installed on slow processors, e.g. less than 300 MHz Pentium II processor. If used with inverter-fed machines, the presence of a DSP board might be required. In one embodiment of the invention, the software is based on C, C++, LabVIEW, and Matlab programming languages.

The present invention, aspects of which are shown in the above FIG's, may be distributed in the form of instructions, which may include data structures and may be referred to as a “computer program,” “program,” “program code,” “software,” “computer software,” “resident software,” “firmware,” “microcode,” etc. Stored on a computer-readable storage medium, such instructions and storage medium may be referred to as a “computer program product,” “program product,” etc.

The computer program product may be accessible from a computer-readable storage medium providing program code for use by or in connection with a computer or any instruction execution system. The present invention applies equally regardless of the particular type of media actually used to carry out the distribution. The instructions are read from the computer-readable storage medium by an electronic, magnetic, optical, electromagnetic or infrared signal. Examples of a computer-readable storage medium include a semiconductor or solid-state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD. The instructions may also be distributed by digital and analog communications links, referred to as “transmission media.”

Computer System

A data processing system suitable for storing and/or executing program code includes at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

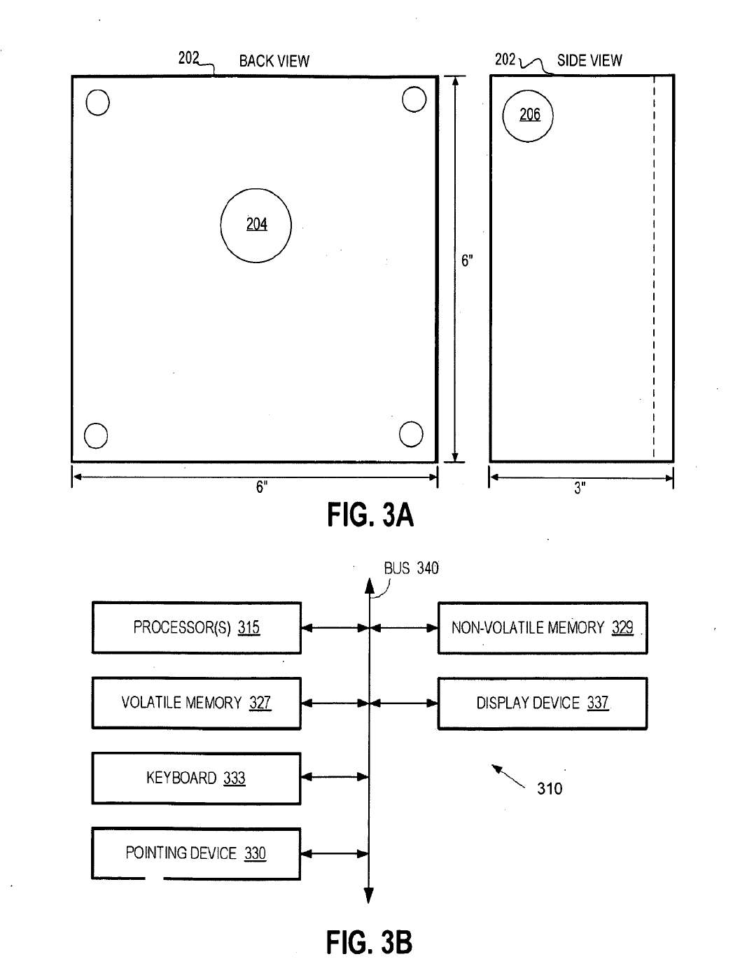

Referring now to FIG. 3B, a computer system 310 is shown that is generally applicable for embodiments described of the computer systems of FIG. 13 and others. System 310 is also suitable to perform some of the functions of the single-board embodiment of the invention shown in FIG. 5. In various embodiments of the present invention, a system such as computer system 310 of the embedded device detects whether the electromechanical machine has an anomalous or faulty mechanical or electrical condition, wherein the condition includes a predetermined or learned fault signature pattern, wherein the detection is in response to the received bus voltage and aggregate current time series measurements. Alternatively, such as in an embodiment of the invention as shown in FIG. 5, the embedded device performs signal processing for the received measurements and transmits the processed signals, preferably wirelessly, to a remote computing system such as computer 310, as shown in FIG. 13, for example. In this embodiment of the Invention, the remote computing system 310 detects the conditions, or at least cooperates with the embedded device to detect the conditions.

The system 310 of FIG. 3A includes a processor 315, a volatile memory 320, e.g., RAM, a keyboard 325, a pointing device 330, e.g., a mouse, a nonvolatile memory 335, e.g., ROM, hard disk, floppy disk, CD-ROM, and DVD, and a display device 305 having a display screen. Memory 320 and 335 are for storing program instructions, which are executable by processor 315 to implement various embodiments of a method in accordance with the present invention. Components included in system 310 are interconnected by bus 340. A communications device (not shown) may also be connected to bus 340 to enable information exchange between system 310 and other data carriers.

In various embodiments system 310 takes a variety of forms, including a personal computer system, mainframe computer system, workstation, Internet appliance, PDA, an embedded processor with memory, etc. That is, it should be understood that the term “computer system” is intended to encompass any device having a processor that executes instructions from a memory medium.

The memory medium preferably stores instructions (also known as a “software program”) for implementing various embodiments of a method in accordance with the present invention. In various embodiments the one or more software programs are implemented in various ways, including procedure-based techniques, component-based techniques, and/or object-oriented techniques, among others. Specific examples include XML, C, C++, Java and Microsoft Foundation Classes (MFC).

Those of ordinary skill in the art will appreciate that the processes of the present invention are capable of being distributed as computer readable medium of instructions in a variety of forms and that the present invention applies equally regardless of the particular type of signal bearing media actually used to carry out the distribution. Examples of computer readable media include recordable-type media such a floppy disc, a hard disk drive, a RAM, and CD-ROMs.

Hardware Specifications

In an embodiment of the present invention, hardware specifications of embedded device 102 are divided into the following groups:

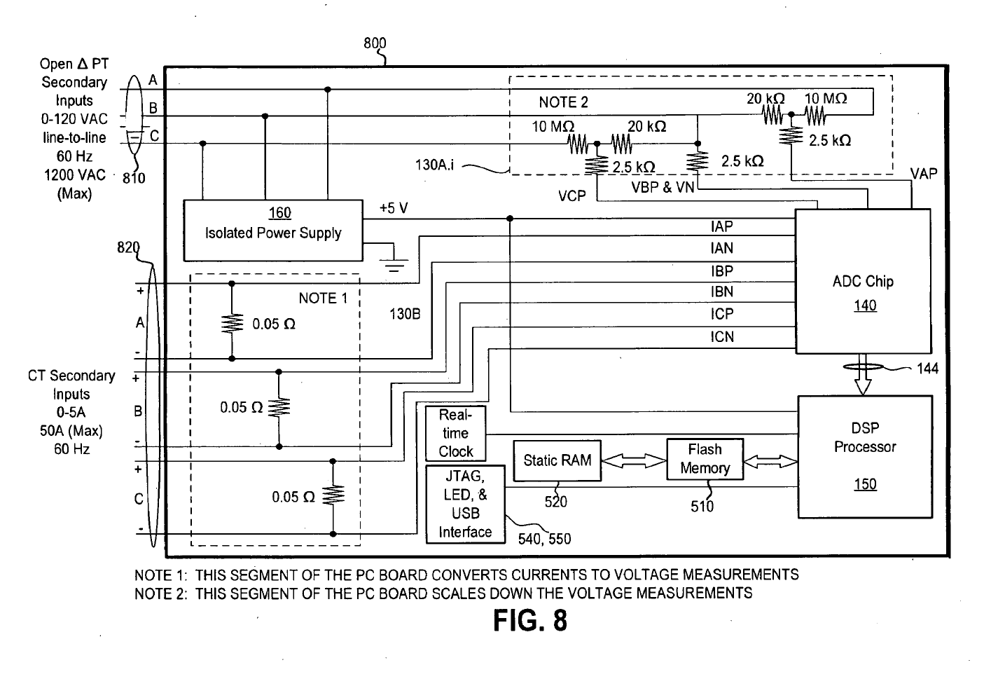

Analog Inputs and Circuitry: For electro-mechanical systems supplied by three-phase power, there are 6 or 7 analog inputs to the system, depending on the PT wiring connections. All these analog inputs are isolated because they originate from the secondary side of transformers. Three (open Δ) 810 or four (Y-neutral) 910 of these inputs are the PT secondaries of the three-phase line-to-line (or line-to-neutral) voltages rated at 0-120 VAC (1200 VAC maximum). The other three inputs are the CT secondaries 820 and 920 of the three-phase currents that must be measured through three high-accuracy shunt resistors 130B without exceeding the maximum CT “burden”. The CT secondaries 820 and 920 are rated at 0-5 A (50 A maximum). A bridge circuit 130A is needed to scale-down these measurements to the range needed for input to the A/D chip 140. (In one embodiment of the present invention, a shunted CT having a split core is used.) The PT connections 810 and 910 can be used to run the power supply 160 of the embedded device 102. The analog circuitry of the embedded device 102 for the case of a three-phase open Δ connected PT 810 is shown in FIG. 8.

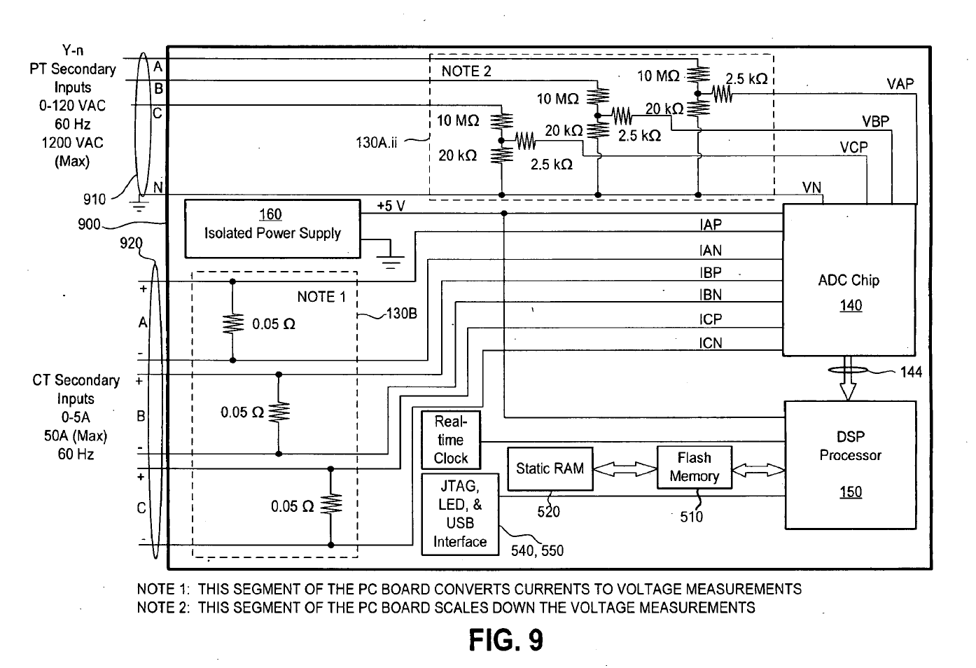

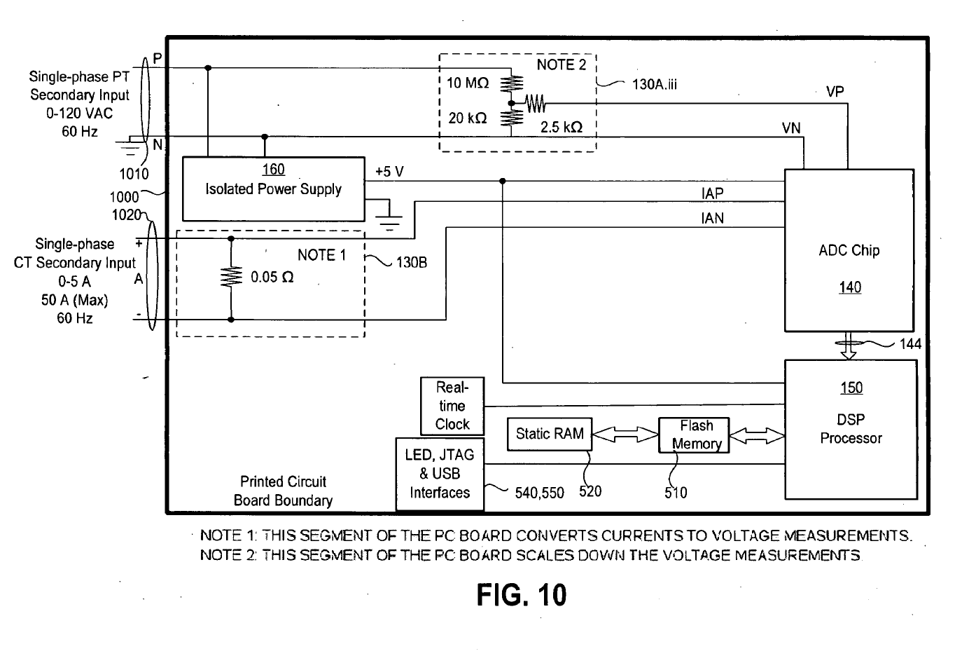

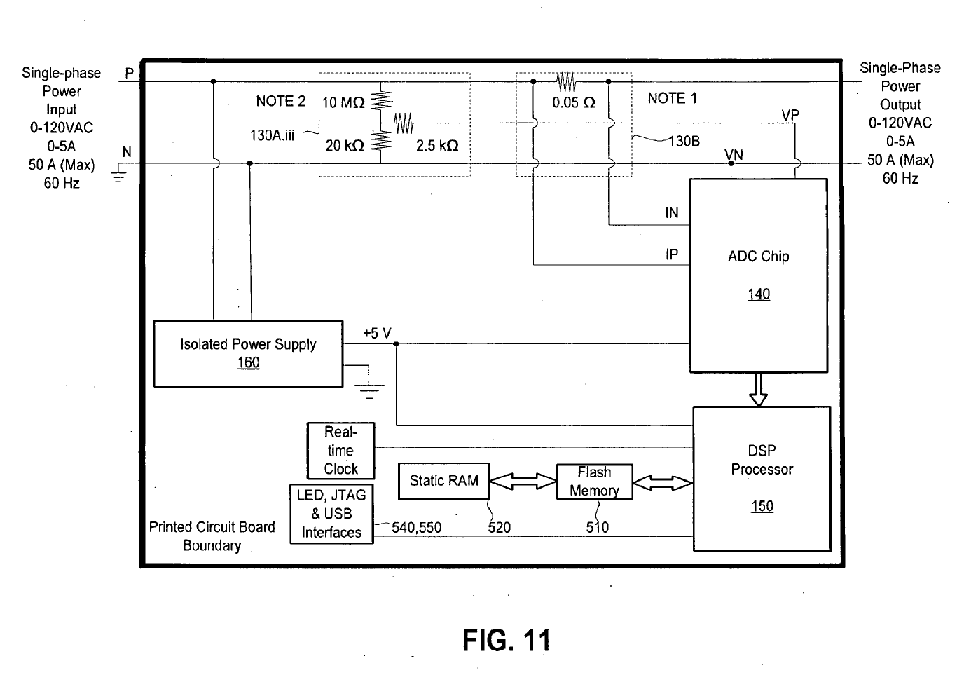

The above-described embodiment is a baseline configuration for the embedded device, as most of the available switchgear are open Δ connected. Other embodiments are, of course, within the scope of the invention, as will be understood by a person of ordinary skill in the art. For example, the same circuitry for the case of a three-phase Y-neutral connected PT 910 is shown in FIG. 9. FIG. 10 shows the embedded device circuitry 1000 for the case of single-phase power supply when a PT 1010 and a CT 1020 is externally available. FIG. 11 depicts the embedded device circuitry 1100 for the case of single-phase power supply 1110 when a PT and a CT is not available.

A/D Chip 140: The Analog Devices ADE7754 or a similar A/D chip 140, such as the TI ADS8364 is a good candidate for the design if we can obtain as outputs 144 from this chip sampled waveforms of the six input analog signals 134 in a multiplexed manner. In addition some chips 140 provide samples of the RMS values of the six analog inputs 134. Each of the raw analog inputs 134 will be sampled at 2,000 to 5000 samples/sec. Additionally, each of the RMS values of the raw analog signals 134 will be sampled at approximately 100 samples/sec.

DSP Chip 150: In addition to the ADE7754 chip 140, a floating-point DSP chip 150 is included for the signal processing operations. Currently, the TI TMS320C6711 or TMS320C6713 DSP or a similar chip is present for this purpose. The DSP chip 150 will access 16 MB of flash or EEPROM memory 510 (non-volatile) and 16 MB of RAM 520 (volatile) for storage and computations.

Board Interfaces: The PCB board 500 has a JTAG 540 and a USB 2.0 interface 540,550 for communication 1250 to a laptop or other external device and an interface 604 to the embedded device control panel 104 with several LEDs as shown in FIG. 6. An isolated power supply 160 is included to energize the PCB 500. The power supply 160 is energized by the PT connections 810, 910 and/or 1010.

Expandability Specifications

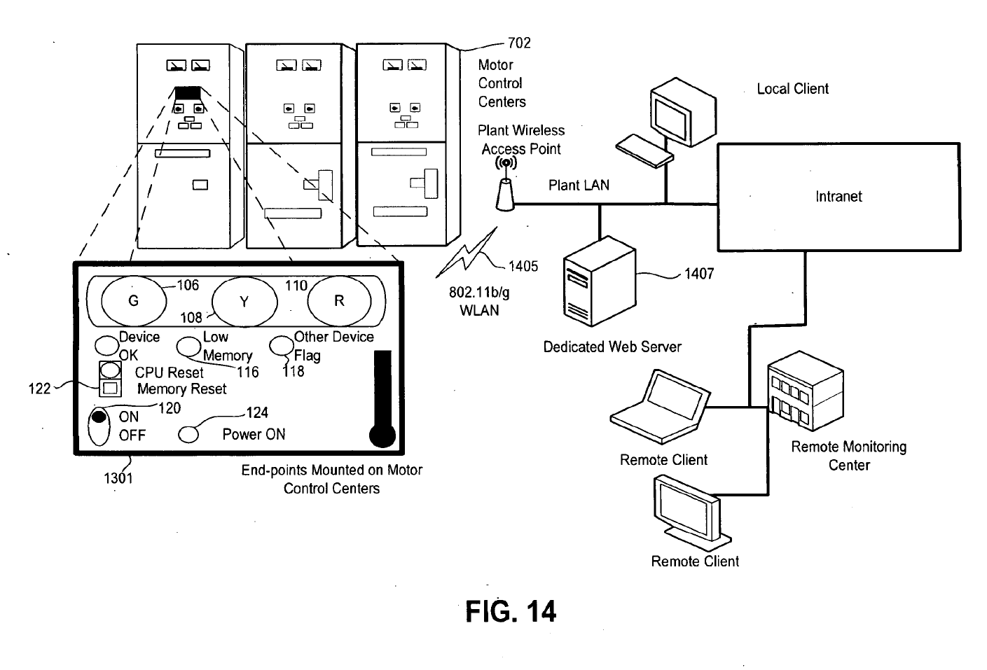

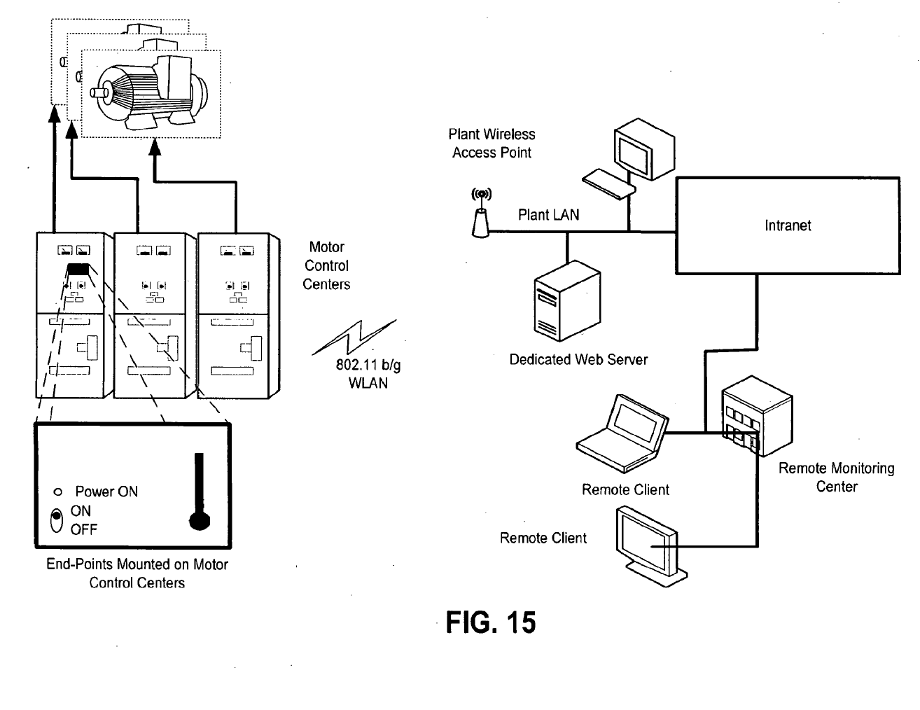

Embedded device hardware 500 has been designed keeping in mind certain expandability issues. Extra PCB footprint 530 is needed for future addition of flash or EEPROM 510 or RAM 520 memory to functionally expand the system and for possibly adding anti-aliasing filters (not shown), if necessary. Furthermore, a small LCD display (not shown) might be eventually needed to communicate additional system information to users. Finally, consideration has been given to the need of an 802.11b and/or Bluetooth wireless interface (not shown) connecting the embedded device 102 to other computing platforms, wired or wireless, fixed or mobile (as shown in FIGS. 13 and 14).

Other Specifications

In an embodiment of the invention, the hardware platform, as delivered to a user, will include all firmware, e.g., device drivers (not shown), needed to perform all necessary hardware checks and tests of the various components present in the embedded device 102. Additionally, all of the software needed to perform the described device functionality will be preloaded. A turnkey device will be delivered to an end-user.

Parts List

Following is a preliminary parts list for the device according to an embodiment of the invention.

| Components | | Quantity |
|---|---|---|
| (1) | TMS320C6711 DSP or similar DSP chip 150 | 1 |
| (2) | ADE7754 or similar A/D chip 140 | 1 |
| (3) | Non-volatile memory (Flash or EEPROM) 510 | 16 MB |
| (4) | Volatile memory (RAM) 520 | 16 MB |
| (5) | USB 2.0 port 608 | 1 |
| (6) | JTAG port 606 | 1 |
| (7) | Power supply (5 V) 160 | 1 |
| (8) | Isolation amplifier for power supply 170 | 1 |
| (9) | Front control and indicator panel 104 | 1 |
| (10) | LED indicators 106, 108, 110, 112, 114, 116, 118, 124 | 8 |
| (11) | Memory reset button 122 | 1 |
| (12) | Power switch 120 | 1 |
| (13) | Metal box/mounts (6″ × 6″ × 3″) 202 | 1 |
| (14) | LED, JTAG, USB wiring pins 604, 606, 608 | 1 |
| (15) | High-accuracy “shunt resistors” 130B | 3 |
| (16) | Voltage bridge resistors 130A | 9 |
| (17) | Printed Circuit Board (PCB) (4″ × 4″) 500 | 1 |
| (18) | Others (wires, fuses, etc.) | |

NOTES:
1. With exception of the (high-accuracy) shunt resistors 130B which should be rated at 125 W, the remaining resistors 130A on the PCB 500 will not carry any significant amount of current. They can be rated 0.5 W or the standard rating.
2. All components of the embedded device 102 are placed on a single PCB 500, preferably of size 4″ × 4″ or smaller, if possible.
3. An important aspect of the PCB design is to insure that the power supply 160 which will be energized by the PTs 810, 910, and 1010 (0-120 V and 1200 V max) can withstand the occasional voltage spikes. As such, it is preferred, and may be required, that an isolation amplifier be placed between the 5 V power supply and the PT connections 810, 910 and 1010 energizing it to limit the voltage spikes.

### Additional Embodiments of the Invention

Following are various embodiments and uses of this invention:

The disclosed hardware configuration 102 is combined with algorithms reported in patents specified in “Software Specifications” section of this document or it is combined with other “sensorless” algorithms intended to manage the life-cycle health of electrical equipment such as motors 1202, generators (not shown), and transformers 1230. The device 102 is interfaced to the secondary side of potential transformers (PTs) 810 and current transformers (CTs) 820 available in the switchgear 702 of the electrical equipment. FIG. 8 shows a diagram of this embodiment for three-phase electrical equipment, with the open-delta configuration of PTs 810.

The disclosed hardware configuration 102 is combined with algorithms reported in patents specified in “Software Specifications” section of this document or it is combined with other “sensorless” algorithms intended to manage the life-cycle health of electrical equipment such as motors 1202, generators (not shown), and transformers 1230. The device 102 is interfaced to the secondary side of potential transformers (PTs) 910 and current transformers (CTs) 920 available in the switchgear 702 of the electrical equipment. FIG. 9 show a diagram of this embodiment for three-phase electrical equipment, with the Y-neutral configuration of PTs 910

The disclosed hardware configuration 102 is combined with algorithms reported in patents specified in “Software Specifications” section of this document or it is combined with other “sensorless” algorithms intended to manage the life-cycle health of electrical equipment such as motors 1202, generators (not shown), and transformers 1230. The device 102 is interfaced to the secondary side of potential transformer (PT) 1010 and current transformer (CT) 1020 available in the switchgear 702 of the single-phase electrical equipment. FIG. 10 shows a diagram of this embodiment for single-phase electrical equipment

The disclosed hardware configuration 120 is combined with algorithms reported in patents specified in “Software Specifications” section of this document or it is combined with other “sensorless” algorithms intended to manage the life-cycle health of electrical equipment such as motors 1202, generators (not shown), and transformers 1230. The device 102 is interfaced directly to the single-phase power lines 1110 of the electrical equipment. FIG. 11 shows a diagram of this embodiment for single-phase electrical equipment, when no PTs or CTs are available.

The disclosed hardware configuration 102 is combined with algorithms reported in patents specified in “Software Specifications” section of this document or it is combined with other “sensorless” algorithms intended to manage the life-cycle health of mechanical equipment, such as pumps 1206, compressors 1204, fans 1208, etc., being driven by electrical equipment such as motors 1202, or mechanical prime movers, such as turbines and engines, driving generators. The device 102 is interfaced to the secondary side of potential transformers (PTs) 810, 910 and current transformers (CTs) 820, 920 available in the switchgear 702 of the electrical equipment in either three-phase open-delta or Y-neutral configuration. The device 102 is also interfaced to the secondary side of a single-phase potential transformer (PTs) 1010 and current transformer (CTs) 1020 available in the switchgear 702 of the electrical equipment. Finally, the device 102 is interfaced directly to the single-phase or three-phase power lines of the electrical equipment as seen in FIG. 11.

The disclosed hardware configuration 102 is combined with algorithms reported in patents specified in “Software Specifications” section of this document or it is combined with other “sensorless” algorithms intended to manage the life-cycle health of mechanical equipment and/or electrical equipment 1220, as described in embodiments 1 through 6. The device 102 is interfaced at a centralized location, preferably at the distribution transformer 1230 energizing a given bus 1240 or at the power entry point to a facility (not shown). The device 102 is interfaced to the secondary side of potential transformers (PTs) 810,910 and current transformers (CTs) 820,920 available in the switchgear 702 of the transformer 1230 or power entry (not shown), in either three-phase open-delta or three-phase Y-neutral configuration. The device 102 is also interfaced to the secondary side of a single-phase potential transformer (PTs) 1010 and current transformer (CTs) 1020 available in the switchgear 702 of the electrical equipment at the centralized location. Finally, the device 102 is interfaced directly to the single-phase (see FIG. 11) or three-phase power lines (not shown) of the electrical equipment available at the centralized location, in the event that PTs and CTs are not present. In this embodiment, the current invention is used to manage the health of large collection of electrical and mechanical equipment 1220, using a single device installation for the purpose of making aggregate measurements. These measurements are used in assessing the health of individual equipment 1220 present downstream the device 102 installation.

A collection of devices 1301 in accordance with the disclosed hardware configuration are combined with algorithms reported in patents specified in “Software Specifications” section of this document or it is combined with other “sensorless” algorithms intended to manage the life-cycle health of mechanical equipment and/or electrical equipment 1220, as described in embodiments 1 through 7. The collection of these devices 1102 forms a wireless network of “sensorless” embedded devices 1301, communicating 1305 machine health information to a centralized location via a combination of wireless 1305 and wired Internet/intranet 1315 configurations, as shown in FIG. 13. Typically the communication mode is two-way and in real-time or near real-time. The “sensorless” devices 1301 are interfaced as described in embodiments 1 through 7, either at individual machine level or at a centralized location, preferably at the distribution transformer 1230 energizing a given bus 1240 or at the power entry point to a facility (not shown). The device 102 is interfaced to the secondary side of potential transformers (PTs) 810, 910 and current transformers (CTs) 820, 920 available in the switchgear 702 of the transformer 1230 or power entry (not shown), in either three-phase open-delta or three-phase Y-neutral configuration. The device 102 is also interfaced to the secondary side of a single-phase potential transformer (PTs) 1010 and current transformer (CTs) 1020 available in the switchgear 702 of the electrical equipment at the centralized location. Finally, the device 102 is interfaced directly to the single-phase (see FIG. 11) or three-phase power lines (not shown) of the electrical equipment available at the centralized location, in the event that PTs and CTs are not present. In this embodiment, the current invention is used in the form of a wireless network of “sensorless” embedded devices 1301 to manage the health of large collection of electrical and mechanical equipment 1220, using a combination of aggregate and individual machine measurements. These measurements are used in assessing the health of individual equipment 1220 present downstream the device 1301 installations. The network configuration of the “sensorless” embedded devices 1301 could be “point-to-point” or “multi-point-to-point” (not shown) or in the form of an ad-hoc network of nodes 1601. The nodes communicate wirelessly directly with each other or through a wireless gateway to a wired network 1501, or to third-party computing platforms, such as hand-held devices or laptops 1313. The nodes could be stationary or mobile.

It is advantageous to use only the so-called “nameplate” machine information and measured operating current and voltage, instead of detailed machine design information, to detect faults in a large population of machines fed through the same power distribution network by measurements at the bus level instead of measurements at individual machine terminals.

The term “switchgear” is used herein for various embodiments of the invention. This term has meaning in an industrial electrical equipment context. It should be understood that the invention includes embodiments other than switchgear in the industrial electrical equipment sense. Accordingly, the term “switchgear,” particularly as used in the claims herein, should be understood to include other kinds of power distribution devices, such as a motor control center, load center, and distribution panel.

In one embodiment, the system comprises one or more distributed nodes (end-points) attached to a power distribution network (PDN) supplying electric power to the devices, and one or more centralized or decentralized computing platforms (servers) interfaced to a network or inter-network infrastructure, e.g. the Internet. The one or more nodes manage condition, life and efficiency of one or more devices. The system can used to manage the life cycle of one, more than one or all of the devices attached to a segment or the entirety of a PDN, where the devices receive electric power directly from the PDN or indirectly powered by a device receiving power from the PDN.

The system comprises hardware that resides nodes and the servers. The system also comprises software. The system software executes concurrently or intermittently on all the nodes and all servers.

Each node has an electrical interface connecting to the PDN at any one of several possible locations, e.g. device terminals, switchgear or voltage bus. The electrical interface is used to power the node; measure one or more phases of voltages, either directly or through potential transformers; and measure one or more phases of currents, either directly or through current transformers. The node can be used to measure the electrical voltages, the electrical currents or both.

Each node has an embedded computing platform for sampling one or more analog signals and for processing them. The platform includes a CPU or DSP, memory, etc., that is all components found in an embedded computer.

Each node has a wireless interface for communicating data and/or other information to the servers. The communication interface could be based on Wifi, WiMax, ZigBee or any other IEEE standard or otherwise protocol. The multiple nodes of the system form a wireless LAN (WLAN) that comprises the nodes, wireless bridges, routers, repeaters, etc. The WLAN is interfaced to a wired network and it could be operated in “infrastructure” or “ad-hoc” mode.

In view of the interfaces found in a node, each node is characterized as a network embedded device without sensor interfaces, i.e. a sensorless networked embedded device.

Centralized or decentralized computing platforms (servers) communicating with the nodes can be accessed via the Web or via e-mail over the Internet or Intranet, displaying health, maintenance or energy efficiency related information, in either graphical or textual form. This remote access of continuous information streams enables the system to be used in a service mode.

one embodiment of the invention, the system can be configured such that each node is interfaced, is associated and manages a single electromechanical or mechanical device. In this embodiment each node is made up of a single power interface in the form of a power printed circuit board (PCB) and a single computing PCB, with a single electrical measurement interface. Each node also has a single wireless interface.

In another embodiment, the system can be configured such that each node is interfaced, is associated and manages multiple electromechanical or mechanical devices. In this embodiment each node is made up of a single power interface in the form of a power PCB and multiple computing PCBs, with multiple electrical measurement interfaces. Each node also has a single wireless interface.

In yet another embodiment, the system can be configured such that each node is interfaced at a single point of a PDN and thus it is associated and manages, without further electrical interfaces, all electromechanical or mechanical devices drawing power from the PDN. In this embodiment each node has a single power interface in the form of a power PCB and a single computing PCB, with a single electrical measurement interface. Each node also has a single wireless interface.

The arrangements described herein receiving static data for each machine by the device, wherein the static data includes date selected from the group including operating voltage, full load current, locked rotor current, and a machine type designation, wherein the detecting is further responsive to the static data.

The disclosed sensorless system is intended for use in life cycle condition (or health) monitoring and assessment, and in end-of-life prediction of electromechanical and mechanical devices, i.e. equipment or machines. In particular, the system can be used for the early detection of deteriorating device health, early detection and diagnosis of device faults and their associated uncertainties, device life expectancy estimation and the associated uncertainty, and device life-cycle efficiency estimation and energy management.

Example electromechanical devices include electric motors, including those operated at constant frequency and those operated through the use of variable frequency drives, and electric generators. All types of electric motors and generators are included, such as induction, synchronous, etc.

Example mechanical devices include pumps, compressors, fans, turbines, engines, conveyor belts, etc., that is all types of mechanical devices that are driven by electric motors and all types of mechanical devices that drive electric generators, including those with gear-boxes in between motor and driven load, or prime mover and generator.

Such electromechanical and mechanical devices could be found in power plants, processing plants, manufacturing facilities, commercial or other buildings, transportation equipment, medical devices, etc.

In one embodiment, the system includes one or more distributed nodes (end-points) attached to a power distribution network (PDN) supplying electric power to the devices, and one or more centralized or decentralized computing platforms (servers) interfaced to a network or inter-network infrastructure, e.g. the Internet.

The system can used to manage the life cycle of one, more than one or all of the devices attached to a segment or the entirety of a PDN, where the devices receive electric power directly from the PDN or indirectly powered by a device receiving power from the PDN.

The system can have one or more nodes managing the condition, life and efficiency of one or more devices.

The system includes hardware that resides in the nodes and the servers. The system also includes software. The system software executes concurrently or intermittently on all the nodes and all servers.

Each node has an electrical interface connecting to the PDN at any one of several possible locations, e.g. device terminals, switchgear or voltage bus. The electrical interface is used to power the node, measure one or more phases of voltages, either directly or through potential transformers, and measure one or more phases of currents, either directly or through current transformers.

The node can be used to measure the electrical voltages, the electrical currents or both.

Each node has an embedded computing platform for sampling one or more analog signals and for processing them. The platform includes a CPU or DSP, memory, etc., that is all components found in an embedded computer.

Each node has a wireless interface for communicating data and/or other information to the servers. The communication interface could be based on WiFi, WiMax, ZigBee or any other IEEE standard or otherwise protocol. The multiple nodes of the system form a wireless LAN (WLAN) that includes the nodes, wireless bridges, routers, repeaters, etc. The WLAN is interfaced to a wired network and it could be operated in “infrastructure” or “ad-hoc” mode. In view of the interfaces found in a node, each node is characterized as a network embedded device without sensor interfaces, i.e. a sensorless networked embedded device.

The centralized or decentralized computing platforms (servers) communicating with the nodes can be accessed via the Web or via e-mail over the Internet or Intranet, displaying health, maintenance or energy efficiency related information, in either graphical or textual form. This remote access of continuous information streams enables the system to be used in a service mode.

In one embodiment the system can be configured such that each node is interfaced, is associated and manages a single electromechanical or mechanical device. In this embodiment each node is made up of a single power interface in the form of a power printed circuit board (PCB) and a single computing PCB, with a single electrical measurement interface. Each node also has a single wireless interface.

another embodiment the system can be configured such that each node is interfaced, is associated and manages multiple electromechanical or mechanical devices. In this embodiment each node is made up of a single power interface in the form of a power PCB and multiple computing PCBs, with multiple electrical measurement interfaces. Each node also has a single wireless interface.

In yet another embodiment the system can be configured such that each node is interfaced at a single point of a PDN and thus it is associated and manages, without further electrical interfaces, all electromechanical or mechanical devices drawing power from the PDN. In this embodiment each node has a single power interface in the form of a power PCB and a single computing PCB, with a single electrical measurement interface. Each node also has a single wireless interface.

Combinations of the above are, of course, intended embodiments.

The embodiments described herein were chosen and described in order to best explain the principles of the invention, the practical application, and to enable others of ordinary skill in the art to understand the invention. Various other embodiments having various modifications may be suited to a particular use contemplated, but may be within the scope of the present invention.

Unless clearly and explicitly stated, the claims that follow are not intended to imply any particular sequence of actions. The inclusion of labels, such as a), b), c) etc., for portions of the claims does not, by itself, imply any particular sequence, but rather is merely to facilitate reference to the portions.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

### I. Introduction

A. Motivation

Motor current signature analysis (MCSA) and electrical signal analysis (ESA) have been in use for some time to estimate the condition of induction motors based on spectral analysis of the motor current and voltage waveforms. In almost all applications, motors are always coupled to other dynamic systems. Consequently, it would be more beneficial if the drivepower system as a whole is monitored. A drivepower system includes the electronic drive and control packages, motors, shafts, couplers, belts, chains, gear drives, bearings, pumps, conveyors, etc. As time passes, all of the individual system components of the drivetrain degrade and finally some component catastrophically fails resulting in an unscheduled shutdown. The large costs associated with the resulting idle equipment and personnel can often be avoided if the degradation is detected in its early stages [1]. Hence there is a need for an effective diagnosis scheme not only for condition assessment of the motor, but also for the rest of the drivetrain. This work deals with the sensorless diagnosis of faults that occur in centrifugal pumps driven by induction motors.

A point to note is that the proposed approach is “sensorless” in the sense that no mechanical or process-based sensors are used for the detection and isolation of faults that occur within centrifugal pumps. Only the motor electrical signals are used. The motor line voltages and phase currents can be measured using potential transformers (PT's) and current transformers (CT's), which are standard installations in most of the industries and are easily accessible.

The journal model is IEEE Transactions on Automatic Control.

A lot of effort has been invested in detecting and diagnosing incipient faults in centrifugal pumps through the analysis of vibration data, obtained using accelerometers installed in various locations on the pump. Fault detection schemes based on the analysis of process data, such as pressure, flow and temperature have also been developed. In some cases, speed is used as an indicator for the degradation of the pump performance. All of the above mentioned schemes require sensors to be installed on the system. Installation of these sensors leads to an increase in overall system cost. Additional sensors need cabling, which also contributes towards increasing the cost of the system. These sensors have lower reliability, and hence fail more often than the system being monitored, thereby reducing the overall robustness of the system. In some cases it maybe difficult to access the pump to install sensors. One such example is the case of submersible pumps wherein it is difficult to install or maintain sensors once the pump is underwater. To avoid the above-mentioned problems, the use of mechanical sensors has to be avoided to the extent possible. Since many of the industrial pumps currently in use are centrifugal pumps (about 90% [2]) and most are driven by induction motors, the present work concentrates on analyzing the motor line currents and line voltages to detect and diagnose faults occurring in centrifugal pumps.

A fault diagnosis scheme consists of three stages, which are described below:
1. Stage 1—Fault Detection: This stage involves analyzing the fault features extracted from the sampled signals and detecting the presence of a fault in the system. The output of this stage informs the plant supervisor or the manager that the system under supervision is not performing up to its standards. There is no further information as to which component within the system is faulty and what type of fault is present.
2. Stage 2—Fault Isolation: Once it has been established that there is a fault in the system the next stage is to locate the fault and determine the faulty component. This would save time for the maintenance personnel in deciding the course of action to be taken to get the system back online. Moreover, the equipment/production downtime would be reduced drastically as the personnel would not be dismantling many components to establish the cause of the downtime.
3. Stage 3—Fault Identification: Once the faulty component is determined, the downtime can be further reduced if the maintenance personnel have information about the type of fault. For example whether the fault is of mechanical or electrical origin. This would enable them to be ready with the necessary spare parts or the repair personnel to replace or repair the faulty part of the component.

This work deals only with the first two stages of the fault diagnosis scheme.

B. Problem Definition

The objective of this work is to develop and validate an efficient, sensorless fault detection and isolation scheme for operational and mechanical faults that occur within centrifugal pumps. The developed scheme must not generate false alarms arising due to changes in the power supply or load and/or load pulsations. At the same time, the scheme must have a high probability of fault detection and enable the distinction between motor and pump faults.

C. Literature Survey

Most of the literature on fault detection of centrifugal pumps is based on techniques that require the measurement of either vibration or other process based signals. There are very few references that deal with sensorless or non-invasive/non-intrusive techniques to diagnose faults in centrifugal pumps. Moreover, in all the literature presented, the motor is considered to be “healthy”. No experiments are performed to determine whether the fault exists in the motor or in the pump. Faults are only staged in the pump and this knowledge is used in the detection of pump faults. But in reality, this information is seldom available. In [3], the authors review the latest techniques that are employed in pump diagnostics. A list of typical pump problems that develop in the pump along with the conventional method of detection is presented.

In [4], the development and application of signal processing routines for the condition monitoring of water pumps used in submarines is discussed in detail. Eroded impeller condition of a Bryon Jackson Sea Water Pump, which is a centrifugal pump, found in submarines is investigated. The eroded condition affects the mechanical load and the amount of torque provided by the three phase induction motor. It is postulated that changes in the load torque would lead to changes in the input power driving the induction motor. Hence fault features related to eroded impeller conditions are extracted from the power spectrum using the signal processing algorithms developed and these features are used as indicators for fault diagnosis. A classification scheme based on the nearest neighborhood technique is also developed. Using this technique, 90% of the test cases are classified correctly. A neural network-based scheme is also developed to improve the classification accuracy.

In [5, 6, 7, 8], the authors point out that the operation of the pump away from its best efficiency point (BEP) has been a significant source of pump problems. Unsteady hydraulic forces are the dominant sources of overall loads for centrifugal pumps. In this work, motor current and power analysis has been shown to be an alternative for the detection of some of the operational and structural problems related to pumps. Some of the cases considered are:
Load stability versus flow rate,
Equipment misalignment and
Clogged suction strainer.

A comparative study between the vibration spectrum, power spectrum and the torque ripple spectrum is undertaken in the detection of the above-mentioned case studies. In these studies, the underlying assumption is that the motor speed, current, power and power factor change in response to load changes or fluctuations. The idea is to monitor the load related peaks in the power or current spectrum. Since the motor power changes relatively linearly with load as opposed to the nonlinear relationship between the current and the load, the motor power is considered as the parameter to be monitored. The running speed harmonic is one of the indicators monitored in the power spectrum to establish the condition of the pumps under consideration. It is concluded that although vibration spectra obviously provided critical equipment health information, the motor current and the power spectra analysis offered an attractive alternative in diagnosing the condition of the pumps.

Some of the submersible pumps in operation today are at a depth of more than 1000 meters. Therefore the use of vibration sensors for pump and motor protection and condition monitoring is difficult due to the extreme conditions and remote locations. Motor current signature analysis (MCSA) offers an attractive alternative for the condition monitoring of these pumps. For example, if a pump is running under improper conditions, the torque transmitted from the motor to the pump will be influenced. Non-stationary torque changes cause non-stationary changes in the rotor speed inducing amplitude modulation of the motor current. In [9], motor currents are analyzed to detect some of the faults that occur in centrifugal pumps, namely, partial flow operation, reverse rotation, disturbed inflow condition, cavitation, air suction and bearing failures. The energy content of the current signal in the frequency range of 2 Hz to 10 Hz is considered as an indicator. Depending on the changes in the noise floor level in certain operating regions of the pump, the above-mentioned faults are diagnosed.

The work in [10] deals with the development of a multi-model fault diagnosis system of an industrial pumping system. The system under consideration is a seawater pumping system in operation at the Nuclear Electric “Heysham 2” power station. The system is based around the operation of two centrifugal pumps with associated valves, motors and pipework. This system can have two different type of faults; incipient, slowly-developing faults whose effects may be difficult to distinguish from normal operating condition changes and abrupt severe faults which must be detected immediately. A detailed nonlinear and linear simulation model of the two-pump system is developed, of which the linear model is used as the basis for fault detection and isolation. Two different approaches to model-based fault detection are outlined based on observers and parameter estimation. For the observer based methods, the motor current, the suction and the discharge pressures are monitored. A vector of residuals was formed from the outputs of the observer and the actual outputs (in these cases, simulations). The deviation of these residuals from zero indicates the presence of a fault. Similarly a simplified model was developed for parameter estimation case. The relationship between the model coefficients and the physical parameters of the system was developed. Residual signals were formed by comparing each on-line calculated parameter with the respective known parameter values derived from known fault free situations. The results showed that the majority of these faults were identified by their effect on the different residuals. The authors also point out that the observer method and the parameter estimation method can be combined for more effective fault diagnosis.

In [11], the motor current is used as a diagnosing signal to estimate the following faulty conditions in pumps:
cavitation (including low-level cavitation as a separate fault),
blockage (including low-level blockage as a separate fault) and
damaged impeller.

Fault signatures are established by relating the spectral features to individual faults and by analyzing their behaviour in the presence of faults. Eight attributes are chosen to characterize the three faults considered. A fuzzy logic system is then designed to classify the faults. The consistency of the selected attributes is established so that they could be used as inputs to the fuzzy logic system, which performs the evaluation based on the rules set and finally makes a decision on the pump condition. The fuzzy logic system is developed using data collected from a centrifugal pump and is tested and evaluated with data collected from another centrifugal pump. The probability of fault detection varies from 50% to 93%. The authors finally conclude that adjustments to the rules or the membership functions are required so that differences in the pump design and operating flow regimes can be taken into consideration. They also point out that, in industrial setups the pump type, size and performance specifications are fixed and are unlikely to undergo any change.

In [12, 13], electrical signature analysis (ESA) is extended to condition monitoring of aircraft fuel pumps. While considerable amount of data are acquired from both main and auxiliary pumps, the data analysis is concentrated on data obtained from the auxiliary pumps. Among the various degraded conditions observed, the bearing wear is selected to demonstrate the effectiveness of ESA in determining the pump condition. Moreover, inspection of the auxiliary pumps shows that the front bearing wear is more common than the rear bearing wear, since the front bearing/journal clearance is mostly greater than the rear bearing/journal clearance in almost all the cases considered. After considerable study, it is established that the best indicator of front bearing wear in the motor current spectrum is not any specific frequency peak but is the base or floor of the spectrum. The noise floor of the demodulated current spectrum at dead-head (zero flow) conditions is observed to increase in all the pumps having degraded front bearings. The authors also point out that methods for detecting other pump degradations would be developed.

In [14], a model-based approach using a combination of structural analysis, observer design and analytical redundancy relation (ARR) design is used to detect faults in centrifugal pumps driven by induction motors. Structural considerations are used to divide the system into two cascaded connected subsystems. The variables connecting the two subsystems are estimated using an adaptive observer derived from the equations describing the first subsystem. The fault detection algorithm is based on an ARR which is obtained using Groebner basis algorithm. Four different types of faults, namely, clogging inside the pump, dry running, rub impact and cavitation are staged to test the validity of the algorithm. The measurements used in the development of the fault detection method are the motor terminal voltages and currents and the pressure delivered by the pump.

In [15], a fault detection scheme has been discussed, which assumes that the torque and the speed of the motor can be measured and that either the differential pressure between the suction and discharge, or the pump flow can be measured. The measured process variable is compared to that which is computed based on the motor speed and torque. An important point to note is that, an inherent assumption is made regarding the health of the motor. It is assumed that the motor is healthy. The measured parameters also change if the motor develops a fault or if the load level is changed.

In [16], a diagnosis scheme to detect the low flow and/or cavitation condition in centrifugal pumps using the current and the voltage data of the motor is patented. These signals are conditioned, which includes amplification, anti-aliasing, etc. They are sampled at a rate of approximately 5 kHz. From the sampled voltage and the current signals, a power signal is determined by multiplying the voltage and the current values. The power signal is then re-sampled to 213.33 Hz. This signal is then used to compute a 1024 point FFT, with a frequency resolution of around 0.208 Hz. The spectral energy within the band of about 5 to 25 Hz is calculated and the noise energy in this region is compared to the baseline signal. If the difference exceeds a certain fixed threshold value, a warning signal is raised. The authors also propose an alternate method for detecting the low flow/cavitation using a digital band-pass filter as opposed to an FFT to generate the output that represents the energy content around the 5 to 25 Hz range. In this case though, the signal is re-sampled to 500 Hz and the region of interest is reduced to 5 to 15 Hz as the filter must attenuate frequencies over 25 Hz without a complex transfer function. In [17], the authors describe a fault detection system for diagnosing potential pump system failures using fault features extracted from the motor current and the predetermined pump design parameters.

Most of the literature presented above deal with detecting pump faults either by using vibration and process measurements or by using physics based models. The drawbacks of using vibration and process sensors were outlined earlier and the need to avoid mechanical sensors was established. The models developed depend on the pump design parameters, which are not easily available and hence the detection schemes presented in the literature are not easily portable to other pump systems. Some of the studies however, use motor electrical signals to detect pump faults, but these detection schemes are based on either tracking the variation of the characteristic fault frequency or computing the change in the energy content of the motor current in certain specific frequency bands. The fault frequency depends on the design parameters, which are again not easily available. For example, the rolling element bearing fault frequency depends on the bearing diameter, pitch, number of rollers, etc. This information is not available, unless the pump is dismantled. Changes in the energy content of certain frequency bands could also result due to changes in the power supply or changes in the load even without any fault in the pump. Hence, this would result in the generation of frequent false alarms. Moreover, none of the literature mentioned above deal with the distinction between motor and pump faults.

D. Research Objectives

Based on the previous section, it can be seen that there is not only a strong need to develop a non-intrusive/non-invasive and sensorless fault detection algorithm to detect faults in centrifugal pumps but also the developed scheme must be insensitive to false alarms and must be independent of the motor and pump design parameters. Moreover, a fault isolation scheme has to be developed to distinguish between motor faults and pump faults. The research objectives can be summarized as follows:
Develop a sensorless fault detection and isolation method to
   detect faults in centrifugal pump.
   distinguish between motor faults and pump faults.
The desired performance characteristics are:
   exhibit high probability of fault detection.
   exhibit low probability of false alarms.
   continuous monitoring system.
   independent of motor and pump design information.

E. Proposed Approach

The objectives of the proposed research can be achieved by dividing them into three phases, which are as explained below:
1. Phase 1: The first task consists of controlled experiments of the various anticipated healthy conditions of the centrifugal pump. The pump curves at the healthy state of the pump will be established through these experiments and the best efficiency region of the pump will be determined. Performance metrics pertaining to the cavitation conditions will be established in order to approximately quantify the effects of operational faults in centrifugal pumps.
2. Phase 2: In this phase, the motor line currents and line voltages will be sampled and analyzed to extract fault features pertaining to the operational and structural problems of the pump. The first step would be to carry out signal segmentation of the motor currents and analyze only the stationary parts of the signal. Digital signal processing techniques such as FFT analysis will be used to extract the different fault features. The second step will be to develop a generalized early fault detection scheme based on the extracted fault features. This will be based on recent work in [18, 19] that describes the development of a sensorless system for the detection of both mechanical and electrical incipient faults developing in induction motors. The detection effectiveness of the system has been experimentally demonstrated on motors of varying power rating [18]. Furthermore, the false alarm reduction effectiveness of the system has also been experimentally demonstrated [19].
3. Phase 3: This is the final phase, which deals with the design of a fault isolation algorithm to distinguish between faults occurring in the pump and the motor. Higher order spectra will be used to distinguish between motor and pump faults.

F. Research Contributions

This work concentrates on developing and validating a sensorless fault diagnosis algorithm for centrifugal pumps that is based on the analysis of the motor currents and voltages only and it is independent of a priori motor and pump model and/or parameters. The contributions of this work can be summarized as follows:
Use of the motor currents and voltages to detect some of the most commonly encountered faults in centrifugal pumps.
Design and evaluation of a fault isolation scheme, to differentiate between faults in centrifugal pumps and motors that are used to drive them.
The fault detection and isolation algorithms are:
   insensitive to motor electric power supply variations.
   insensitive to pump load changes or load fluctuations.
   independent of a priori motor and pump models and/or design parameters.

Thus the proposed fault diagnosis approach is considered quite portable to motor-pump systems of different size and manufacturer.

### II. Overview of Fault Detection Methods

A. Introduction

Maintenance practices employed in various industries have varied over the past decade. These practices can be broadly classified as
Reactive Maintenance: This is basically the “run till failure” approach. No maintenance action is taken until the equipment fails and once the equipment breaks down it is either repaired or replaced depending on the amount of budget allocated. Although it may seem that money is being saved on maintenance costs and labor costs, actually more money is spent in the long run on the repair costs and the purchase of new equipment. The life of the equipment is actually shortened while waiting for the equipment to break-down. This results in more frequent equipment replacements. One of the major concerns of this approach is the unplanned downtime of equipment resulting in loss of production and hence reactive maintenance results in equipment being operated inefficiently for extended periods resulting in increased energy costs.
Preventive Maintenance: This refers to routine scheduled maintenance. Equipment are tested for their performance on a time-based schedule or are tested based on the machine run-time. Although this type of maintenance procedure is better than reactive maintenance, it still cannot prevent unplanned downtime of equipment and includes unnecessary maintenance activities which might result in the damage of other components.
Predictive or Proactive Maintenance: This approach is based on the fact that

TABLE I
Maintenance procedures employed in industry [28].

| Maintenance Procedure | Percentage (%) |
|---|---|
| Reactive Maintenance | 55% |
| Preventive Maintenance | 31% |
| Predictive Maintenance | 12% |
| Other | 2% |

equipments are periodically or continuously monitored and if any anomaly is detected, maintenance is scheduled. Predictive maintenance differs from preventive maintenance because the maintenance needs are based on the actual condition of the equipment rather than some pre-determined schedule. This method can substantially reduce the unplanned downtime of equipment thereby enabling greater plant availability and smoother plant operations. In addition it can enhance energy efficiency by reducing the time equipments operate with damaged components. This approach is also referred to as Condition Based Maintenance (CBM).

Recent studies [28] indicate that the predominant form of maintenance procedures employed in industries is still reactive maintenance. Table I gives a breakdown of the maintenance programs used in various industries. The present work primarily deals with formulating a centrifugal pump fault detection and isolation method that can be used within a continuous CBM system.

The different detection scenarios available for any fault detection method are shown in FIG. 7 It can be concluded that, for the fault detection method to perform effectively, it must exhibit a high probability of fault detection and a low probability of false alarms. If the detection scheme is too sensitive then it is likely to generate false alarms which in turn would lead to operators questioning the effectiveness of the algorithm. At the same time if the detection scheme is too insensitive, the false alarms will be reduced but then there is a chance of missing anomalies and faults that might lead to a failure. Missed faults may lead to critical equipment failures leading to downtime. As a result, a balance must be achieved in designing a fault detection scheme that is sensitive to faults but insensitive to false alarms.

B. Classification of Fault Detection Methods

The fault detection methods can be broadly classified into two groups, namely, signal-based fault detection methods and model-based fault detection methods. A brief overview of the two methods are described in the following two subsections.

### 1. Signal-Based Fault Detection Methods

Signal-based fault detection techniques are based on processing and analyzing raw system output measurements, such as motor currents, vibration signals and/or other process-based signals. No explicit system model is used in these techniques. Fault features are extracted from the sampled signals and analyzed for the presence or lack of a fault. The basic schematic of a signal-based fault detection method is as shown in FIG. 18.

The output measurements are the sampled signals that are analyzed to check for the presence or lack of a fault within the system. However, these system output signals are impacted by changes in the operating conditions that are caused due to changes in the system inputs and disturbances. Hence, if one were to analyze only the system output signals for the presence of a fault, then it would be difficult to distinguish the fault related features from the input and disturbance induced features. This would result in the generation of frequent false alarms, which would in turn result in the plant personnel losing confidence over the fault detection method. If the system inputs are considered to be ideal, i.e.,there are no changes in the input and a constant input is supplied to the system and the disturbances are also assumed to be constant, then the signal-based detection schemes can be used in the detection of system faults with 0% false alarm rates. However, in reality such a case is not possible. The input variations cannot be controlled and harmonics are injected into the system inputs due to various reasons. Moreover, the system disturbances are also never constant. Hence these variations affect the system output signals and result in the generation of false alarms.

### 2. Model-Based Fault Detection Methods

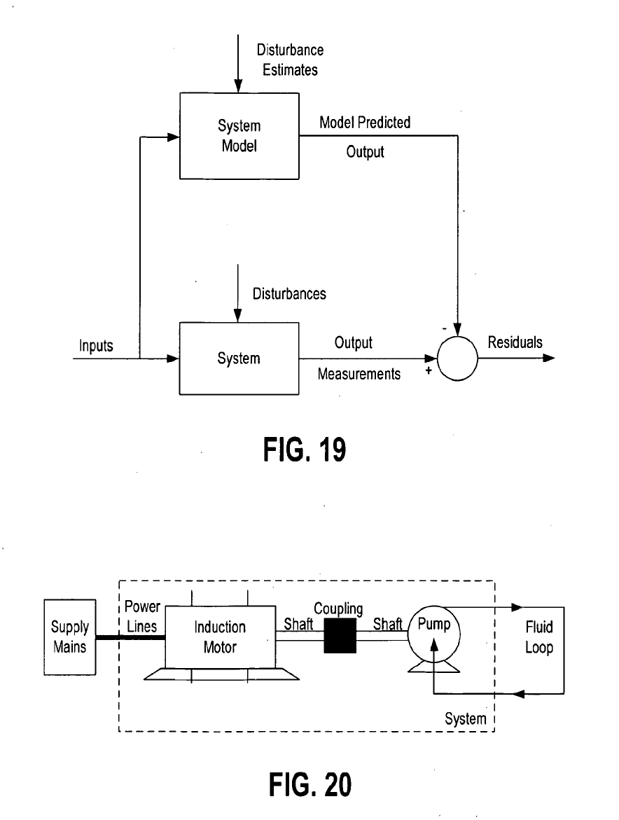

The framework of a model-based fault detection method is as shown in FIG. 19. The basic principle of a model-based fault detection scheme is to generate residuals that are defined as the differences between the measured and predicted outputs. The system model could be a physics-based model or an empirical model of the actual system being monitored. The model defines a relationship between the system outputs and the system faults, system disturbances and system inputs. The measured variables are the system inputs and outputs and the predicted variables are the outputs of the system model. Ideally, these residuals are only affected by the system faults and not affected by any changes in the operating conditions due to changes in the system inputs and disturbances. That is, the generated residuals are only sensitive to faults while being insensitive to system input or disturbance changes [29]. If the system is “healthy”, then the residuals would be approximated by white noise. Any deviations of the residuals from the white noise behavior could be interpreted as a fault in the system.

In [30], signal-based and model-based fault detection schemes are compared to a flip-of-a-coin fault detector as applied to induction motor fault detection. The results of the study can be extended to centrifugal pump fault detection also. Receiver operating characteristic (ROC) curves are plotted for all the three types of detection schemes and their performances are compared with respect to the probability of false alarms and probability of fault detection. For false alarm rates of less than 50%, the flip-of-a-coin fault detector outperformed the signal-based detection scheme for the cases under consideration. It was possible to achieve 100% fault detection capability using the signal-based fault detection method, but at the same time there was a very high probability of false alarms (about 50%). On the contrary, the model-based fault detection method operated with 0% false alarm rates and had approximately 89% of fault detection capability. If the constraint on the false alarm probability was relaxed to about 10%, then it was possible to achieve 100% fault detection capability using the model-based detection technique.

### C. The Basic Principle of Detecting Pump Faults Using Motor Electrical Signals

To obtain a better and an intuitive understanding of a fault detection method developed in this research, consider the system shown in FIG. 20. The system under consideration consists of a driver and a driven load. In this work, the driver is an induction motor and the driven load is a centrifugal pump. The pump is connected to the motor by means of a mechanical coupling. If the motor and the pump are both “healthy”, then the system would perform as per the design specifications. The output of the motor, which is the torque produced, would be as expected. Similarly, the outputs of the pump, which are the flow rate and the pressure difference would be as per the characteristics curves of the pump provided by the manufacturer. However, if the motor is faulty then the output torque would not be the same as compared to a “healthy” motor and would have extra harmonics pertaining to the fault. Similarly, if the pump is not “healthy”, then it would not be able to produce the required work horsepower. Moreover, the torque transmitted from the motor to the pump will also be influenced through the pump speed. Hence, a fault in either the pump or the motor will affect the torque produced by the induction motor. Any changes in the motor torque will be reflected as changes in the motor currents. Hence fault detection schemes based on analyzing the motor currents to detect centrifugal pump faults have gained significant importance and attention over the last few years. In this study, the basic principle of model-based fault detection schemes previously used for detecting motor faults, is used in the development of techniques to detect pump faults.

Based on the above discussions, it can be concluded that a model-based fault detection scheme outperforms a signal-based fault detection schemes as regards to the generation of false alarms. The objective of this work is to develop a method that would be capable of detecting centrifugal pump faults with detection effectiveness of greater than 90% and 10% or lower rate of false alarms. Moreover, the use of sensors is to be avoided and only the motor electrical signals, which can be sampled using standard industrial installations, are to be used in the development of the method.

### III. Proposed Fault Detection and Isolation Method

### A. Proposed Model-Based Fault Detection Scheme

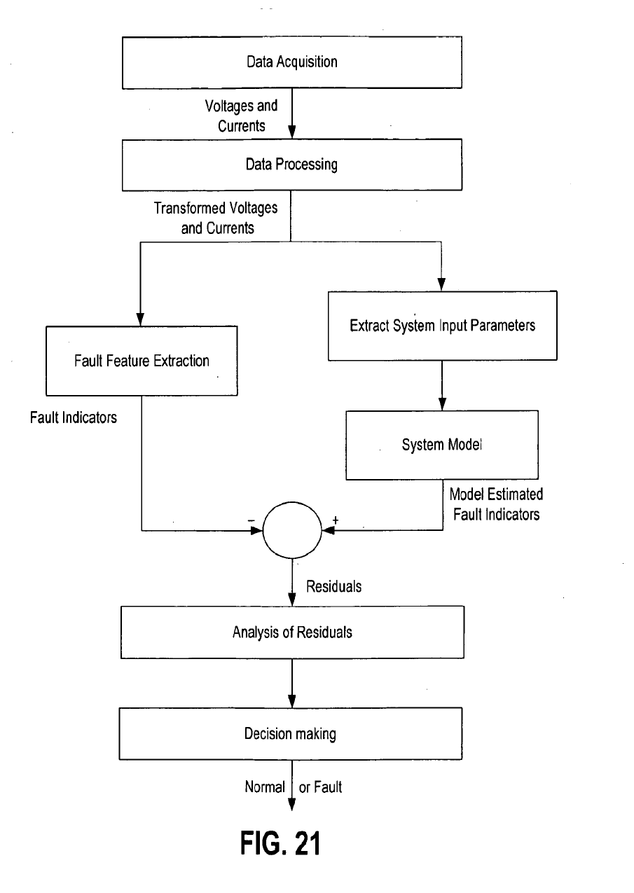

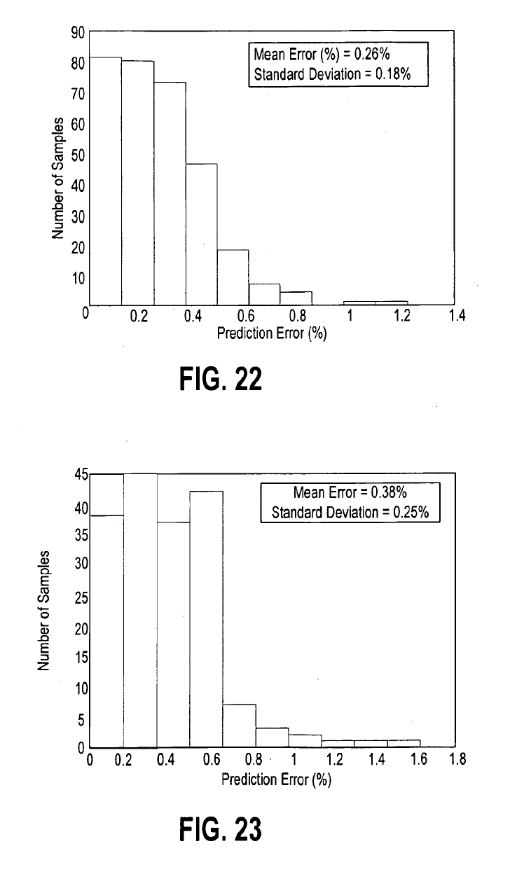

The framework of the proposed model-based fault detection scheme is the same as that shown in FIG. 19 except that the system under consideration is an induction motor-centrifugal pump system and the system model is empirically obtained. The flowchart for the proposed model-based fault detection method is shown in FIG. 21.

The data acquisition block consists of sampling the motor electrical signals and vibration signals from the motor-pump system. The electrical signals (three phase currents and three line voltages) and the vibration signals (x, y and z-axis vibration signals) are sampled simultaneously, for comparison purposes.

The data preprocessing block includes downsampling the sampled signals to lower frequencies for further processing. The downsampled signals are further scaled to per-unit values. This demonstrates the feasibility of applying the fault detection algorithm to motor-pump systems of different power ratings and different make and manufacturers. In other words, since the fault detection method uses only the per unit values of the electrical signals, the algorithm can be applied to systems with any rated voltage and rated current. The scaling factors used to convert the signal to per-unit values are obtained during the training phase of the model development. Only the rated voltage, rated current and the CT and PT turn ratios are required to obtain these scaling factors. These constitute nameplate information and are easily accessible in most industrial facilities.

### 1. Description of the Fault Detection Indicator

As mentioned earlier, any change in the system load would induce harmonic changes in the motor torque which would in turn induce harmonic changes in the motor current. Most of the available literature is based on extracting and tracking the variation of the characteristic frequency associated with a particular fault in the system. There are two main disadvantages associated with this approach. One is the fact that motor and/or pump design parameters or physical model parameters are required to obtain such characteristic frequencies. Secondly, owing to the non-stationary nature of the motor electrical signals, tracking one frequency component for fault detection would enable successful identification of the fault but this would also lead to the generation of large number of false alarms. To counter the above-mentioned drawbacks the proposed fault indicator is defined as follows:

$$Fault Detection Indicator ( FDI ) = \frac{1}{3 } {\sum }_{a , b , c} \frac{\sum {I}_{k }^{2}}{{I}_{f}^{2}} , \qquad ( 4.1 )$$

where a, b and c are the three phases of the motor current, Iₖ is the RMS value of the k^{th} harmonic component in the motor current, I_{f} is the fundamental frequency component of the motor current and fₛ is the sampling frequency of the signal.

### 2. Model Input Parameters

The inputs to the system model are various transformed signals computed from the raw voltages and raw currents such as voltage level, voltage imbalance, etc.

The voltage level is computed by obtaining the average of the voltage RMS of the three phases. The typical voltage level range is from 0.9 p.u. to 1.1 p.u., where 1.0 p.u. is the rated voltage level. The voltage RMS is computed using the formula given below:

$$Voltage RMS = \sqrt{\frac{1}{N} {\sum }_{i = 1}^{N} {V}_{i }^{2}} , \qquad ( 4.2 )$$

where Vᵢ is the i^{th} sample of the voltage signal and ‘N’ is the total number of samples. Overvoltage is defined as an increase in the voltage level greater than 110% at the rated frequency for a duration longer than 1 minute. Similarly an undervoltage is a decrease in the voltage level to less than 90% at the rated frequency for a duration of longer than 1 minute. Overvoltages are usually due to load switching such as switching off a large load or energizing a capacitor bank. Overvoltages are caused because either the system is too weak to handle the desired voltage regulation or the voltage controls are inadequate. Undervoltages occur as a result of events that are opposite to the events causing overvoltages [31].

The average value of the motor current RMS over the three phases is also used as one of the inputs to the system model. The current RMS is computed using equation (4.2), except that Vᵢ is replaced with Iᵢ, which is the i^{th} sample of the motor current signal.

The typical voltage supply is usually well balanced in magnitude and phase. However, for many reasons, some degree of voltage imbalance occurs at the point of utilization that is varying with time. Voltage imbalance is the achilles heel of rotating equipment and even a slight degree of imbalance could harm a three-phase equipment operating at full capacity. The national electrical manufacturer's association (NEMA) defines voltage imbalance as the maximum deviation from the average of the three phase voltages divided by the average of the three phase voltages. Voltage imbalance, expressed in percent, is given as follows:

$$Voltage Imbalance ( \% ) = \frac{max \vert {V}_{X}^{RM S} - {V}_{mean}^{R MS} \vert}{{V}_{mean}^{RM S}} \times 100 , \qquad ( 4.3 )$$

where Vₘₑₐₙ^{RMS} is the average of the three phase voltage and the subscript X stands for the three phases. The primary source of imbalance is the use of single phase loads on a three phase circuit. Voltage imbalance could also result from blown fuses. The impact of this problem is evident by the large industry in manufacturing of devices that monitor phase balance to protect motors. Any voltage imbalance of more than 5% is considered excessive.

Ideally, voltage and current waveforms must be perfectly sinusoidal in nature. However, due to the increase in electronic and other non-linear loads, these waveforms are distorted. This deviation from the ideal sine wave can be characterized by the spectral content of the deviation. There are basically four primary types of waveform distortion [31]:
DC Offset—The presence of a dc voltage in an ac power system is termed as dc offset. This can occur as a result of asymmetry of electronic power converters. The presence of dc offset could be detrimental to transformer cores, as they might saturate in normal operation due to the unwanted bias present. This could further lead to additional heating and loss of transformer life.
Integer and Inter Harmonics—Integer harmonics are sinusoidal voltages or currents having frequencies that are integer multiples of the fundamental frequency or the carrier frequency (usually 60 Hz). Interharmonics are those frequency components that are not integer multiples of the fundamental frequency. They can appear as discrete frequencies or as a wideband spectrum. The integer harmonics are due to the nonlinear characteristics of the devices and loads connected to the power system, whereas the sources of the interharmonic distortion are static frequency converters, induction motors, etc. Harmonic distortion levels in the signal can be characterized by means of a metric called the total harmonic distortion (THD). The THD, expressed in percent, is given as

$$Total Harmonic Distortion ( THD ) ( \% ) = \frac{1}{{V}_{f}} \sqrt{{\sum }_{k > 1}^{{k}_{ma x}} {V}_{k}^{2}} \times 100 , \qquad ( 4.4 )$$

where V_{f} is the RMS value of the fundamental frequency component and Vₖ is the RMS value of the k^{th} harmonic component. Since the magnitude of the integer harmonics are much higher than that of inter-harmonics, a different metric must be used to characterize the amount of distortion caused only by the inter-harmonics.
Notching—Notching is defined as the periodic voltage disturbances caused by the normal operation of power electronic devices when current is commutated from one phase to another. Since notching occurs continuously, it can also be characterized through the harmonic spectrum of the voltage. The frequency components of notching are very high.
Noise—Noise is defined as unwanted electrical signals with broadband spectral content lower than 200 kHz. These are superimposed upon the power system voltage or current phase conductors or found on neutral conductors or signal lines.

The signals are unbiased to remove the dc offset and are downsampled to lower frequencies to remove the effect of notching (if present) and high frequency noise.

### 3. Development of the Predictive Model

As described in the previous section, the model describes a relation between the baseline (or “healthy”) response of the system and the various system inputs. In other words, the model relates the time varying fault indicator as a function of the time varying system inputs. The model structure can be expressed as

FDI(k)=f(uᵢ(k), uᵢ(k−1), . . . , uᵢ(k−n)); i=1, . . . , N (4.5)

where “ƒ(.)” is the unknown function to be modeled, u(.) are the time series of the inputs, n is the net delay in the inputs, k is the discrete-time and N is the number of inputs used.

In this study, the function “ƒ(.)” is modeled as a polynomial of the various inputs taking the form of a polynomial NARX. The model parameters of the function “ƒ(.)” are to be estimated online during commissioning.

The accuracy of the model output depends on the nature (accuracy, volume, etc) of the raw data used in the training or estimation phase. Hence the system is operated in a sufficiently wide range to cover the entire operating envelope of interest. The proposed model is developed using data collected from the baseline system. The developed model predicts the baseline fault indicator estimate for a given operating condition characterized by the model inputs. The model is validated using data that are different from the one used in its development. The model prediction error is defined as

$$Error ( \% ) = \frac{\vert {y}_{i} - {\hat{y}}_{i} \vert}{\sqrt{{\sum }_{i = 1}^{N} {y}_{i}^{2}}} \times 100 ; i = 1 , … , N . \qquad ( 4.6 )$$

where yᵢ is the measured variable and ŷᵢ is the model predicted variable. FIG. 11 and FIG. 23 show the histogram of the prediction errors of the model at 20% and 40% of the rated load level, respectively.

No fault data are used to train the model. Hence for anomalies in the pump or motor, the output of the model will be the system baseline fault indicator for the given operating condition. No motor or pump design parameters are used in the development of the baseline model. Hence this model can be easily ported to other motor-centrifugal pump systems, as only the measured motor voltages and currents are used in model development. However, each motor-centrifugal pump system will have a different baseline model, which can be adaptively developed using the measured motor electrical signals.

### 4. Decision Making

The model predicted output is compared to the FDI extracted from the measured signals and the residuals between the two are computed. If the system is “healthy”, then the residual signal would be closed to a white noise signal. However, if there is a fault in the system, then the residual will deviate from the white noise behavior. If this deviation exceeds a certain threshold then a “fault” alarm is issued. Otherwise, the system is considered “healthy” and the procedure is repeated. If the detection threshold is chosen to be large, then although the false alarm rates are reduced, there is a very high probability of missing a fault. Similarly, if the detection threshold is chosen very small then along with good fault detection capability, there is a very high probability of generating false alarms. Hence a balance has to be achieved in deciding the detection threshold. One factor in choosing the threshold is the intended application of the detection method or the system that is being monitored. For example, in space applications a high rate of false alarms is acceptable as people's life are at stake. Hence the threshold can be chosen small to detect any anomaly. In utility industries however, false alarms are not tolerated and hence a somewhat higher threshold is preferred. The detection method might not detect the fault as soon as the fault initiates, but might detect it as the fault degrades and well before any catastrophic failure.

### B. Proposed Model-Based Fault Isolation Scheme

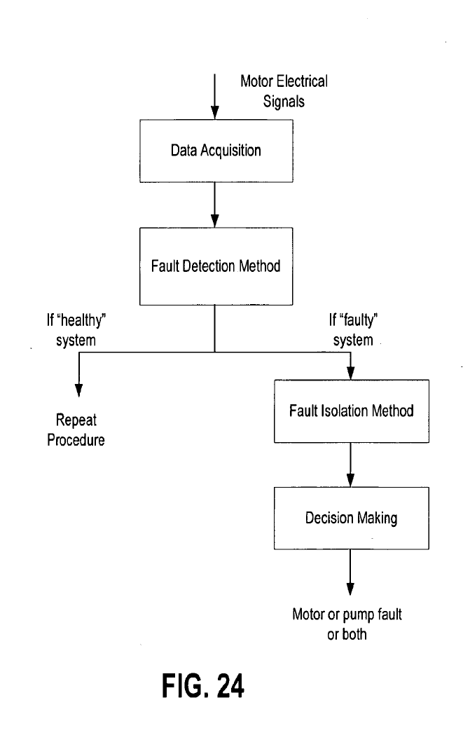

The output of the model developed in the previous section is affected by either a fault in the induction motor or a fault in the centrifugal pump or any other component affecting the motor output. For the purpose of this study only motor and pump faults are assumed. Hence, it is not possible to isolate a developing fault. To distinguish between faults in the motor and faults in the pump, a localized model of one of the components is required wherein the output of the model is affected only by the faults in that component and is insensitive to the faults in the other. In this study, since no measurement is available from the centrifugal pump, a localized model for the induction motor is developed. The output of this model is only sensitive to faults in the motor and is insensitive to faults in the centrifugal pump. FIG. 24 shows the overall schematic of the proposed fault detection and isolation method. The fault isolation method is used to distinguish between motor and pump faults only when a fault within the system is detected. If the system is “healthy”, then the next data set is analyzed to check for the presence or lack of fault and the fault isolation method is not used.

### 1. Development of the Localized Induction Motor Model

Consider an induction machine such that the stator windings are identical, sinusoidally distributed windings, displaced by 120°, with Nₛ equivalent turns and resistance, rₛ. Consider the rotor windings as three identical sinusoidally distributed windings displaced by 120°, with Nₛ equivalent turns and resistance, rᵣ. The voltage equations are given as

v_{abcs}=rₛi_{abcs}+pλ_{abcs} (4.7)

v_{abcr}=rᵣi_{abcr}+pλ_{abcr} (4.8)

where p is the first derivative operator, subscript s denotes variables and parameters associated with stator circuits, subscript r denotes the variables and parameters associated with the rotor circuits. rₛ and rᵣ are diagonal matrices each with equivalent nonzero elements and

(f_{abcs})^{T}=[fₐₛ f_{bs} f_{cs}]

(f_{abcr})^{T}=[fₐᵣ f_{br} f_{cr}] (4.9)

where f represents either voltage, current or flux linkages.

For a magnetically linear system, the flux linkages may be expressed,

$$[ \begin{matrix}{λ}_{abcs} \\ {λ}_{abcr}\end{matrix} ] = [ \begin{matrix}{L}_{s} & {L}_{sr} \\ {L}_{sr}^{T} & {L}_{r }\end{matrix} ] [ \begin{matrix}{i}_{abcs} \\ {i}_{abcr}\end{matrix} ] , \qquad ( 4.10 )$$

where Lₛ and Lᵣ are the winding inductances which include the leakage and magnetizing inductances of the stator and rotor windings, respectively. The inductance Lₛᵣ is the amplitude of the mutual inductances between the stator and rotor windings. Lₛ and Lᵣ are constants and Lₛᵣ is a function of the mechanical rotor position, θₘ(t) Details of the variables are described in [32].

The vast majority of induction motors used today are singly excited, wherein electric power is transformed to or from the motor through the stator circuits with the rotor windings short-circuited. Moreover, a vast majority of single-fed machines are of the squirrel-cage rotor type. For a squirrel cage induction motor, v_{abcr}=0. Substituting equation (4.10) into equations (4.7) and (4.8), we get,

v_{abcs}=rₛi_{abcs}+Lₛ(pi_{abcs})+(pLₛᵣ)i_{abcr}+Lₛᵣ(pi_{abcr}), (4.11)

0=rᵣi_{abcr}+(pLₛᵣ^{T})i_{abcs}+Lₛᵣ^{T}(pi_{abcs})+Lᵣ(pi_{abcr}). (4.12)

At steady-state, equations (4.11) and (4.12) can be expressed as,

\tilde{V}ₛ(t)=(rₛ+jwₛLₛ)Ĩₛ(t)+(jwₛLₛᵣ)Ĩᵣ(t), (4.13)

0=jwᵣLₛᵣ^{T}\tilde{T}ₛ(t)+(rᵣ+jwᵣLᵣ)Ĩᵣ(t). (4.14)

The detailed derivation can be found in [32].

In equation (4.14), assuming that (rᵣ+jwᵣLᵣ) is invertible, Ĩᵣ(t) can be expressed as,

$${\hat{I}}_{r} ( t ) = - \frac{j {ω}_{r} {L}_{sr}^{T}}{{r}_{r} + j {ω}_{r} {L}_{r}} {\tilde{I}}_{s} ( t ) . \qquad ( 4.15 )$$

Substituting equation (4.15) into equation (4.13), we have,

$${\tilde{V}}_{s} ( t ) = ( {r}_{s} + j {ω}_{s} {L}_{s} + \frac{{ω}_{s} {ω}_{r} {L}_{sr} {L}_{sr}^{T}}{{r}_{r} + j {ω}_{r} {L}_{r}} ) {\tilde{I}}_{s} ( t ) . \qquad ( 4.16 )$$

Assuming

$$( {r}_{s} + j {ω}_{s} {L}_{s} + \frac{{ω}_{s} {ω}_{r} {L}_{sr} {L}_{sr}^{T}}{{r}_{r} + j {ω}_{r} {L}_{r}} )$$

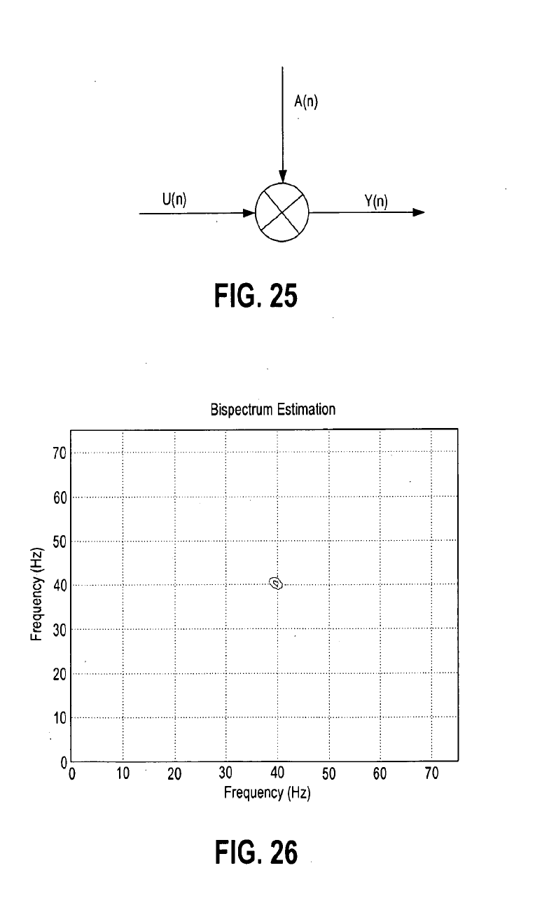

in invertible, the following relationship between stator voltages and currents can be obtained,

$$\begin{matrix}{\tilde{I}}_{s} ( t ) = {[ {r}_{s} + j {ω}_{s} {L}_{s} + \frac{{ω}_{s} {ω}_{r} {L}_{sr} {L}_{sr}^{T}}{{r}_{r} + j {ω}_{r} {L}_{r}} ]}^{- 1} {\tilde{V}}_{s} ( t ) . & ( 4.17 ) \\ {\tilde{I}}_{s} ( t ) = {[ Z ]}^{- 1} {\tilde{V}}_{s} ( t ) . & ( 4.18 )\end{matrix}$$

where Z is a function of the machine parameters which in turn are functions of the mechanical rotating angle of the rotor, θₘ(t). Equation (4.18) represents a modulator wherein the current spectrum will be composed of both the input voltage frequencies and also other frequency components due to the modulation. The modulated frequencies will appear as side-bands in the current spectrum around each frequency component corresponding to the input voltage signal. Hence an induction motor can be generalized as a modulator as shown in FIG. 25, where U(n) is the system input, the stator voltages, A(n) is the signal containing the spatial harmonics of the motor and Y(n) is the system output, the stator currents.

Any fault in the rotor of the induction motor or in the motor bearings would result in the generation of additional spatial irregularities. This would induce additional spatial harmonics in the motor air-gap flux. These additional harmonics would modulate the voltage frequencies and appear as sidebands in the stator current spectrum. Higher order spectra are used to detect these modulated frequencies in the stator current spectrum.

### 2. Use of Higher Order Spectra Analysis

Higher-order spectra is a rapidly evolving signal processing area with growing applications in science and engineering. The power spectral density or the power spectrum of deterministic or stochastic processes is one of the most frequently used digital signal processing technique. The power spectrum estimation methods can be classified into a number of different categories, namely, maximum-likelihood methods, maximum-entropy methods, harmonic decomposition methods, etc. In power spectrum estimation, the process under consideration is treated as a superposition of statistically uncorrelated harmonic components and the distribution of power among these frequency components is then estimated. The phase relationships between frequency components are suppressed. The information contained in the power spectrum is essentially present in the autocorrelation sequence. This is sufficient for the complete statistical description of a Gaussian process of known mean. However, there are practical situations where the power spectrum or the autocorrelation domain is not sufficient to obtain information regarding deviations from Gaussianness and the presence of nonlinearities in the system that generates the signals. Higher order spectra (also known as polyspectra), defined in terms of higher order cumulants of the process, do contain such information. Particular cases of higher order spectra are the third-order spectrum also called the bispectrum, defined as the Fourier transform of the third-order cumulant sequence of a stationary random process, and the trispectrum (fourth-order spectrum), which is the Fourier transform of the fourth-order cumulant sequence of a stationary random process. The power spectrum is, in fact, a member of the class of higher order spectra, i.e., it is the second-order spectrum [33].

The main reasons for using higher order spectral analysis in signal processing are itemized below [33]:
to suppress Gaussian noise processes of unknown spectral characteristics in detection, parameter estimation and classification problems; the bispectrum also suppresses non-Gaussian noise with symmetrical probability density function (pdf),
to reconstruct the phase and magnitude response of signals or systems, and
to detect and characterize the nonlinearities in time series.

In this study higher order spectra are used to detect the phase relationship between harmonic components that can be used to detect motor related faults. One of the most widely used method in detecting phase coupling between harmonic components is the bispectrum estimation method. In fact, bispectrum is used in detecting and characterizing quadratic phase coupling.

Consider a discrete, stationary, zero-mean random process, x(n). The bispectrum of x(n) is defined as

$$\begin{matrix}B ( {ω}_{1} , {ω}_{2} ) = {\sum }_{{τ}_{1} = - ∞}^{∞} {\sum }_{{τ}_{2} = - ∞}^{∞} c ( {τ}_{1} , {τ}_{2} ) exp [ - j ( {ω}_{1} {τ}_{1} + {ω}_{2} {τ}_{2} ) ] , \\ where , & ( 4.19 ) \\ c ( {τ}_{1} , {τ}_{2} ) = E [ x ( n ) x ( n + {τ}_{1} ) x ( n + {τ}_{2} ) ] , & ( 4.20 )\end{matrix}$$

where E[.] denotes the expectation operator. A class of techniques named “direct” can be used to estimate the bispectrum. This technique uses the discrete fourier transform (DFT) to compute the bispectrum as follows:

B(k₁,k₂)=E[X(k₁)X(k₂)X*(k₁+k₂)], (4.21)

where X(k) is the DFT of x(n).

From equation (4.21), it can be concluded that the bispectrum only accounts for phase couplings that are the sum of the individual frequency components. However, motor related faults manifest themselves as harmonics that modulate the fundamental frequency and appear as sidebands at frequencies given by |fₑ±mf_{υ}|, where fₑ is the fundamental frequency and f_{υ}is the fault frequency. Hence, the bispectrum estimate given by equation (4.21) detects only half of the coupling, as it does not detect the presence of the other half given by the difference of the two frequency components. Moreover, information about the modulation frequency has to be known to use this bispectrum estimate correctly. This point can be illustrated with the following example. Consider the following two signals,

x₁(n)=cos(2π60n+φ₁) (4.22)

x₂(n)=B+cos(2π20n+φ₂) (4.23)

where, φ₁ and φ₂ are arbitrary phase angles. The signal, x₁(n) is considered to be an unbiased signal as is the case in power system applications. In this example, x₁(n) is analogous to the carrier signal and x₂(n) is analogous to the signal that modulates the carrier signal. The product of these two signals results in,

$$\begin{matrix}x ( n ) = {x}_{1} ( n ) {x}_{2} ( n ) \\ = B cos ( 2 π60 n + {φ}_{1} ) + cos ( 2 π 60 n + {φ}_{1} ) cos ( 2 π 20 n + {φ}_{2} ) \\ = B cos ( 2 π 60 n + {φ}_{1} ) + \frac{1}{2} cos ( 2 π 80 n + {φ}_{1} + {φ}_{2} ) + \\ \frac{1}{2} cos ( 2 π 40 n + {φ}_{1} - {φ}_{2} ) .\end{matrix} \qquad ( 4.24 )$$

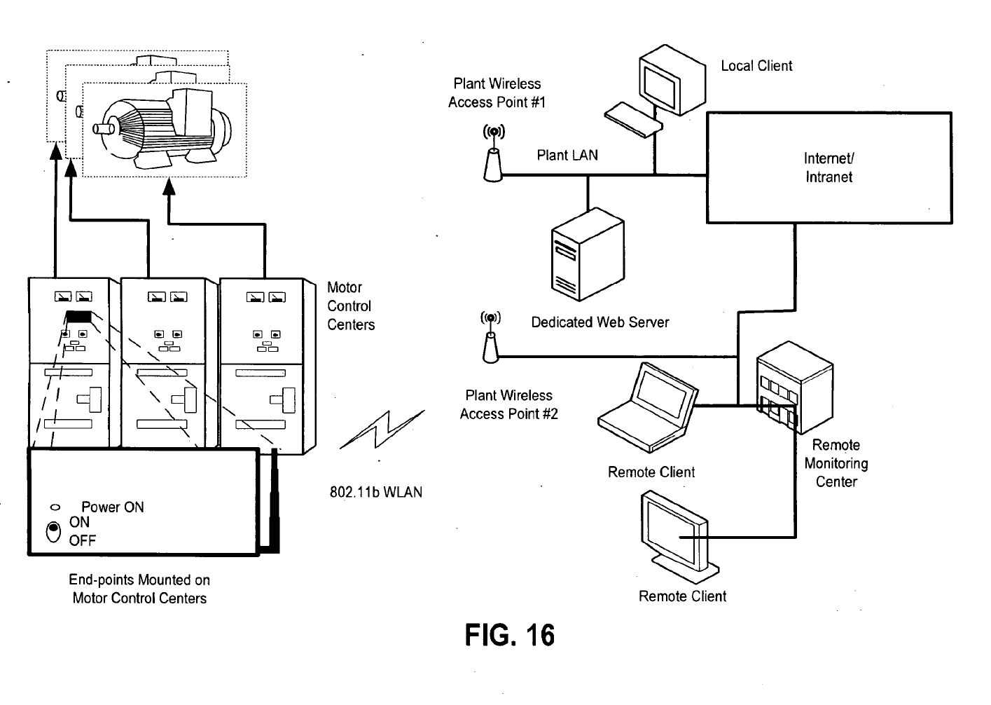

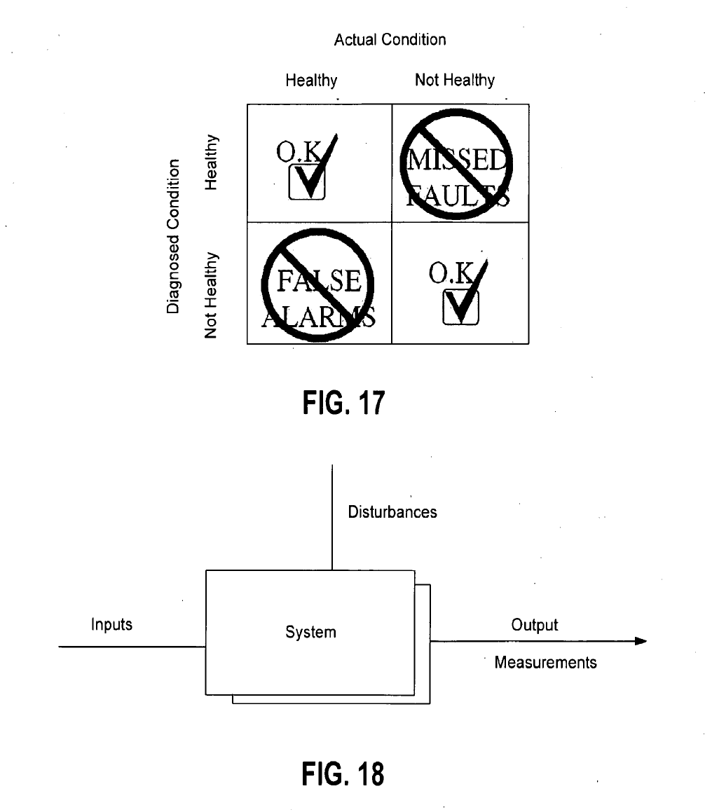

For simplicity, the constant B is assumed to be equal to 1. In the resultant signal, the 40 Hz and the 80 Hz components are obtained due to the modulation of the 20 Hz component with the 60 Hz carrier frequency. From equation (4.21), it can be concluded that for the bispectrum to correctly identify this modulation relationship, the carrier frequency and the modulation frequency information have to be known. However, in the example shown above, the final signal x(n), does not contain any information about the modulation frequency. Hence the bispectrum cannot be used to correctly identify the modulation relationship as is evident from FIG. 26. The bispectrum plot is typically displayed as a three-dimensional plot with frequency on the x and y axes and the magnitude on the z axis. For simplicity, this study uses two-dimensional contour plots with frequency on the x and y and the magnitude coming out of the page. FIG. 16 shows a peak at frequency pair (40 Hz, 40 Hz), indicating that the signal is made up of only 40 Hz frequency component and that 40 Hz is the modulation frequency, which is not the case. Hence to correctly identify the modulation relationship, a modified bispectrum estimator is used [34].

The modified bispectrum estimator also referred to as the amplitude modulation detector (AMD) is defined as follows:

A\hat{M}D (k₁,k₂)=E[X(k₁+k₂)X(k₁−k₂)X*(k₁)X*(k₁)]. (4.25)

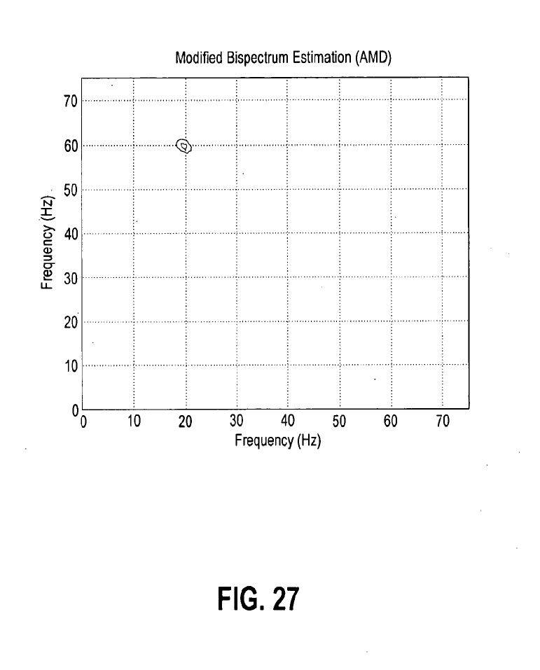

From equation (4.25), it can be seen that both the sidebands of the modulation are accounted for in the definition. FIG. 27 shows the modified bispectrum for the example considered in the previous subsection. The peak at the frequency pair (60 Hz, 20 Hz) indicates that the 20 Hz frequency component modulates the 60 Hz frequency component. Moreover, no information about the modulation frequency is utilized in computing the modified bispectrum. This is very useful since the motor related fault frequencies which modulate the supply frequency are very difficult to compute. These frequencies are dependent on the design parameters, which are not easily available. For example, the fault frequency pertaining to a motor rolling element bearing depends on the number of balls in the hearing, the ball diameter, the pitch diameter, etc. Hence it is desirable to design an algorithm which does not require the motor design parameters. Therefore, in this study, various forms of the AMD indicator depicted in equation (4.25) are used to detect motor related faults.

The reason that the AMD correctly identifies the modulation relationship is that it detects phase coupling. If phase coupling exists between frequency components, then the AMD component at those frequencies will have zero phase and maximum peak. To illustrate this, consider the equation (4.25) and represent it in terms of its phase and magnitude, as follows:

E[|X(k₁+k₂)|e^{j∠(k}^{₁}^{+k}^{₂}⁾|X(k₁−k₂)|e^{j∠(k}^{₁}^{-k}^{₂}^{)|X*(k}₁)|e^{-j∠(k}^{₁}⁾|X*(k₁)|e^{-j∠(k}^{₁}⁾] (4.26)

Rearranging the terms results in,

E[|X(k₁+k₂∥X(k₁−k₂)∥X*(k₁)∥X*(k₁)|e^{j(∠(k}^{₁}^{-k}^{₂}^{)+∠(k}^{₁}^{-k}^{₂}^{)-∠(k}^{₁}⁾⁾]. (4.27)

If there is phase coupling between the frequency components k₁ and k₂, then

∠(k₁+k₂)=∠(k₁)+∠(k₂), and (4.28)

∠(k₁−k₂)=∠(k₁)−∠(k₂). (4.29)

Substituting equations (4.28) and (4.29) in equation (4.27), results in zero phase and the final expression is the expectation of the product of the magnitudes. Hence, if the frequency components, k₁, k₁+k₂ and k₁−k₂ exists in the spectrum, and if there is phase coupling between the frequency components, k₁ and k₂, then the detector will exhibit a peak at AMD(k₁, k₂), indicating that frequencies k₁ and k₂ are modulated components.

The AMP spectrum is a two dimensional matrix. The frequency resolution of AMD can be calculated by

$$Δ f = \frac{{f}_{s}}{N} , \qquad [ 33 ]$$

where fₛ is the sampling frequency and N is the total number of samples. A good frequency resolution will lead to a large AMD matrix, which cannot be implemented easily and would require large memory and a very fast processor. In this study, we are interested only in the frequency components that are modulated with one specified frequency; for example, the supply fundamental frequency. Therefore, it is possible to use only a one dimensional AMD, to calculate the AMD spectra that are modulated only with the supply fundamental frequency.

The induction motor has been modelled as the modulator shown in FIG. 14. Any fault in the rotor or the motor bearings would lead to the generation of spatial harmonics which modulate the frequencies corresponding to the input voltage and manifest as sidebands in the motor current. Since the spatial harmonics pertaining to the fault are unknown, the AMD is used to detect if any such modulation relationship exists, which does not require any information about the modulation frequency component. Detailed derivations of these AMD indicators are given in [35].

C. Vibration-Based Signal Analysis

The effectiveness of the model-based scheme is compared to the effectiveness of a continuous vibration monitoring scheme. A tri-axial accelerometer is mounted on top of the pump to continuously monitor the vibration level of the pump, both during the normal operation and during the staged fault experiments. Similarly, an accelerometer is mounted on the motor close to the bearing housing to monitor the change in the vibration level as the motor bearing condition degrades. The vibration levels in the x, y and z directions are recorded and the aggregate vibration level is used as an indicator to detect the presence of a fault. The indicator is defined as follows:

$$Vibration Indicator ( VI ) = \frac{1}{3} {\sum }_{x , y , z} \sqrt{\frac{1}{N} {\sum }_{i = 1}^{N} {Vib}_{X , i}^{2}} \qquad ( 4.30 )$$

where Vib_{X,i} is the i^{th} sample of the vibration signal in the X direction, where X stands for the three axes x, y, z, and N is the total number of samples. Since the vibration level of the system varies after each re-assembly and cannot be controlled, a fixed threshold cannot be used for detection. Hence, an adaptive threshold is used. In this study, a multiple of the standard deviation of the baseline vibration is used as the detection threshold.

### REFERENCES

[1] J. E. McInroy and S. F. Legowski, “Using power measurements to diagnose degradations in motor drivepower systems: A case study of oilfiled pump jacks”, in IEEE Transactions on Industry Applications, vol. 37, no. 6, pp. 1574-1581, November/December 2001.
[2] L. Bachus and A. Custodio, Know and Understand Centrifugal Pumps. New York: Elsevier Advanced Technology, 2003.
[3] C. J. Dister, “On-line health assessment of integrated pumps”, in Aerospace Conference Proceedings, vol. 7, pp. 3289-3294, Montana, March 2003,
[4] J. A. Siegler, “Motor current signal analysis for diagnosis of fault conditions in shipboard equipment”, U.S.N.A—Trident Scholar Project Report, no. 220, U.S. Naval Academy, 1994.
[5] D. A. Casada, “Detection of pump degradation”, in 22nd Water Reactor Safety Information Meeting, Maryland, October, 1994.
[6] D. A. Casada and S. L. Bunch, “The use of the motor as a transducer to monitor pump conditions”, in P/PM Technology Conference, Indianapolis, Ind., December 1995.
[7] D. A. Casada, “Monitoring pump and compressor performance using motor data”, in ASME International Pipeline Conference, vol. 2, pp. 885-895, 1996.
[8] D. A. Casada and S. L. Bunch, “The use of the motor as a transducer to monitor system conditions”, in 50th meeting of the Society for Machinery Failure Prevention Technology, January 1996.
[9] T. Kenull, G. Kosyna and P. U. Thamsen, “Diagnostics of submersible motor pumps by non-stationary signals in motor current”, in ASME Fluids Engineering Division Summer Meeting, vol. 11, Jun. 22-26, 1997.
[10] T. Dalton and R. Patton, “Model-based fault diagnosis of a two-pump system”, in Transactions of the Institute of Measurement and Control, vol. 20, no. 3, pp. 115-124, 1998.
[11] S. Perovic, P. J. Unsworth and E. H. Higham, “Fuzzy logic system to detect pump faults from motor current spectra” in Proceedings of 2001 IEEE Industry Applications Society 36th Annual Meeting—IAS'01, vol. 1, pp. 274-280, September/October 2001.
[12] D. E. Welch, H. D. Haynes, D. F. Cox and R. J. Moses, “Electric fuel pump condition monitor system using electrical signature analysis”, U.S. Pat. No. 6,941,785, September 2005.
[13] H. D. Haynes, D. F. Cox and D. E. Welch, “Electrical signature analysis (ESA) as a diagnostic maintenance technique for detecting the high consequence fuel pump failure modes”, Presented at Oak Ridge National Laboratory, October, 2002.
[14] C. S. Kallesoe, V. Cocquemptot and R. Izadi-Zamanabadi, “Model based fault detection in dentrifugal pump application”, in IEEE Transactions on Control Systems Technology, vol. 14, no. 2, pp. 204-215, March 2006.
[15] E. P. Sabini, J. A. Lorene and O. Henyan, “Centrifugal pump performance degradation detection”, U.S. Pat. No. 6,648,606 B2, November 2003.
[16] S. C. Schmalz and R. P. Schuchmann, “Method and apparatus of detecting low flow/cavitation in a centrifugal pump”, U.S. Pat. No. 6,709,240 B1, March 2004.
[17] C. A. Harris, J. A. Schibonski, F. E. Templeton and D. L. Wheeler, “Pump system diagnosis”, U.S. Pat. No. 6,721,683 B2, April 2004.
[18] K. Kim, A. G. Parlos and R. M. Bharadwaj “Sensorless fault diagnosis of induction motors”, in IEEE Transactions on Industrial Electronics, vol. 50, no. 5, pp. 1038-1051, 2003.
[19] K. Kim and A. G. Parlos, “Reducing the Impact of False Alarms in Induction Motor Fault Diagnosis”, in Journal of Dynamic Systems, Measurement and Control, vol. 125, no. 1, pp. 80-95, 2003.
[20] http://www.cee.vt.edu/program_areas/environmental/teach/wtprimer/pumps/pumps.html. Accessed on Feb. 11, 2004.
[21] F. R. Spellman and J. Drinan, Fundamentals for the Water and Wastewater Maintenance Operator Series: Pumping. Lancaster: Technomic Publishing Company, 2001.
[22] http://www.energymanagertraining.com/eqp_ind_pumps.htm. Accessed on Jan. 21, 2004.
[23] S. Yedidiah, Centrifugal Pump User's Guidebook: Problems and Solutions. New York: International Thomson Publishing Company, 1996.
[24] http://www.hargrave.com.my/about_pumps.php?page=5. Accessed on Dec. 12, 2006.
[25] http://www.depcopump.com/catalog107/149.pdf. Accessed on Jan. 28, 2004.
[26] http://www.worldpumps.com/WZ/WorldPumps/latestfeatures/maintenance/000021/show. Accessed on Jan. 28, 2004.
[27] G. mendles and B. Larose, “Pump and seal failure analysis improves reliability, reduces costs”, in Enery-Tech Magazine, January 2007.
[28] http://www.eere.energy.gov/femp/operations_maintenance/strategies/strat_reactive.cfm. Accessed on Dec. 13, 2006.
[29] R. J. Patton and J. Chen, “Robustness in quantitative model-based fault diagnosis”, in IEE Colloquium on Intelligent Fault Diagnosis—Part 2: Model-Based Techniques, pp. 4/1-4/17, 1992.
[30] P. P. Harihara, K. Kim and A. G. Patios, “Signal-based versus model-based fault diagnosis—a tradeoff in complexity and performance”, in IEEE International Symposium on Diagnostics for Electric Machines, Power Electronics and Drives (SDEMPED 2003), pp. 277-282, Atlanta, Ga., Aug. 24-26, 2003.
[31] R. C. Dugan, M. F. McGranaghan, S. Santoso and H. W. Beaty, Electrical Power Systems Quality. New York: McGraw-Hill, 2003.
[32] P. C. Krause, O. Wasynczuk and S. D. Sudhoff, Analysis of Electric Machinery. New York: The Institute of Electrical and Electronics Engineers. Inc., 1995.
[33] C. L. Nikias and A. P. Petropulu, Higher-Order Spectra Analysis—A Nonlinear Signal Processing Framework. New Jersey: PTR Prentice Hall, 1993.
[34] J. R. Stack, R. G. Harley and T. G. Habetler, “An amplitude modulation detector for fault diagnosis in rolling element bearings”, in IEEE Transactions on Industrial Electronics, vol. 51, no. 5, pp. 1097-1102, October 2004.
[35] L. Wang, “Induction motor bearing fault detection using a sensorless approach”, Ph.D Dissertation, Mechanical Engineering, Texas A&M University, College Station, May 2007.
[36] J. R. Stack, “Experimentally Generating Faults in Rolling Element Bearings Via Shaft Current,” IEEE Transactions on Industry Applications, vol. 41, No. 1, January/February 2005.
[37] H. Prashad, “Diagnosis of Rolling-element Bearings Failure by Localized Electrical Current between Track Surfaces of Races and Rolling-elements,” Journal of Tribology, vol. 124, no. 3, pp. 468- 473, July 2002.
[38] D. F. Busse, J. M. Erdman, R. J. Kerkman, D. W. Schlegel, and G. L. Skibinski, “The Effects of PWM Voltage Source Inverters on the Mechanical Performance of Roller Bearings,” IEEE Transactions on Industry Applications, vol. 33, No. 2, pp. 567-576, March/April 1997.
[39] “IEEE standard test procedure for polyphase induction motors and generators”, IEEE Power Engineering Society, November 2004.

Any fault in the rotor of the induction motor or in the motor bearings would result in the generation of additional spatial irregularities. This would induce additional spatial harmonics in the motor air-gap flux. These additional harmonics would modulate the voltage frequencies and appear as sidebands in the stator current spectrum. Higher order spectra are used to detect these modulated frequencies in the stator current spectrum.

### 2. Use of Higher Order Spectra Analysis

Higher-order spectra is a rapidly evolving signal processing area with growing applications in science and engineering. The power spectral density or the power spectrum of deterministic or stochastic processes is one of the most frequently used digital signal processing technique. The power spectrum estimation methods can be classified into a number of different categories, namely, maximum-likelihood methods, maximum-entropy methods, harmonic decomposition methods, etc. In power spectrum estimation, the process under consideration is treated as a superposition of statistically uncorrelated harmonic components and the distribution of power among these frequency components is then estimated. The phase relationships between frequency components are suppressed. The information contained in the power spectrum is essentially present in the autocorrelation sequence. This is sufficient for the complete statistical description of a Gaussian process of known mean. However, there are practical situations where the power spectrum or the autocorrelation domain is not sufficient to obtain information regarding deviations from Gaussianness and the presence of nonlinearities in the system that generates the signals. Higher order spectra (also known as polyspectra), defined in terms of higher order cumulants of the process, do contain such information. Particular cases of higher order spectra are the third-order spectrum also called the bispectrum, defined as the Fourier transform of the third-order cumulant sequence of a stationary random process, and the trispectrum (fourth-order spectrum), which is the Fourier transform of the fourth-order cumulant sequence of a stationary random process. The power spectrum is, in fact, a member of the class of higher order spectra, i.e., it is the second-order spectrum [33].

The main reasons for using higher order spectral analysis in signal processing are itemized below [33]:
to suppress Gaussian noise processes of unknown spectral characteristics in detection, parameter estimation and classification problems; the bispectrum also suppresses non-Gaussian noise with symmetrical probability density function (pdf),
to reconstruct the phase and magnitude response of signals or systems, and
to detect and characterize the nonlinearities in time series.

In this study higher order spectra are used to detect the phase relationship between harmonic components that can be used to detect motor related faults. One of the most widely used method in detecting phase coupling between harmonic components is the bispectrum estimation method. In fact, bispectrum is used in detecting and characterizing quadratic phase coupling.

Consider a discrete, stationary, zero-mean random process, x(n). The bispectrum of x(n) is defined as

$$\begin{matrix}B ( {ω}_{1} , {ω}_{2} ) = {\sum }_{{τ}_{1} = - ∞}^{∞} {\sum }_{{τ}_{2} = - ∞}^{∞} c ( {τ}_{1} , {τ}_{2} ) exp [ - j ( {ω}_{1} {τ}_{1} + {ω}_{2} {τ}_{2} ) ] , \\ where , & ( 4.19 ) \\ c ( {τ}_{1} , {τ}_{2} ) = E [ x ( n ) x ( n + {τ}_{1} ) x ( n + {τ}_{2} ) ] , & ( 4.20 )\end{matrix}$$

where E[.] denotes the expectation operator. A class of techniques named “direct” can be used to estimate the bispectrum. This technique uses the discrete fourier transform (DFT) to compute the bispectrum as follows:

B(k₁, k₂)=E[X(k₁)X(k₂)X*(k₁+k₂)], (4.21)

where X(k) is the DFT of x(n).

From equation (4.21), it can be concluded that the bispectrum only accounts for phase couplings that are the sum of the individual frequency components. However, motor related faults manifest themselves as harmonics that modulate the fundamental frequency and appear as sidebands at frequencies given by |fₑ±mfᵥ|, where fₑ is the fundamental frequency and fᵥ is the fault frequency. Hence, the bispectrum estimate given by equation (4.21) detects only half of the coupling, as it does not detect the presence of the other half given by the difference of the two frequency components. Moreover, information about the modulation frequency has to be known to use this bispectrum estimate correctly. This point can be illustrated with the following example. Consider the following two signals,

x₁(n)=cos(2π60n+φ₁) (4.22)

x₂(n)=B+cos(2π20n+φ₂) (4.23)

where, φ₁ and φ₂ are arbitrary phase angles. The signal, x₁(n) is considered to be an unbiased signal as is the case in power system applications. In this example, x₁(n) is analogous to the carrier signal and x₂(n) is analogous to the signal that modulates the carrier signal. The product of these two signals results in,

$$\begin{matrix}x ( n ) = {x}_{1} ( n ) {x}_{2} ( n ) \\ = B cos ( 2 π 60 n + {φ}_{1} ) + cos ( 2 π 60 n + {φ}_{1} ) cos ( 2 π 20 n + {φ}_{2} ) \\ = B cos ( 2 π 60 n + {φ}_{1} ) + \frac{1}{2} cos ( 2 π 80 n + {φ}_{1} + {φ}_{2} ) + \\ \frac{1}{2} cos ( 2 π 40 n + {φ}_{1} - {φ}_{2} ) .\end{matrix} \qquad ( 4.24 )$$

For simplicity, the constant B is assumed to be equal to 1. In the resultant signal, the 40 Hz and the 80 Hz components are obtained due to the modulation of the 20 Hz component with the 60 Hz carrier frequency. From equation (4.21), it can be concluded that for the bispectrum to correctly identify this modulation relationship, the carrier frequency and the modulation frequency information have to be known. However, in the example shown above, the final signal x(n), does not contain any information about the modulation frequency. Hence the bispectrum cannot be used to correctly identify the modulation relationship as is evident from FIG. 26. The bispectrum plot is typically displayed as a three-dimensional plot with frequency on the x and y axes and the magnitude on the z axis. For simplicity, this study uses two-dimensional contour plots with frequency on the x and y and the magnitude coming out of the page. FIG. 16 shows a peak at frequency pair (40 Hz, 40 Hz), indicating that the signal is made up of only 40 Hz frequency component and that 40 Hz is the modulation frequency, which is not the case. Hence to correctly identify the modulation relationship, a modified bispectrum estimator is used [34].

### 3. Description of the Fault Isolation Indicator

The modified bispectrum estimator also referred to as the amplitude modulation detector (AMD) is defined as follows:

A\hat{M}D (k₁, k₂)=E[X(k₁+k₂)X(k₁−k₂)X*(k₁)X*(k₁)]. (4.25)

From equation (4.25), it can be seen that both the sidebands of the modulation are accounted for in the definition. FIG. 27 shows the modified bispectrum for the example considered in the previous subsection. The peak at the frequency pair (60 Hz, 20 Hz) indicates that the 20 Hz frequency component modulates the 60 Hz frequency component. Moreover, no information about the modulation frequency is utilized in computing the modified bispectrum. This is very useful since the motor related fault frequencies which modulate the supply frequency are very difficult to compute. These frequencies are dependent on the design parameters, which are not easily available. For example, the fault frequency pertaining to a motor rolling element bearing depends on the number of balls in the bearing, the ball diameter, the pitch diameter, etc. Hence it is desirable to design an algorithm which does not require the motor design parameters. Therefore, in this study, various forms of the AMD indicator depicted in equation (4.25) are used to detect motor related faults.

The reason that the AMD correctly identifies the modulation relationship is that it detects phase coupling. If phase coupling exists between frequency components, then the AMD component at those frequencies will have zero phase and maximum peak. To illustrate this, consider the equation (4.25) and represent it in terms of its phase and magnitude, as follows:

E[|X(k₁+k₂)|e^{j∠(k}^{₁}^{+k}^{₂}^{)|X(k}₁−k₂)|e^{j∠(k}^{₁}^{-k}^{₂}⁾|X*(k₁)|e^{-j∠(k}^{₁}⁾|X*(k₁)|e^{-j∠(k}^{₁}⁾] (4.26)

Rearranging the terms results in,

E[|X(k₁+k₂)∥X(k₁−k₂)∥X*(k₁)∥X*(k₁)|e^{j∠(k}^{₁}^{+k}^{₂}^{)+∠(k}^{₁}^{-k}^{₂}^{)-∠(k}^{₁}^{)-∠(k}^{₁}⁾⁾]. (4.27)

If there is phase coupling between the frequency components k₁ and k₂, then

∠(k₁+k₂)=∠(k₁)+∠(k₂), and (4.28)

∠(k₁−k₂)=∠(k₁)−∠(k₂). (4.29)

Substituting equations (4.28) and (4.29) in equation (4.27), results in zero phase and the final expression is the expectation of the product of the magnitudes. Hence, if the frequency components, k₁, k₁+k₂ and k₁−k₂ exists in the spectrum, and if there is phase coupling between the frequency components, k₁ and k₂, then the detector will exhibit a peak at AMD(k₁, k₂), indicating that frequencies k₁ and k₂ are modulated components.

The AMD spectrum is a two dimensional matrix. The frequency resolution of AMD can be calculated by

$$Δ f = \frac{{f}_{s}}{N} , \qquad [ 33 ]$$

where fₛ is the sampling frequency and N is the total number of samples. A good frequency resolution will lead to a large AMD matrix, which cannot be implemented easily and would require large memory and a very fast processor. In this study, we are interested only in the frequency components that are modulated with one specified frequency; for example, the supply fundamental frequency. Therefore, it is possible to use only a one dimensional AMD, to calculate the AMD spectra that are modulated only with the supply fundamental frequency.

The induction motor has been modelled as the modulator shown in FIG. 14. Any fault in the rotor or the motor bearings would lead to the generation of spatial harmonics which modulate the frequencies corresponding to the input voltage and manifest as sidebands in the motor current. Since the spatial harmonics pertaining to the fault are unknown, the AMD is used to detect if any such modulation relationship exists, which does not require any information about the modulation frequency component. Detailed derivations of these AMD indicators are given in [35].

C. Vibration-Based Signal Analysis

The effectiveness of the model-based scheme is compared to the effectiveness of a continuous vibration monitoring scheme. A tri-axial accelerometer is mounted on top of the pump to continuously monitor the vibration level of the pump, both during the normal operation and during the staged fault experiments. Similarly, an accelerometer is mounted on the motor close to the bearing housing to monitor the change in the vibration level as the motor bearing condition degrades. The vibration levels in the x, y and z directions are recorded and the aggregate vibration level is used as an indicator to detect the presence of a fault. The indicator is defined as follows:

$$Vibration Indicator ( VI ) = \frac{1}{3} {\sum }_{x , y , z} \sqrt{\frac{1}{N} {\sum }_{i = 1}^{N} {Vib}_{X , i}^{2}} \qquad ( 4.30 )$$

where Vib_{X,i} is the i^{th} sample of the vibration signal in the X direction, where X stands for the three axes x, y, z, and N is the total number of samples. Since the vibration level of the system varies after each re-assembly and cannot be controlled, a fixed threshold cannot be used for detection. Hence, an adaptive threshold is used. In this study, a multiple of the standard deviation of the baseline vibration is used as the detection threshold.

### REFERENCES

[1] J. E. McInroy and S. F. Legowski, “Using power measurements to diagnose degradations in motor drivepower systems: A case study of oilfiled pump jacks”, in IEEE Transactions on Industry Applications, vol. 37, no. 6, pp. 1574-1581, November/December 2001.
[2] L. Bachus and A. Custodio, Know and Understand Centrifugal Pumps. New York: Elsevier Advanced Technology, 2003.
[3] C. J. Dister, “On-line health assessment of integrated pumps”, in Aerospace Conference Proceedings, vol. 7, pp. 3289-3294, Montana, March 2003.
[4] J. A. Siegler, “Motor current signal analysis for diagnosis of fault conditions in shipboard equipment”, U.S.N.A—Trident Scholar Project Report, no. 220, U.S. Naval Academy, 1994.
[5] D. A. Casada, “Detection of pump degradation”, in 22nd Water Reactor Safety Information Meeting, Maryland, October 1994.
[6] D. A. Casada and S. L. Bunch, “The use of the motor as a transducer to monitor pump conditions”, in P/PM Technology Conference, Indianapolis, Ind., December 1995.
[7] D. A. Casada, “Monitoring pump and compressor performance using motor data”, in ASME International Pipeline Conference, vol. 2, pp. 885-895, 1996.
[8] D. A. Casada and S. L. Bunch, “The use of the motor as a transducer to monitor system conditions”, in 50th meeting of the Society for Machinery Failure Prevention Technology, January 1996.
[9] T. Kenull, G. Kosyna and P. U. Thamsen, “Diagnostics of submersible motor pumps by non-stationary signals in motor current”, in ASME Fluids Engineering Division Summer Meeting, vol. 11, Jun. 22-26, 1997.
[10] T. Dalton and R. Patton, “Model-based fault diagnosis of a two-pump system”, in Transactions of the Institute of Measurement and Control, vol. 20, no. 3, pp. 115-124, 1998.
[11] S. Perovic, P. J. Unsworth and E. H. Higham, “Fuzzy logic system to detect pump faults from motor current spectra” in Proceedings of 2001 IEEE Industry Applications Society 36th Annual Meeting—IAS'01, vol. 1, pp. 274-280, September/October 2001.
[12] D. E. Welch, H. D. Haynes, D. F. Cox and R. J. Moses, “Electric fuel pump condition monitor system using electrical signature analysis”, U.S. Pat. No. 6,941,785, September 2005.
[13] H. D. Haynes, D. F. Cox and D. E. Welch, “Electrical signature analysis (ESA) as a diagnostic maintenance technique for detecting the high consequence fuel pump failure modes”, Presented at Oak Ridge National Laboratory, October, 2002.
[14] C. S. Kallesoe, V. Cocquemptot and R. Izadi-Zamanabadi, “Model based fault detection in dentrifugal pump application”, in IEEE Transactions on Control Systems Technology, vol. 14, no. 2, pp. 204-215, March 2006.
[15] E. P. Sabini, J. A. Lorene and O. Henyan, “Centrifugal pump performance degradation detection”, U.S. Pat. No. 6,648,606 B2, November 2003.
[16] S. C. Schmalz and R. P. Schuchmann, “Method and apparatus of detecting low flow/cavitation in a centrifugal pump”, U.S. Pat. No. 6,709,240 B1, March 2004.
[17] C. A. Harris, J. A. Schibonski, F. E. Templeton and D. L. Wheeler, “Pump system diagnosis”, U.S. Pat. No. 6,721,683 B2, April 2004.
[18] K. Kim, A. G. Parlos and R. M. Bharadwaj “Sensorless fault diagnosis of induction motors”, in IEEE Transactions on Industrial Electronics, vol. 50, no. 5, pp. 1038-1051, 2003.
[19] K. Kim and A. G. Parlos, “Reducing the Impact of False Alarms in Induction Motor Fault Diagnosis”, in Journal of Dynamic Systems, Measurement and Control, vol. 125, no. 1, pp. 80-95, 2003.
[20] http://www.cee.vt.edu/program_areas/environmental/teach/wtprimer/pumps/pumps.html. Accessed on Feb. 11, 2004.
[21] F. R. Spellman and J. Drinan, Fundamentals for the Water and Wastewater

Maintenance Operator Series: Pumping. Lancaster: Technomic Publishing Company, 2001.
[22] http://www.energymanagertraining.com/eqp_ind_pumps.htm. Accessed on Jan. 21, 2004.
[23] S. Yedidiah, Centrifugal Pump User's Guidebook: Problems and Solutions. New York: International Thomson Publishing Company, 1996.
[24] http://www.hargrave.com.my/about_pumps.php?page=5. Accessed on Dec. 12, 2006.
[25] http://www.depcopump.com/catalog107/149.pdf. Accessed on Jan. 28, 2004.
[26] http://www.worldpumps.com/WZ/WorldPumps/latestfeatures/maintenance/000021/show. Accessed on Jan. 28, 2004.
[27] G. mendles and B. Larose, “Pump and seal failure analysis improves reliability, reduces costs”, in Enery-Tech Magazine, January 2007.
[28] http://www.eere.energy.gov/femp/operations_maintenance/strategies/strat_reactive.cfm. Accessed on Dec. 13, 2006.
[29] R. J. Patton and J. Chen, “Robustness in quantitative model-based fault diagnosis”, in IEE Colloquium on Intelligent Fault Diagnosis—Part 2: Model-Based Techniques, pp. 4/1-4/17, 1992.
[30] P. P. Harihara, K. Kim and A. G. Parlos, “Signal-based versus model-based fault diagnosis—a tradeoff in complexity and performance”, in IEEE International Symposium on Diagnostics for Electric Machines, Power Electronics and Drives (SDEMPED 2003), pp. 277-282, Atlanta, Ga., Aug. 24-26, 2003.
[31] R. C. Dugan, M. F. McGranaghan, S. Santoso and H. W. Beaty, Electrical Power Systems Quality. New York: McGraw-Hill, 2003.
[32] P. C. Krause, O. Wasynczuk and S D. Sudhoff, Analysis of Electric Machinery. New York: The Institute of Electrical and Electronics Engineers, Inc., 1995.
[33] C. L. Nikias and A. P. Petropulu, Higher-Order Spectra Analysis—A Nonlinear Signal Processing Framework. New Jersey: PTR Prentice Hall, 1993.
[34] J. R. Stack, R. G. Harley and T. G. Habetler, “An amplitude modulation detector for fault diagnosis in rolling element bearings”, in IEEE Transactions on Industrial Electronics, vol. 51, no. 5, pp. 1097-1102, October 2004.
[35] L. Wang, “Induction motor bearing fault detection using a sensorless approach”,

Ph.D Dissertation, Mechanical Engineering, Texas A&M University, College Station, May 2007.
[36] J. R. Stack, “Experimentally Generating Faults in Rolling Element Bearings Via Shaft Current,” IEEE Transactions on Industry Applications, vol. 41, No. 1, January/February 2005.
[37] H. Prashad, “Diagnosis of Rolling-element Bearings Failure by Localized Electrical Current between Track Surfaces of Races and Rolling-elements,” Journal of Tribology, vol. 124, no. 3, pp. 468- 473, July 2002.
[38] D. F. Busse, J. M. Erdman, R. J. Kerkman, D. W. Schlegel, and G. L. Skibinski, “The Effects of PWM Voltage Source Inverters on the Mechanical Performance of Roller Bearings,” IEEE Transactions on Industry Applications, vol. 33, No. 2, pp. 567-576, March/April 1997.
[39] “IEEE standard test procedure for polyphase induction motors and generators”, IEEE Power Engineering Society, November 2004.

### IV. Induction Motor Fault Detection and Diagnosis

### 1. Motivation

Induction motors play a very important role in the safe and efficient running of any industrial plant. Like all rotating machinery, induction motors are not 100% reliable. Several parts of the machine are especially susceptible to failure. For example, the stator windings are subject to insulation failures caused by mechanical vibration, heat, age, damage during installation, and contamination by oil. The rotor bars are subject to failures caused by a combination of various stresses that act on the rotor. Machine bearings are subject to excessive wear and damage caused by inadequate lubrication, incorrect loading, or misalignment. In many applications, these failures can shut down an entire industrial process. The unexpected shutdowns cost the user both time and money that can be avoided if some form of early warning system is used. Furthermore, such systems add to safety and reliability, which are key factors in a wide range of industrial environments. Fault detection and diagnosis schemes are intended to provide advanced warnings so that corrective action can be taken without detrimental interruption of the process. Extensive fault diagnosis of motors can lead to greater plant availability, extended plant life, higher quality products, and smoother plant operation.

The goal of fault detection and diagnosis is to ensure the success of the planned operations by providing information that recognizes and indicates anomalies of system

The journal model is IEEE Transactions on Automatic Control. behavior. This information not only keeps the operators better informed of the status of the system, but also assists them in taking appropriate remedial actions to eliminate any abnormal system behavior. The success of a fault detection and diagnosis algorithm is fundamentally related to the available information, the features of the information that it uses, and the technique with which these features are evaluated. A fault is defined as the inability of a system to perform in an acceptable manner. A fault manifests itself as a deviation in observed system behavior from a set of acceptable behaviors. Fault detection is the recognition of the unacceptable behavior, and fault diagnosis is the identification of a component or set of components in the system that caused the fault, including the type, location, magnitude, and time of the fault. The detection and diagnosis tasks should be considered separately, but this distinction is not always made clear in practice because detection and diagnosis processes can be closely intertwined. Fault detection consists of 1) collecting data, 2) extracting relevant features from the data and evaluating those extracted features into a form of fault indicators, and 3) comparing those indicators to baseline observations formed from the normal condition of the system. Based on the results of this comparison, a fault can be declared.

Before the literature review, motor anomalies, motor faults, and motor fault detection and diagnosis methods are reviewed in this chapter.

### 2. Motor Anomalies

Motor anomalies are not faulty conditions of the machine. They are normal machine operating conditions that occur when there are temporal variations in the motor inputs and disturbances. Motor anomalies, being major sources of false alarms, can produce signatures similar to some faults. Motor anomalies originate from supply imbalance and the load fluctuations.

a. Supply Imbalance

Three phase electric power systems generally provide voltage supply at the generating station that is well balanced in both magnitude and displacement. At the distribution end, unbalanced single phase loads and non-linear loads cause unequal voltage drops in the transformer and line impedances. This results in an unbalanced supply voltage at the point of utilization. The supply imbalance will affect fault detection to some extent. For example, the majority of the methods developed until now to detect stator faults are based on monitoring the negative sequence of the current. If the supply becomes unbalanced, a negative sequence current will flow because of the motor's low negative sequence impedance. Using only current measurements, it is difficult to distinguish between the negative sequence current due to unbalanced voltage and due to motor stator deterioration. This makes the negative sequence of the current alone an unreliable indicator for incipient fault detection.

b. Load Fluctuations

If the load torque varies, the stator current spectrum contains load induced frequency components that coincide with those caused by a fault condition. In the sinusoidal steady-state, a load torque oscillation produces a related oscillation in the electromagnetic field. The current drawn by the motor contains all of the frequency components found in the load torque. The magnitude of these developed load torque harmonics are primarily dependent upon the system inertia and the frequency of the torque oscillation. If the stator flux linkage is purely sinusoidal, then any oscillation in the load torque at multiples of the rotational speed will produce stator currents at frequencies [1],

$${f}_{load} = {f}_{e} \pm {kf}_{rm} = {f}_{e} [ 1 \pm k \frac{( 1 - s )}{p / 2} ] , \qquad ( 1.1 )$$

where fₑ is the electrical supply frequency, k=1, 2,3, . . . . , s is the per unit slip, p is the number of poles, and fᵣₘ is the mechanical rotor speed in Hertz. Since motor faults, like air-gap eccentricity and broken rotor bars generate the same frequencies as those given in equation (1.1), it is clear that when induction motors operate with a typical time-varying load, stator current frequency components caused by torque oscillations can obscure those caused by fault conditions.

### 3. Motor Faults

Motor reliability studies have been performed by both General Electric, under the sponsorship of the Electric Power Research Institute [2], and the IEEE Industry Application Society [3], in order to evaluate the reliability of electric motors and to identify the design and operational characteristics offering the potential to increase their reliability. These two surveys are for motors energized by power supply mains. Another motor reliability survey for motors energized by inverters was performed by Thorson [4]. The failure rates are reported to be 47% for stator faults, 5% for rotor faults, 32% for bearing faults, and 16% for other faults. However, the original sources of the Thorson survey cannot be tracked down in the literature. Table I shows the first two motor reliability survey results, where the first two columns include motors of all types and the third column includes only squirrel-cage induction machines.

The majority of electric machine component failures are related to three main components of motors, the stator, the rotor, and the bearings. Bearing failures account for 30% to 50% of all electric motor failures. In the following sections, failures related to each of these motor components are discussed.

TABLE I
Motor Reliability Survey Results [2, 3].

| | EPRI Survey | IEEE IAS Survey | IEEE IAS Survey |
|---|---|---|---|
| Survey Size | 1052 Failures | 380 Failures | 304 Failures |
| Stator | 36% | 26% | 25% |
| Rotor | 9% | 8% | 9% |
| Bearings | 41% | 44% | 50% |
| Others | 14% | 22% | 16% |

a. Stator Faults

Stator faults are usually insulation related, which might be inter-turn, phase-to-phase, and phase-to-ground shorts. While the insulation is most susceptible to failure where the end windings enter the stator slots, failures also occur at locations where the conductors pass through the motor casing [5]. Manufacturing defects that include voids, contamination, and penetration by foreign materials, such as oil or metal, frequently cause failures in the electrical insulation of the machine. Damaging conditions are also produced by the large electrical voltage stresses at conductor bends, electro-dynamic forces produced by the winding current, thermal aging from multiple heating and cooling cycles, and mechanical vibrations from internal and external sources. The deterioration of the insulation strength eventually leads to shorted or grounded stator windings that give rise to zero and negative sequence currents.

b. Rotor Faults

Bar defects occur in squirrel-cage rotors. These defects come from two sources [5]. The first source is associated with high temperatures and large centrifugal forces developed during transient operations, such as startup. Defective casting (voids) or poor end-ring joints formed during manufacturing are the second source. Once the initial defect occurs, propagation of the fault is the result of multiple startups and load fluctuations that produce high centrifugal forces. The condition is further accentuated by the heating and cooling cycles of the rotor. Similar to stator windings, damage in wound rotors generally occurs at the end regions. Mechanical defects produced by high centrifugal stresses experienced by rotor components can lead to catastrophic failures. These failures are accelerated if the cooling system contains impurities, which encourage corrosion and degrade the mechanical strength of the rotor. Long before unassisted disassembly occurs, the machine begins to exhibit some level of mechanical imbalance. In many cases, this eccentricity of the rotor is amplified by the unbalanced magnetic pull produced by the magnetic field of the machine. This situation is compounded when the asymmetrical heating leads to thermal bending of the rotor. Machines with small air-gaps are especially susceptible and the possibility of contact between the rotor and the stator becomes real.

c. Bearing Faults

Over the past several decades, rolling-element bearings have been utilized in many electric machines, while sleeve bearings are installed in only the larger machines. In the case of induction motors, rolling-element bearings are widely used to provide rotor supports. Bearing deterioration, which accounts for 30% to 50% of all machine failures, is now one of the main causes of induction motor failures [2, 3, 4]. The causes and classifications of bearing failures are discussed in Chapter II.

d. Air-Gap Eccentricity

An induction motor can fail due to air-gap eccentricity, which can be caused by many reasons. There are two types of air-gap eccentricities: static air-gap eccentricity and dynamic air-gap eccentricity. In the case of static air-gap eccentricity, the position of the minimal radial air-gap length is fixed in space. Static air-gap eccentricity can be caused by the ovality of the core or by the incorrect positioning of the stator or rotor at the commissioning stage. In the case of dynamic air-gap eccentricity, the center of the rotor is not at the center of the rotation and the minimum air-gap rotates with the rotor. It follows that dynamic eccentricity is time and space dependent, whereas static eccentricity is only space dependent. Dynamic eccentricity can be caused by a bent rotor shaft, wear of bearings, misalignment of bearings, mechanical resonances at critical speed, and so on. Both types of eccentricities cause excessive stressing of the motor and greatly increase bearing wear. In addition, the radial magnetic force waves produced by eccentricity can also act on the stator core and subject the stator windings to unnecessary and potentially harmful vibrations. It is also possible that rotor-to-stator rub might occur, leading to damage of the core, windings, and the rotor cage [6].

### 4. Fault Detection and Diagnosis Methods

Detection techniques consider one or more fault indicators of the observations. These indicators are calculated from the measured data, which in some way represent the state or behavior of the system. For fault detection, limits may be placed on some of the indicators, and a fault is detected whenever one of the indicators is evaluated to be outside its limits. The indicators of a fault detection scheme are mainly derived from three approaches, data-driven, knowledge-based, and analytical methods. The data-driven indicators are derived directly from measurements. The analytical approach uses mathematical models often constructed from physical principles, while the knowledge-based approach uses qualitative models. The analytical approach is applicable to information-rich systems, where satisfactory models and sufficient sensors are available. Meanwhile, the knowledge-based approach is better applied to information-poor systems, where few sensors or poor models are available [7].

a. Data-Driven Methods

Accurate and detailed models are difficult to develop for complex systems containing a large number of inputs, outputs, and/or states. Thus, analytical methods cannot he successfully applied to complex systems. In these situations, data-driven methods are widely applied. Data-driven methods use the data collected during normal operating conditions and during specific faults to develop the fault indicators for detecting and diagnosing failures. Because these methods are data-driven, their effectiveness is highly dependent on the quantity and quality of the measured data. While a large amount of data might be available from many sensors, typically only a small portion might be useful. One must determine with confidence that the useful fraction of the data are not somehow corrupted and that no unknown faults occurred in the system [8, 9, 10].

b. Knowledge-Based Methods

For establishing a knowledge base for fault detection and diagnosis, several approaches have been described in the literature [11]. In general, specific rules are applied in order to set up logical interactions between observed symptoms (effects) and unknown faults (causes). The propagation from the actual fault appearance to observable symptoms follows physical cause-effect relationships such that physical properties and variables are not only connected to each other quantitatively, but also as functions of time. However, the underlying physical laws are usually not known in analytical form or are too complicated for calculations. Rule-based expert systems are a general technique for representing knowledge in usable forms, and are thus capable of using almost any pre-specified observation feature for diagnosis [12]. Expert systems can be excellent tools for capturing and utilizing knowledge that is not or cannot be captured by traditional techniques, such as models. Expert systems generally work well when a model is not known, or is too complex to develop. In some types of systems, the symptoms used by the expert system are more successful in identifying a fault compared to the model-based diagnosis. This is because some types of symptoms are difficult to relate to a fault through a model, but may easily be related to a fault through a simple rule. However, rule-based expert systems have several drawbacks [13]. Most expert systems are fault specific and are only capable of diagnosing faults that are represented in the knowledge base. In a complex system, it may not be possible or practical to represent all possible faults. Moreover, although rules can easily be added to the knowledge base, expert systems can be difficult to modify and maintain in certain circumstances. This is because the knowledge base would require extensive reworking following a system modification or sensor change.

c. Analytical Methods

Fault diagnosis can be achieved using a replication of hardware (e.g., computers, sensors, actuators, and other components). In what is known as hardware or physical redundancy, outputs from identical components are compared for consistency. Alternatively, fault diagnosis can be achieved using analytical information about the system being monitored. This is known as analytical or functional redundancy. In contrast to hardware redundancy, in which measurements from different sensors are compared, in analytical redundancy sensory measurements are compared to analytically obtained values of the corresponding variable. This implies that the inherent redundancy contained in the static and dynamic relationships among the system inputs and outputs is exploited for fault diagnosis. Such computations exploit the present and/or previous measurements of other variables and the mathematical model of the system describing their relationships. The model can use the system input and output data to estimate information about the system, including the output, state, or internal parameters [14, 15].

d. Pattern Recognition

Many data-driven, knowledge-based, and analytical approaches incorporate pattern-based techniques to some extent. Pattern-based methods generally consist of templates or patterns distinguishing acceptable and unacceptable operations. These are then compared to the system observations to determine whether a fault has occurred. Templates or patterns may be determined by performance specifications, by past observations of faulty operations, by expert knowledge, or even from analysis or simulation of a system model. Since pattern recognition approaches are based on inductive reasoning through generalization from a set of stored or learned examples of system process behaviors, these techniques are useful when data are abundant, and expert knowledge is lacking [16]. The artificial neural network (NN) is a particularly promising approach in pattern-based fault detection and diagnosis [6, 17, 18, 19].

e. Motor Condition Monitoring Sensors

While there have been numerous sensors proposed in the literature, such as temperature, flux, etc., the most widely used induction motor fault detection sensors are of mechanical and electrical origin [5].

Mechanical monitoring of electric machines is accomplished through the use of spectral signature analysis, which converts the measured vibration signal into frequency components of constant bandwidth by using Fast Fourier Transform (FFT) [5]. The idea is based on the concept that mechanical vibrations at various frequencies are related to identifiable causes of anomalies in the machine and they can be used to provide an indication of the condition of the machine. The vibrational energy of the machine is measured in units of one of the three related quantities: displacement, velocity, or acceleration. These measurements are accomplished using either displacement probes, velocity transducers, or accelerometers. The appropriate device depends upon the size of the machine and the frequency range of interest; however, it is now common practice for displacement and velocity to be integrated from the acceleration measurements.

While mechanical monitoring has been utilized for decades, most of the recent research has been directed toward electrical monitoring techniques utilizing stator currents of the machine. On the surface, stator currents contain much less information than the magnetic flux density, but are more readily accessible by non-invasive measurement techniques. They have been selected as appropriate signals for processing, together with the supply line voltages in this research. A large amount of research has been directed toward using motor currents to sense stator insulation failures involving turn-to-turn shorts, rotor faults involving air-gap eccentricity, and broken rotor bars.

Thermal monitoring of electric machines is accomplished by measuring either the local or the bulk temperatures of the motor [5]. Local temperatures include those measurements taken with embedded detectors located at hot spots within either the stator core and windings or the motor bearings. While these measurements provide temperature indications at known problem areas, there is still the question of whether the hottest spot in the machine is being monitored. Bearing temperatures are often surveyed on a routine basis, like vibration levels. They provide a useful warning for tribological problems. Winding temperature is very valuable for determining the limit to which a motor can be loaded and for estimating the remnant life of the winding insulation. Bulk temperatures include the measurements of cooling and lubrication fluids such as the air flowing inside the machine casting and the bearing oil. They are valuable for indicating motor cooling problems and for monitoring motor operation beyond its rating. But, even these temperature measurements can miss isolated problems in the machine.

### 5. Motor Current Signature Analysis and Electrical Signal Analysis

Traditionally, motor condition has been monitored by measuring variables such as noise, vibration, and temperature. But the implementation of such systems is expensive and they are generally installed only on the largest motors or most critical applications where the cost of the monitoring system can be justified. In addition, the environmental sensitivity of some sensors can cause mechanical monitoring techniques to provide unreliable indications. Mechanical forms of sensing are also limited in their ability to detect some electrical faults such as stator insulation faults. A solution to this problem can be the use of quantities that are already measured in a drive system, or easily accessible in a system with or without drives, e.g., the machine's stator currents and voltages.

In the literature, two categories of fault detection schemes that use the motor terminal signals are presented, Motor Current Signature Analysis (MCSA) and Electrical Signal Analysis (ESA).

The Motor Current Signal Analysis (MCSA), which separates the monitored signal into individual frequency components, is commonly used to detect some induction machine mechanical faults. Most rotor faults affect either the air-gap permeance or the magnetomotive force (MMF) that cause variations in the air-gap flux density. These flux variations produce stator currents at frequencies related to the fault condition. In MCSA, only motor stator currents are considered as the fault media. This is acceptable in some special environment where the voltage inputs are clean and mostly stationary. However in practical industrial environments, the voltage inputs are highly non-stationary signals where rich harmonic information comes from the supply and other devices, and may mask fault signatures abstracted using MCSA techniques.

The ESA is based on the concept that air-gap flux density variations caused by mechanical and electrical defects produce correlated changes in currents and voltages. Therefore, stator voltages and currents are utilized for fault detection purposes. In this research, both stator currents and voltages are used for motor bearing detection purposes.

“Sensorless” means that only current and voltage measurements are used. Current and voltage monitoring can be implemented inexpensively on any size machine by utilizing the current transformers and potential transformers in the motor control/switch gear centers. Use of the existing current transformers and potential transformers makes it feasible to monitor large numbers of motors remotely from one location. Similarly, these measurements can be easily obtained when a drive system is used to energize the motor.

### B. Literature Review

In this research, detection of bearing faults in motors energized by power supply mains and VSI type drives is investigated. The desired fault detection method should be independent of any physical motor parameters and must utilize only motor terminal currents and voltages.

In the following sections, the literature for bearing fault detection in motors energized by power supply mains and VSI type drives is reviewed.

### 1. Classification of the Bearing Faults

Depending on the location of the fault, bearing faults can be classified as ball fault, inner race fault, outer race fault, and train fault. But, this classification does not include all bearing faults. In [20], bearing faults are grouped into two categories: single point defects and generalized roughness faults.

A single point defect is defined as a single, localized defect on an otherwise relatedly undamaged bearing surface. A common example is a pit or a spall. A single point defect produces one of the four characteristic fault frequencies depending on which surface of the bearing contains the fault, the ball, the inner raceway, the outer raceway, or the cage. These predictable frequency components typically appear in the machine vibration spectrum and arc often reflected into the stator current spectrum. Despite its name, a bearing can possess multiple single point defects.

Generalized roughness is a type of fault where the condition of a bearing surface degrades considerably over a large area and becomes rough, irregular, or deformed. This damage may or may not be visible to the unaided eye. There is no localized defect to be identified as the fault; rather, large areas of the bearing surfaces deteriorate. A common example is the overall surface roughness produced by a contamination or loss of lubricant. The effects produced by this type of fault are difficult to predict, and there are no characteristic fault frequencies in the current or vibration spectra associated with this type of fault [20].

There are many reasons that cause the general roughness fault in a bearing. Some of the more common fault sources include contamination of the lubricant, lack or loss of lubricant, shaft currents, and misalignment. While these fault sources may also produce single point defects, it is common that they produce unhealthy bearings that do not contain single point defects. If one of these bearings is removed from service prior to a catastrophic failure, a technician can easily recognize that a problem exists within the bearing because it either spins roughly or with difficulty. However, upon a visual examination, there is no single point defect, and the actual damage of the bearing may or may not be visible to the unaided eye. For this kind of fault, it is stated in [20] that the specific way in which these bearings fail is unpredictable. Therefore, the effect the fault has on machine vibration and stator current spectra is unpredictable. However, as the fault increases in severity, the magnitude of the broadband machine vibration increases accordingly.

### 2. Bearing Fault Detection in Induction Motors Energized by the Power Supply Mains

In the literature, most bearing fault detection techniques for induction motors are intended for detecting single point defects. To detect such faults, vibration analysis is widely used. In MCSA approaches, frequency analysis, time-frequency analysis, and model based method are used for detecting single point defects. For bearing generalized roughness faults, model based approaches are used.

a. Frequency Analysis

Single-point defects produce one of the four characteristic fault frequencies in machine vibration spectrum depending on which bearing surface contains the fault. These frequencies are listed below. More details can be found in [4, 20, 21, 22].

### Cage Fault Frequency:

$${F}_{CF} = \frac{1}{2} {F}_{R} ( 1 - \frac{BD cos β}{PD} ) , \qquad ( 1.2 )$$

### Outer Raceway Fault Frequency:

$${F}_{ORF} = \frac{{N}_{B}}{2} {F}_{R} ( 1 - \frac{BD cos β}{PD} ) , \qquad ( 1.3 )$$

### Inner Raceway Fault Frequency:

$${F}_{IRF} = \frac{{N}_{B}}{2} {F}_{R} ( 1 + \frac{BD cos β}{PD} ) , \qquad ( 1.4 )$$

### Ball Fault Frequency:

$${F}_{BF} = \frac{PD}{2 BD} {F}_{R} ( 1 - \frac{{BD}^{2} {cos}^{2} β}{{PD}^{2}} ) . \qquad ( 1.5 )$$

Ball bearing dimensions are shown FIG. 28. n the above equations, BD is the ball diameter; PD is the bearing pitch diameter; N_{B} is the number of rolling elements; β is the contact angle; and F_{R} is the rotor frequency.

It has been shown that single point defects in damaged bearings cause air gap variations. These variations generate stator current harmonics at the following frequencies [21],

F_{BNG}=|F_{E}±m·F_{V}|, (1.6)

where F_{E} is the supply fundamental frequency, F_{V} is one of the characteristic vibration frequencies, and m=1, 2, 3, . . . .

Equation (1.6) is the most often quoted model studying the influence of bearing damage on the induction machine stator current. However in the literature, researchers reported that it's not easy to identify these bearing fault related frequencies in the stator current spectra [23, 24]. Studies in [25] gave the following modified version of equation (1.6),

### Outer Raceway Fault Frequency:

F_{BNG}_{_{—}}_{ORF}=|F_{E}±m·F_{ORF}|, (1.7)

### Inner Raceway Fault Frequency:

F_{BNG}_{_{—}}_{IRF}=|F_{E}±F_{R}±m·F_{IRF}|, (1.8)

### Ball Fault Frequency:

F_{BNG}_{_{—}}_{BF}=|F_{E}±F_{CF}±m·F_{BF}|. (1.9)

The main drawback of the bearing defect frequency identification method is that calculation of a bearing defect frequency requires full knowledge of the bearing design parameters. Usually such parameters are not available, except to bearing designers. Moreover, it is difficult to identify the contact angle β because it is depended on the practical assembling.

b. Time-Frequency Analysis

Induction motor stator currents are known to be non-stationary and the Fast Fourier Transformation is not suitable for such non-stationary signals [26]. In order to overcome this problem, a time-frequency method is proposed in [26] and [27].

In [26], inner and outer race bearing defect frequencies are investigated. The total number of balls and the fundamental electrical frequency are needed for the calculation. The Short Time Fourier Transformation (STFT) is used to capture time variation of the bearing defect frequencies. Bearing conditions are determined statistically, by analyzing the bearing fault related spectrum and comparing it with a baseline spectrum.

Compared to STFT, Wavelet Packet Decomposition (WPD) is known to provide optimal combination of time and frequency resolution. This results in better diagnostic performance. In [27], small ranges of bearing defect frequency bands are isolated from the entire stator signature using WPD. The Root Mean Square (RMS) values of the frequency bands are compared with a baseline value and the bearing condtion is determined accordingly. The bearing defect frequency bands are associated with single point defects. Hence, identifying a specific defect band requires bearing dimensions and other bearing design parameters.

c. Model Based Method

A recurrent neural network model was used to detect single point defects in [6]. In this method, quasi-stationary data segments in the terminal currents are grouped together so that the non-stationarity of the signal can be avoided. Then, a neural network model is used to predict the healthy system response.

For bearing generalized roughness faults, Stack presented pioneer work using mechanical vibration analysis [22]. He also used a stator current Auto-Regressive (AR) model to detect generalized bearing faults [28]. In this paper, the current fundamental frequency is removed before sampling the data, so that variations caused by the supply voltage fundamental can be avoided. But, the problem is that the other frequency components of the supply voltage are presented in the current spectrum and they are time-varying. Moreover, in most experimental results shown in this paper, the fault indicator drops down to the healthy level while bearings are already damaged. This makes fault detection difficult.

### 3. Bearing Fault Detection in Induction Motors Energized by Voltage Source Inverter (VSI)

Induction machine drives can be classified into two major categories, Voltage Source Inverter (VSI) and Current Source Inverter (CSI). While CSI's were originally the choice for motor drives, they have pretty much been replaced by VSI's for all but the higher power levels where the controlled output current and reduced load harmonics are desired [29]. VSI type drive is used in this research because it is commonly used in industry.

Bearing fault detection in induction machines energized by VSI are rarely discussed in the literature. Only one method has been published in the open literature, the Vienna Monitoring Method (VMM).

The VMM was proposed in an attempt to reduce the negative effects from inverter harmonics [30, 31, 32]. The VMM is a time domain, model based method. In this method, the stator resistance is needed to model the stator flux and the rotor position is needed to transform the current space phasor in the rotor fixed reference frame. Two models are used in VMM, the voltage model and the current model. In case of an ideal symmetric motor, both models calculate the same torque. As a fault occurs, the distribution of air gap flux is distorted and a deviation appears between the torque values calculated from the two different models. The voltage model is able to indicate the real (faulty) motor performance, while the current model represents the healthy machine. The deviation of the torque is found to be approximately proportional to load torque. Although the authors stated that this method can be used to detect bearing faults, the paper does not provide suitable evidence to support the claim. Moreover, in this method accurate knowledge of induction motor parameters is needed, but such accuracy is usually not practically feasible in most applications.

Although very few papers discuss bearing fault detection of motors energized by VSI drives, yet there exists literature on other kinds of motor faults, like stator shorts and broken rotor bars.

Bellini and Filippetti used the torque and flux components of the current for the detection of stator short circuit and broken rotor bar faults [33, 34]. They conclude that the flux current is suitable for fault diagnosis purposes and the torque current is not robust enough to be a diagnostic index. The reason is that the torque current is strongly affected by load torque values and ripples.

Stator faults are also investigated in [35], where the discrete wavelet transform is used on both the current and voltage, and in [36], where a neural network model is used to estimate the reference signals.

In [37], a rotor cage defect machine model based on motor parameters is developed for rotor cage fault diagnosis under inverter fed conditions. It serves two purposes: to determine the signature frequencies of a cage defect, and to generate the training data for a neural network model. The NN model is used for the purpose of fault classification.

### C. Research Objectives

From the previous sections, it can be seen that there is a strong motivation to develop an improved and cost-effective fault detection method for induction motor bearing faults. The objectives of this research are to
Detect bearing faults when motors are energized by power supply mains and VSI type drives,
Detect bearing failures using only motor terminal voltage and current measurements, i.e., in a sensorless manner, and,
Develop an approach that is independent of physical motor parameters, so that it can be applicable to various induction motors, independent of voltage and power ratings, and manufacturers.

### D. Proposed Approach

To develop a bearing fault detection scheme, bearing fault data are needed. Such data can be generated in an offline manner. That is, to disassemble the bearing, damage it separately, and then assemble the machine in order to collect damaged bearing data. The act of disassembling, reassembling, remounting, and realigning the test motor significantly alters the current and vibration characteristics of the machine, which is one of the difficulties in collecting fault data for a bearing fault detection scheme. In this research, in-situ bearing damage experiments are conducted so that the life span of the bearing can be accelerated and the bearing fault detection scheme can be developed and validated.

In both single defect and general roughness bearing faults, the damaged bearing leads the radial motion between the stator and the rotor. This type of motion varies the air gap of the machine in a way which can be characterized as a modulation relationship with fundamental frequency of the supply. Although this type of modulation relationships exit in the healthy condition, they are changed by the damaged bearing. In single point defect bearing faults, the fault related frequencies can be detected according to the bearing geometry dimensions, while in the generalized roughness bearing faults, the fault related frequencies are residing in wide frequency bands and are not easily predictable. Moreover, the damaged bearing impedes the rotor rotation and causes additional loading on the motor. Although the load itself is small and ignorable, the load fluctuations imposed on the motor increase. This load fluctuations are also modulated with the fundamental frequency of the supply.

Bearing faults can be captured in frequencies that are modulated with the fundamental frequency of the supply. This modulation relationship can be isolated using the phase coupling between the bearing fault frequencies and the fundamental frequency of the supply. An Amplitude Modulation Detector (AMD), developed from estimates of the higher order spectrum, can correctly capture the phase coupling and isolate the modulation relations. This approach is proposed in this research.

The system power supply plays a very important role in bearing fault detection. Variations in the power supply definitely change the stator current spectrum and mask bearing faults. To negate the effects of the power supply changes, bearing fault indicators are developed using the combinations of the stator current AMD and the voltage AMD.

### E. Research Contributions

The main contribution of this research is the development and validation of a method for the detection of bearing faults in induction motors. The method is characterized by the following attributes:
It is applicable to motors energized by power supply mains and VSI type drives,
It requires monitoring of the motor terminal currents and voltages only, and,
Even though it is a model-based method, it does not make use of any physical motor parameters, so that it is easily portable to induction motors of different voltage, power ratings and to induction motors made by different manufacturers.

### F. Organization of the Dissertation

It is expected that this research will provide a powerful general method for incipient bearing fault detection in induction motors.

In Chapter II, an overview of bearing fault causes and effects are discussed. The experimental test beds used in in-situ bearing damage are introduced. In Chapter III, the higher order spectrum, the amplitude modulation detector, the system modulation model and the bearing fault indicators developed in this research are summarized. In Chapter IV, the experimental and the analysis results of the induction motor bearing faults under different power supplies, load levels, VSI control schemes, and operating condition are presented. In Chapter V, a summary of this dissertation, the conclusions reached from this research, and the directions for future research are given.

### 2. Bispectrum Estimation

Bispectrum is one of the polyspectra, which is widely used in identifying the phase relationships between harmonic components.

Let x(n) be a stationary, discrete, zero-mean random process. In this case, its third order cumulant sequence c(n, τ₁, τ₂) will be identical to its third moment sequence (see equation (A.4) in Appendix (A)). Thus,

c(τ₁, τ₂)=E[x(n)x(n+τᵢ)x(n +τ₂)], (3.1)

where E[.] denotes the expectation. The bispectrum is defined as (see equation (A.6) in Appendix (A)),

$$B ( {ω}_{1} , {ω}_{2} ) = {\sum }_{{τ}_{1} = - ∞}^{∞} {\sum }_{{τ}_{2} = - ∞}^{∞} c ( {τ}_{1} , {τ}_{2} ) exp [ - j ( {ω}_{1} {τ}_{1} + {ω}_{2} {τ}_{2} ) ] . \qquad ( 3.2 )$$

When a finite set of observation measurements is given, two chief approaches have been used to estimate the bispectrum, namely, the conventional (‘Fourier type’) and the parametric approach, which is based on autoregressive (AR), moving average (MA), and ARMA models [43].

In the proposed method, phase relationships between harmonic components are desired. The advantage of using the conventional approach to bispectrum estimation is its ability to provide good estimates of the phase coupling at harmonically related frequency pairs [43]. Therefore, the conventional estimation approach is used in this research.

The conventional bispectrum estimation method can be classified into the following two classes [43]:

1) Indirect class of techniques, which are approximations of the definition of the bispectrum given by,

$$\begin{matrix}R ( m , l ) = E [ x ( n ) x ( n + m ) x ( n + l ) ] , & ( 3.3 ) \\ B ( {ω}_{1} , {ω}_{2} ) = {\sum }_{m = - ∞}^{∞} {\sum }_{n = - ∞}^{∞} R ( m , l ) exp [ - j ( {ω}_{1} m + {ω}_{2} l ) ] . & ( 3.4 )\end{matrix}$$

where R(m, l) denotes the third moment sequence of x(n).

2) Direct class of techniques, which approximate an equivalent definition of the bispectrum described by,

B(k₁, k₂)=E[X(k₁)X(k₂)X*(k₁+k₂)]. (3.5)

where X(k) is the DFT of x(n).

### B. Amplitude Modulation Detector

1. From Bispectrum to Amplitude Modulation Detector (AMD)

The bispectrum estimator searches only for the presence of a summation frequency, which can be seen clearly from equation (3.5). However, bearing fault signature frequencies and the supply fundamental frequency are modulated as |fₑ±mfᵥ|. This modulation relationship not only contains a summation relationship, but also contains a subtraction relationship. Assume two biased signals as follows,

x₁(n)=A+cos(2π60n+φ₁) (3.6)

x₂(n)=B+cos(2π20n+φ₂) (3.7)

where, φ₁ and φ₂ are arbitrary phase angles. The multiplication result of these two signals is,

$$\begin{matrix}x ( n ) = {x}_{1} ( n ) {x}_{2} ( n ) \\ = AB + B cos ( 2 π 60 n + {φ}_{1} ) + A cos ( 2 π 20 n + {φ}_{2} ) + \\ cos ( 2 π 60 n + {φ}_{1} ) cos ( 2 π 20 n + {φ}_{2} ) \\ = AB + B cos ( 2 π 60 n + {φ}_{1} ) + A cos ( 2 π 20 n + {φ}_{2} ) + \\ \frac{1}{2} cos ( 2 π 80 n + {φ}_{1} + {φ}_{2} ) + \frac{1}{2} cos ( 2 π 40 n + {φ}_{1} - {φ}_{2} ) .\end{matrix} \qquad ( 3.8 )$$

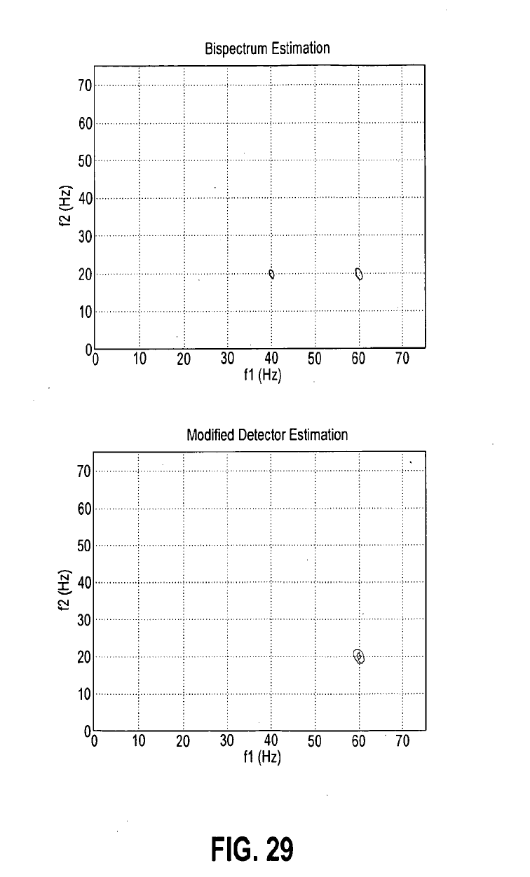

In this signal, the 20 Hz and 60 Hz components are modulated with each other. This modulation relationship can be detected using the phase coupling property. However, the bispectrum not only correctly identifies that the 80 Hz is produced by the 20 Hz and 60 Hz components, but it also incorrectly suggests that the 20 Hz and the 40 Hz components are interacting to generate the 60 Hz component (i.e., 60=20+40), shown in FIG. 29. This makes the bispectrum less useful in finding the amplitude modulation relationship.

In order to correctly identify the modulation relationship between frequency components, a modified bispectrum detector, used by Stack in vibration analysis [22], is utilized. This Amplitude Modulation Detector (AMD) is defined as follows,

A\hat{M}D(k₁, k₂)=E[X(k₁+k₂)X(k₁−k₂)X*(k₁)X*(k₁)]. (3.9)

FIG. 29 shows the result for the example above using the AMD. By considering both side bands created by amplitude modulation, AMD is more appropriate in finding the amplitude modulation components.

The amplitude modulation contains the plus and minus relationships. The above example shows the difference between the bispectrum and AMD estimators. In the

### V. Proposed Bearing Fault Detection Method

### A. Overview of the Higher Order Spectrum

One of the most fundamental and useful tools in digital signal processing has been the estimation of the power spectra density (PSD) of discrete-time deterministic and stochastic processes. The available power spectrum estimation techniques may be considered in a number of separate classes, namely, conventional (or “Fourier type”) methods, maximum-likelihood method of Capon with its modifications, maximum-entropy and minimum-cross-entropy methods, minimum energy, methods based on autoregressive (AR), moving average (MA) and ARMA models, and harmonic decomposition methods such as Prony, Pisarenko, MUSIC, and Singular Value Decomposition. Research in this area has also led to signal modeling, and to extensions to multi-dimensional, multi-channel, and array processing problems Each one of the aforementioned techniques has certain advantages, and limitations riot only in terms of estimation performance, but also in terms of computational complexity. Therefore, depending on the signal environment, one has to choose the most appropriate method [43].

In power spectrum estimation, the process under consideration is treated as a superposition of statistically uncorrelated harmonic components and the distribution of power among these frequency components is then estimated. Only linear mechanisms governing the process are investigated because phase relationships between frequency components are suppressed. The information contained in the power spectrum is essentially present in the autocorrelation sequence. This is sufficient for the complete statistical description of a Gaussian process of known mean. However, there are practical situations where one must look beyond the power spectrum (autocorrelation) to obtain information regarding deviations from Gaussianness and presence of non-linearities in the system that generates the signals. Higher order spectra (also known as polyspectra), defined in terms of higher order cumulants of the process, do contain such information [43]. Particular cases of higher order spectra are the third-order spectrum also called the bispectrum which is, by definition, the Fourier transform of the third-order cumulant sequence, and the trispectrum (fourth-order spectrum), which is the Fourier transform of the fourth-order cumulant sequence of a stationary random process. The power spectrum is, in fact, a member of the class of higher order spectra, i.e., it is the second-order spectrum.

### 1. Motivation for Using Higher Order Spectra in Fault Detection

The general motivation behind the use of higher order spectra in signal processing is threefold: 1) to extract information due to deviations from Gaussianness, 2) to estimate the phase of non-Gaussian parametric signals, and 3) to detect and characterize the nonlinear properties of mechanisms that generate time-series via phase relationships of their harmonic components [43].

In this research, the motivation for using higher order spectra is based on the fact that the nonlinear properties of mechanisms can be characterized via phase relationships of their harmonic components. Using the phase relation information between harmonic components, some motor faults can be detected.

In this research, the amplitude modulation detector is developed from the concept of the bispectrum. In the following section, the bispectrum estimation is reviewed. bispectrum estimator, only one of the two sidebands, the plus relationship is considered, while in the AMD estimator, both plus and minus relationships are considered. This makes the AMD a more effective amplitude modulation estimator.

Most importantly, in the bispectrum calculation, the career frequency, the modulated frequencies, and resulting sidebands are all used, while in AMD calculation, only the career frequency and resulting sidebands are needed. In this research, tools are desired to isolate spatial harmonics that are modulated by the fundamental frequency of the supply. In power systems, the fundamental frequency of the supply is not biased. Hence, in the signal spectrum, only the fundamental frequency and the sidebands appear, and the spatial harmonics that are modulated with the fundamental frequency do not show up actually. In these types of applications, the bispectrum estimator cannot be used because the information of the spatial harmonics are not available.

All in all, AMD is more suitable to detect the amplitude modulation relationships encountered in this application than the bispectrum.

### 2. Development of the Amplitude Modulation Detector

To implement the Amplitude Modulation Detector estimation in computers, two important issues need to be addressed. One is the frequency resolution, the other is the expectation procedure.

a. One Dimensional Amplitude Modulation Detector

The AMD spectrum is a two dimensional matrix. The frequency resolution of AMD can be calculated by Δ=fₐ/N [43], where fₛ is the sampling rate and N is the sample numbers. A good frequency resolution will lead to a rather huge AMD matrix, which cannot be implemented easily using computers.

In this research, we are interested only in the frequency components that are modulated with some specified frequency; for example, the supply fundamental frequency. Therefore, it is possible to use only one dimensional AMD estimation. That is to only calculate AMD spectra that are modulated with the supply fundamental frequency.

b. Expectation on AMD to Distinguish Fault Signature Frequencies

The Amplitude Modulation Detector works as the phase coupling detector. If frequency components have phases that are coupled with each other, AMD components calculated will have zero phases and peaks will be exhibited at those frequencies indicating this phase relationship. To illustrate this, let's expand equation (3.9) as,

E[|X(k₁+k₂)|e^{j∠(k}^{₁}^{+k}^{₂})|X(k₁−k₂)|e^{j∠(k}^{₁}^{-k}^{₂})|X*(k₁)|e^{-j∠(k}^{₁}⁾|X*(k₁)|e^{-j∠(k}^{₁}⁾]. (3.10)

After grouping magnitude and phase terms together, we get,

E[|X(k₁+k₂)∥X(k₁−k₂)∥X*(k₁)∥X*(k₁)|e^{j(∠(k}^{₁}^{+k}^{₂}^{)+∠(k}^{₁}^{-k}^{₂}^{)-∠(k}^{₁}^{)-∠(k}^{₁}⁾⁾]. (3.11)

If there is phase coupling between the frequency components k₁ and k₂, then

∠(k₁+k₂)=∠(k₁)+∠(k₂), (3.12)

∠(k₁−k₂)=∠(k₁)−∠(k₂). (3.13)

By substituting equations (3.12) and (3.13) into equation (3.11), we see that the phase part of equation (3.11) equals zero. Equation (3.11) will equal the expected value of the product of the magnitudes. Therefore, if significant frequency components exist at k₁, k₁+k₂ and k₁−k₂, the detector will exhibit a peak at AMD(k₁, k₂), indicating that frequencies k₁ and k₂ are modulated components.

On the other hand, if there is no phase coupling between the frequency components k₁ and k₂, equations (3.12) and (3.13) are not valid and AMD components calculated will have random phases from sample to sample. The expectation operation will then cause these AMD components to approach zero after a sufficient number of samples are averaged together. Therefore, the AMD spectrum will not exhibit a peak at AMD(k₁,k₂) in the absence of phase coupling.

### C. Effect of Power Supply

### 1. Power Supply Mains

For induction motors, stator voltages can be considered as the system input, while stator currents can be considered as the system output. As the system input, the stator voltage affects the stator current heavily, especially in the practical industrial environment where ‘clean’ power input is usually not available. Because of this, fault signature in stator current spectrum may be masked by frequency components originating from the stator voltage.

In the laboratory environment, clean power input can be provided using big transformers. However, in most practical industrial environments where the power supply system is not big enough compared with the rated power of machines, motor input voltages are affected by other equipment under the same power supply. Noise related harmonics produced in that equipment are interacting with motor input voltages and affect the stator currents in an unpredictable way.

One experiment was conducted to illustrate effects of noise related harmonics in motor voltages. In this experiment, the motor is in healthy condition with 0% load. Data are collected every minute.

The voltage Root Mean Square (RMS), the voltage imbalance, the voltage Total Harmonic Distortion (THD), and the voltage Signal to Noise Ratio (SNR) are calculated for the data collected (see Appendix (B)). Table II lists test results for the first ten data sets. The experimental results show that the voltage RMS, imbalance, and THD values do not change much. But, the SNR changes more than 300%.

TABLE II
Motor Input Voltage Variables, Averaging Three Line Voltages

| Data | | Imbalance | THD | SNR |
|---|---|---|---|---|
| Sets | RMS | (10⁻³) | (10⁻²) | (10²) |
| 1 | 3.611319 | 3.724 | 2.7888 | 5.596 |
| 2 | 3.610595 | 3.661 | 2.7753 | 5.605 |
| 3 | 3.612443 | 4.033 | 2.7867 | 4.423 |
| 4 | 3.612354 | 4.076 | 2.784 | 3.045 |
| 5 | 3.615914 | 4.172 | 2.7219 | 5.488 |
| 6 | 3.612687 | 4.048 | 2.782 | 5.219 |
| 7 | 3.610440 | 4.167 | 2.7599 | 3.715 |
| 8 | 3.611955 | 4.114 | 2.7715 | 1.553 |
| 9 | 3.610664 | 4.099 | 2.7761 | 1.313 |
| 10 | 3.611990 | 4.130 | 2.7658 | 2.026 |

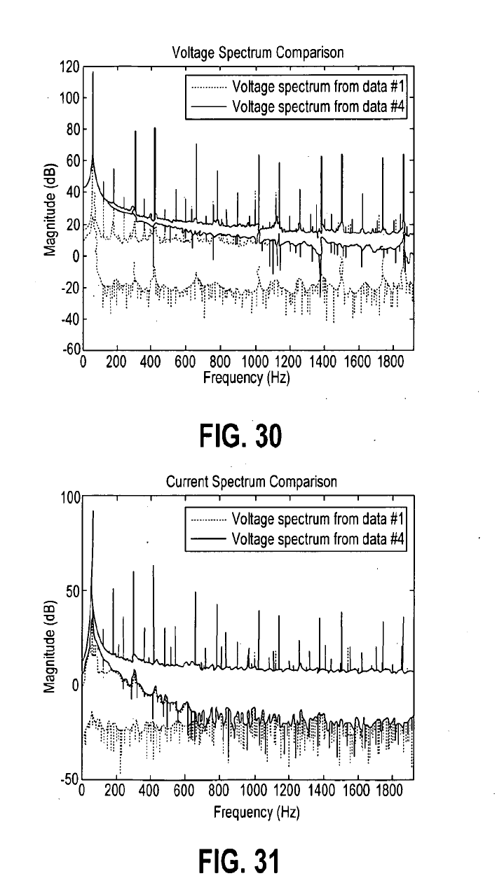

In FIG. 30, two voltage spectra, calculated from data 1 and 4 in Table II are shown. In these two voltage spectra, although differences in the integer harmonics are small, differences in the inter-harmonics are rather big. Corresponding current spectra are shown in FIG. 31. It is obvious that the entire current noise level in data set 1 is lower than that in data set 4. It is reasonable to conclude that differences between two current spectra come from differences between two voltage spectra.

Bearing faults alter stator current inter-harmonics. If the effect of the voltage is not removed, changes in the current spectrum caused by the voltage input may mask the fault information. This will be shown in the next chapter.

### 2. Voltage Source Inverter

a. Overview of Voltage Source Inverters

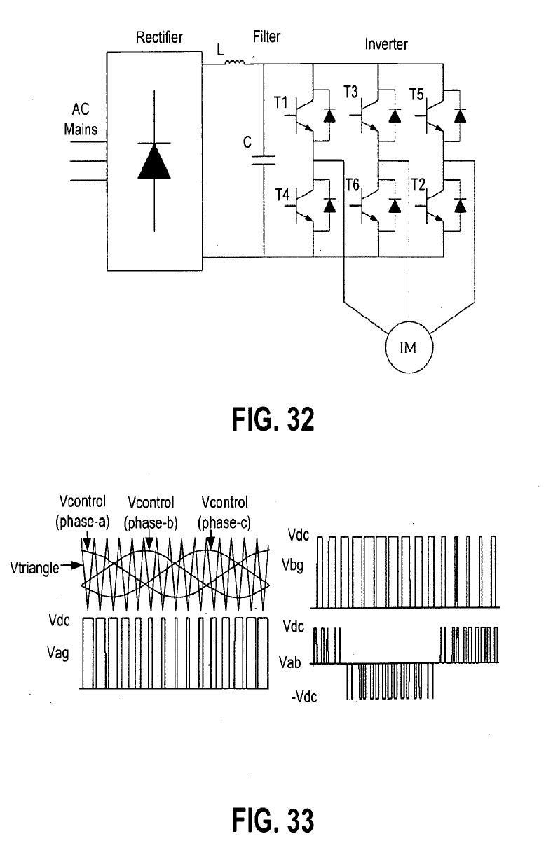

Voltage source inverters allow a variable frequency supply to be obtained from a dc supply. FIG. 32 shows a VSI employing transistors. Any other self-commutated device can be used instead of a transistor. Generally, MOSFET is used in low voltage and low power inverters. IGBT (Insulated Gate Bipolar Transistor) and power transistors are used up to medium power levels. GTO (Gate Turn Off Thyristor) and IGCT (Insulated Gate Commutated Thyristor) are used for high power levels [44].

VSIs can be operated as a stepped wave inverter or a pulse width modulated (PWM) inverter. When operated as a stepped wave inverter, transistors are switched in the sequence of their numbers with a time difference of T/6 and each transistor is kept on for the duration T/2, where T is the time period of one cycle. Frequency of inverter operation is varied by varying T and the output voltage of the inverter is varied by varying DC input voltage. When supply is DC, variable DC input voltage is obtained by connecting a chopper between DC supply and the inverter. When supply is AC, variable DC input voltage is obtained by connecting a controlled rectifier between AC supply and the inverter. A large electrolytic filter capacitor C is connected in the DC link to make inverter operation independent of the rectifier or chopper and to filter out harmonics in DC link voltage [44].

The main drawback of stepped wave inverter is the large harmonics of low frequency in the output voltage. When inverter is operated as a PWM inverter, harmonies are reduced, low frequency harmonics are eliminated, associated losses are reduced, and smooth motion is obtained at low speeds. FIG. 33 shows output voltage waveform for sinusoidal PWM. This voltage waveform is not pure sinusoidal, but a combination of square waves. Since output voltage can be controlled by PWM, no arrangement is required for the variation of input DC voltage [44]. Hence, the inverter can be directly connected when the supply is DC or through a diode rectifier when the supply is AC, as shown in FIG. 32. In this research, a PWM inverter is used.

b. Constant V/Hz Control for Induction Motors

For induction motor fault detection, inverter control schemes need to be investigated. Several control schemes are used in PWM voltage source inverters, the V/Hz control, the Field Orientation Control (FOC), arid the Direct Torque Control (DTC). The V/Hz control is used in this research because of its wide applicability in industry.

Assume the voltage applied to a three phase AC induction motor is sinusoidal v(t)=V_{M} sin(wt), and neglect the voltage drop across the stator resistor. The flux φ in the core of the induction motor can be found from Faraday's Law [45],

$$\begin{matrix}v ( t ) = - N \frac{d φ}{d t} , & ( 3.14 ) \\ \begin{matrix}φ ( t ) = \frac{1}{N} \int v ( t ) d t \\ = \frac{1}{N} \int {V}_{M} sin ( ω t ) d t \\ = - \frac{{V}_{M}}{ω N} cos ( ω t ) \\ = - \frac{{V}_{M}}{2 π \int N} cos ( ω t ) ,\end{matrix} & ( 3.15 )\end{matrix}$$

where N is the number of winding, V_{M} is the voltage magnitude and f is the frequency.

Induction motors are normally designed to operate near the saturation point on their magnetization curves, so the increase in flux due to a decrease in frequency will cause excessive magnetization currents to flow in the motor. To avoid excessive magnetization currents, it is customary to decrease the applied stator voltage in direct proportion to the decrease in frequency whenever the frequency falls below the rated frequency of the motor.

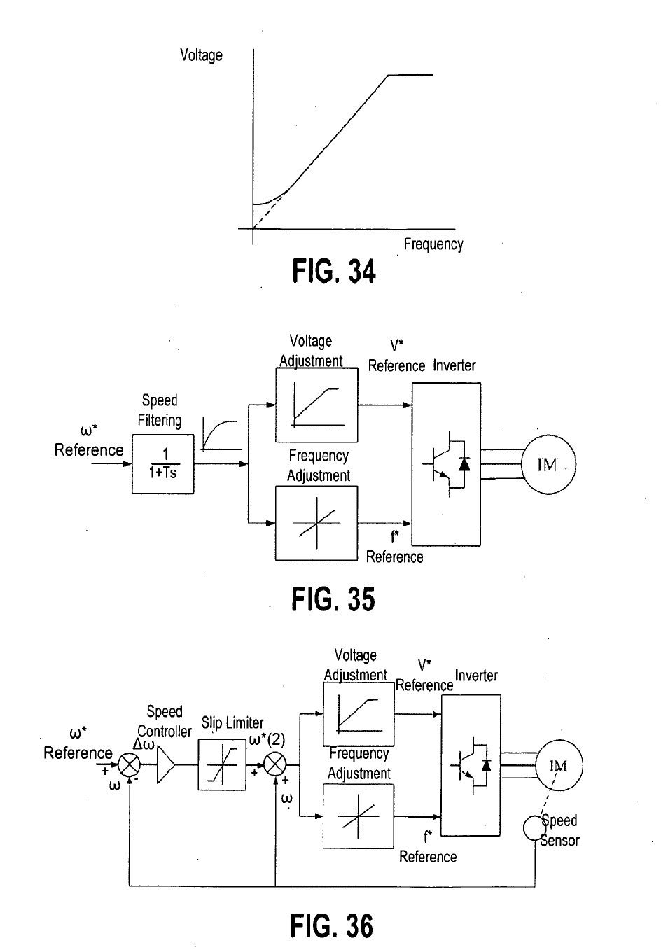

From equation (3.15), it follows that if the ratio V/f remains constant with the change of f, then the flux remains constant too and the torque is independent of the supply frequency. In actual implementation, the ratio between the magnitude and frequency of the stator voltage is usually based on the rated values of these variables or motor ratings. However, when the frequency and, hence, the voltage are low, the voltage drop across the stator resistance cannot be neglected and must be compensated. At frequencies higher than the rated value, the constant V/Hz principle has to be violated in order to avoid insulation breakdown. The stator voltage must riot exceed its rated value. This principle is illustrated in FIG. 34.

Since the stator flux is maintained constant, independent of the change in supply frequency, the torque developed depends on the slip speed [46]. So, by regulating the slip speed, the torque and speed of an AC induction motor can be controlled with the constant V/Hz principle.

Both open-loop and closed-loop control of the speed of an AC induction motor can be implemented based on the constant V/Hz principle. Open-loop speed control is used when accuracy in speed response is not a concern such as in HVAC (Heating, Ventilation, and Air Conditioning), fan, or blower applications. In this case, the supply frequency is determined based on the desired speed and the assumption that the motor will roughly follow its synchronous speed. FIG. 35 shows how the frequency f and the output voltage V of the inverter are proportionately adjusted with the speed reference. The speed reference signal is normally passed through a filter that only allows a gradual change in the frequency f [46].

When accuracy in speed response is a concern, closed-loop speed control can be implemented with the constant V/Hz principle through regulation of slip speed, as illustrated in FIG. 36. In this scheme, the slip limiter is used so that the motor is allowed to follow the change in the supply frequency without exceeding the rotor current and torque limits. The motor speed is sensed and added to a limited speed error (or limited slip speed) to obtain the frequency.

c. Motor Bearing Fault Detection Under VSI Operation

Voltage source inverters are widely used in industry. When the motor is driven by a voltage source inverter, the motor input voltages are isolated from outside devices since most noise outside of the system usually can not pass through the DC line in the inverter, as shown in FIG. 32. Hence, input voltage variations from supply mains do not affect stator currents in motors energized by VSI. However, fault detection of induction motors energized by VSI faces two problems,
The symptoms of internal faults of induction motors may be masked by the control of the drive system.
Harmonics from the inverter are much richer than that from power supply mains. This makes the fault detection difficult.

The control of the drive system affects the bearing fault detection in two aspects. One is the control scheme itself, the other is the speed feedback loop.

For voltage source inverters, controlled variables are finally utilized to adjust the voltage fundament frequency supplied by the VSI. In the proposed method, the current fundamental frequency, which comes from the voltage supplied by the VSI, is used for the AMD estimation. This fundamental frequency is adjusted according to the inverter speed set point and the speed feedback loop. For motors working in the steady state operation condition, the fundamental frequency does not change so that the VSI control schemes do not affect the bearing fault detection.

The bandwidth of the speed feedback loop usually is a degree of freedom set by the user. Extra frequency components may be introduced into current spectra because of the speed feedback loop. These frequency components are unpredictable. The closed-loop experiment conducted in this research show that the bearing fault signatures are not masked by the VSI speed feedback control.

The biggest problem in motor bearing fault detection using VSI is the rich harmonies. The VSI outputs are not pure sinusoidal, as shown in FIG. 33. Inverters switching on and off produces large inter-harmonics in the voltage spectra. These inter-harmonics are injected into current spectra, which causes problems when trying to detect motor bearing faults.

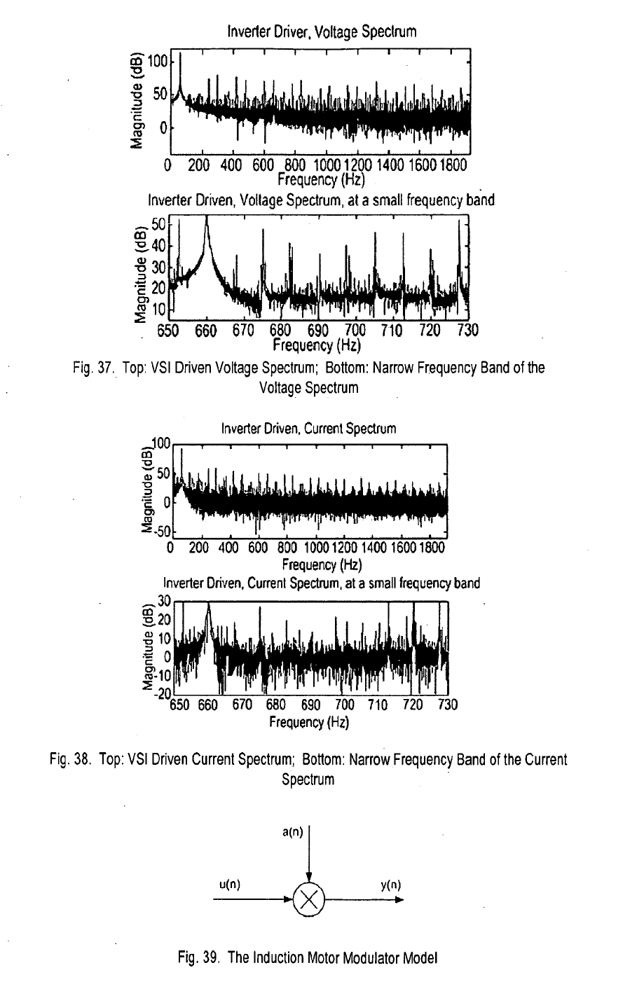

The motor stator voltage and current spectra are shown in FIGS. 37 and 38. Also in these two figures, narrow frequency band spectra are shown so that inter-harmonics can be seen clearly. Because of these big inter-harmonics, motor bearing fault signatures may be masked. This is the main reason that very few papers have been published in the VSI driven motor fault detection area.

### D. Electrical AMD Indicators

### 1. Modulation Model

General induction motor voltage equations in terms of machine variables can be expressed as,

v_{abcs}=τₛi_{abcs}+pλ_{abcs}, (3.16)

v_{abcr}=τ_{τ}i_{abcr}+pλ_{abcr}. (3.17)

where p is the derivative calculator; the s subscript denotes variables and parameters associated with the stator circuits, and the r subscript denotes variables and parameters associated with the rotor circuits; and,

(f_{abcs})^{T}=[fₐₛ f_{bs} f_{cs}],

(f_{abcr})^{T}=[fₐᵣ f_{br} f_{cr}],

For a magnetically linear system, the flux linkages may be expressed,

$$[ \begin{matrix}{λ}_{abcs} \\ {λ}_{abcr}\end{matrix} ] = [ \begin{matrix}{L}_{s} & {L}_{sr} ( {θ}_{m} ( t ) ) \\ {L}_{sr}^{T} ( {θ}_{m} ( t ) ) & {L}_{r}\end{matrix} ] [ \begin{matrix}{i}_{abcs} \\ {i}_{abcr}\end{matrix} ] , \qquad ( 3.18 )$$

where θₘ(t) is the mechanical rotating angle of the rotor. The winding inductances, Lₛ, Lᵣ and Lₛᵣ(θₘ(t)) are complex functions of angular rotor positions and other machine design parameters. They are given in [47].

For a squirrel cage induction motor, v_{abcr}=0. Substituting equation (3.18) into equations (3.16) and (3.17), we get,

v_{abcs}=rₛi_{abcs}+Lₛ(pi_{abcs})+(pLₛᵣ(θₘ(t)))i_{abcr}+Lₛᵣ(θₘ(t))(pi_{abcr}), (3.19)

0=rᵣi_{abcr}+(pLₛᵣ^{T}(θₘ(t))i_{abcs}+Lₛᵣ^{T}(θₘ(t))(pi_{abcs})+Lᵣ(pi_{abcr}). (3.20)

At steady state, equations (3.19) and (3.20) can be expressed in the time phasor form as follows,

\tilde{V}ₛ(t)=(rₛ+jwₛLₛ)Îₛ(t)+(jωₛLₛᵣ(θₘ(t)))Ĩᵣ(t), (3.21)

0=jwᵣLₛᵣ^{T}(θₘ(t))Ĩₛ(t)+(rᵣ+jωᵣLᵣ)Ĩᵣ(t). (3.22)

The detailed derivation can be found in [47].

In equation (3.22), assuming that (rᵣ+jwᵣLᵣ) is invertible, the time phasor Ĩᵣ(t) can be expressed by,

$${\tilde{I}}_{r} ( t ) = - \frac{j {ω}_{r} {L}_{sr}^{T} ( {θ}_{m} ( t ) )}{{r}_{r} + j {ω}_{r} {L}_{r}} {\tilde{I}}_{s} ( t ) . \qquad ( 3.23 )$$

Substituting equation (3.24) into equation (3.21), we have,

$${\tilde{V}}_{s} ( t ) = ( {r}_{s} + j {ω}_{s} {L}_{s} + \frac{{ω}_{s} {ω}_{r} {L}_{sr} ( {θ}_{m} ( t ) ) {L}_{sr}^{T} ( {θ}_{m} ( t ) )}{{r}_{r} + j {ω}_{r} {L}_{r}} ) {\tilde{I}}_{s} ( t ) . \qquad ( 3.24 )$$

Assuming

$$( {r}_{s} + j {ω}_{s} {L}_{s} + \frac{{ω}_{s} {ω}_{r} {L}_{sr} ( {θ}_{m} ( t ) ) {L}_{sr}^{T} ( {θ}_{m} ( t ) )}{{r}_{r} + j {ω}_{r} {L}_{r}} )$$

is invertible, we obtain the following relationship between stator voltages and currents,

$$\begin{matrix}{\tilde{I}}_{s} ( t ) = {[ {r}_{s} + {jω}_{s} {L}_{s} + \frac{{ω}_{s} {ω}_{r} {L}_{sr} ( {θ}_{m} ( t ) ) {L}_{ST}^{T} ( {θ}_{m} ( t ) )}{{r}_{r} + {jω}_{T} {L}_{T}} ]}^{- 1} {\tilde{V}}_{s} ( t ) . & ( 3.25 ) \\ {\tilde{I}}_{s} ( t ) = {[ Z ( {θ}_{m} ( t ) ) ]}^{- 1} {\tilde{V}}_{s} ( t ) . & ( 3.26 )\end{matrix}$$

In general, equation (3.26) is linear in terms of the voltages and currents. However, this relation is representative of a non-linear system, i.e. a modulator, as the inverse of the impedance is made of time-varying and nonlinearly coupled terms. Assuming the voltage to be a single frequency signal, the current will be composed of frequencies beyond the single input voltage frequency, made up of modulated components. This frequency shifts are indicative of a nonlinear system.

Based on this, an induction motor at steady state can be modeled as a modulator as shown in FIG. 39 where u(n) is the system input, the stator voltage; a(n) is an unknown signal which contains the spatial frequencies of the motor, represented by [Z(θₘ)]⁻¹: and y(n) is the system output, the stator current.

Assuming a(n) to be periodic, it can be written as,

$$a ( n ) = {A}_{0} + {\sum }_{i = 1}^{k} {A}_{i} cos ( {ω}_{i} n + {φ}_{i} ) . \qquad ( 3.27 )$$

The system output is given by,

$$y ( n ) = a ( n ) u ( n ) = [ {A}_{0} + {\sum }_{i = 1}^{k} {A}_{i} cos ( {ω}_{i} n + {φ}_{i} ) ] u ( n ) . \qquad ( 3.28 )$$

In the frequency domain, the corresponding system output is,

$$Y ( ω ) = {A}_{0} U ( ω ) + \frac{1}{2} {\sum }_{i = 1}^{k} {A}_{i} [ \begin{matrix}{e}^{- {jφ}_{i}} U ( ω + {ω}_{i} ) + \\ {e}^{{jφ}_{i}} U ( ω - {ω}_{i} )\end{matrix} ] . \qquad ( 3.29 )$$

A special frequency phasor is defined as,

aᵢ≡Aᵢe^{-jφi}. (3.30)

Equation (3.29) can be written as,

$$Y ( ω ) = {A}_{0} U ( ω ) + \frac{1}{2} {\sum }_{i = 1}^{k} [ \begin{matrix}{a}_{i} U ( ω + {ω}_{i} ) + \\ {a}_{i}^{*} U ( ω - {ω}_{i} )\end{matrix} ] . \qquad ( 3.31 )$$

The AMD estimation can be re-written as,

A\hat{M}D(ω)=Y(ω₀+ω)Y(ω₀−ω)Y*(ω₀)Y*(ω₀) (3.32)

where ω₀ is the fundamental supply frequency.

Based on equation (3.31), equation (3.32) can be written as,

$$\begin{matrix}{Y}^{*} ( {ω}_{0} ) = {A}_{0} {U}^{*} ( {ω}_{0} ) + \frac{1}{2} {\sum }_{i = 1}^{k} [ \begin{matrix}{a}_{i}^{*} {U}^{*} ( {ω}_{0} + {ω}_{i} ) + \\ {a}_{i} {U}^{*} ( {ω}_{0} - {ω}_{i} )\end{matrix} ] , & ( 3.33 ) \\ Y ( {ω}_{0} + ω ) = {A}_{0} U ( {ω}_{0} + ω ) + \frac{1}{2} {\sum }_{i = 1}^{k} [ \begin{matrix}{a}_{i} U ( {ω}_{0} + ω + {ω}_{i} ) + \\ {a}_{i}^{*} U ( {ω}_{0} + ω - {ω}_{i} )\end{matrix} ] , & ( 3.34 ) \\ Y ( {ω}_{0} - ω ) = {A}_{0} U ( {ω}_{0} - ω ) + \frac{1}{2} {\sum }_{i = 1}^{k} [ \begin{matrix}{a}_{i} U ( {ω}_{0} - ω + {ω}_{i} ) + \\ {a}_{i}^{*} U ( {ω}_{0} - ω - {ω}_{i} )\end{matrix} ] . & ( 3.35 )\end{matrix}$$

Let T₁ and T₂ be the summation terms in equations (3.34) and (3.35),

$$\begin{matrix}{T}_{1} ( ω ) = {\sum }_{i = 1}^{k} [ {a}_{i} U ( {ω}_{0} + ω + {ω}_{i} ) + {a}_{i}^{*} U ( {ω}_{0} + ω - {ω}_{i} ) ] , & ( 3.36 ) \\ {T}_{2} ( ω ) = {\sum }_{i = 1}^{k} [ {a}_{i} U ( {ω}_{0} - ω + {ω}_{i} ) + {a}_{i}^{*} U ( {ω}_{0} - ω - {ω}_{i} ) ] . & ( 3.37 )\end{matrix}$$

Obviously, these terms depend on the system input.

Suppose the system input contains a fundamental, the fundamental's integer harmonics, and noise. The representation of the system input in the frequency domain is as follows,

$$U ( ω ) = \{ \begin{matrix}{s}_{1} , & ω = {ω}_{0} \\ {s}_{2} , & ω = 2 {ω}_{0} \\ {s}_{3} , & ω = 3 {ω}_{0} \\ ⋮ & ⋮ \\ {s}_{p} , & ω = p {ω}_{0} \\ m , & ∀ ω \neq l {ω}_{0}\end{matrix} \qquad ( 3.38 )$$

where ω₀ and s₁ are the fundamental frequency and its magnitude, respectively; s₂, s₃, . . . , sₚ are magnitudes of integer harmonics; m is the noise level, and l=1, 2, . . . , p.

Generally, for induction motor supply, the magnitude of the fundamental frequency is far larger than the magnitude summation of all other frequencies. Hence, we have,

$$\vert {s}_{1} \vert >> {\sum }_{i = 2}^{p} \vert {s}_{i} \vert + \int \vert m \vert d ω . \qquad ( 3.39 )$$

At any frequency ωₛ, T₁(ωₛ) can be calculated based on the input, equation (3.38), as follows,

$$\begin{matrix}{T}_{1} ( {ω}_{s} ) = {\sum }_{i = 1}^{k} [ \begin{matrix}{a}_{i} U ( {ω}_{0} + {ω}_{s} + {ω}_{i} ) + \\ {a}_{i}^{*} U ( {ω}_{0} + {ω}_{s} - {ω}_{i} )\end{matrix} ] \\ = {a}_{s}^{*} U ( {ω}_{0} ) + {a}_{s} U ( {ω}_{0} + 2 {ω}_{s} ) + \\ {\sum }_{i = 1}^{s - 1} [ \begin{matrix}{a}_{i} U ( {ω}_{0} + {ω}_{s} + {ω}_{i} ) + \\ {a}_{i}^{*} U ( {ω}_{0} + {ω}_{s} - {ω}_{i} )\end{matrix} ] + \\ {\sum }_{i = s + 1}^{k} [ \begin{matrix}{a}_{i} U ( {ω}_{0} + {ω}_{s} + {ω}_{i} ) + \\ {a}_{i}^{*} U ( {ω}_{0} + {ω}_{s} - {ω}_{i} )\end{matrix} ] .\end{matrix} \qquad ( 3.40 )$$

Because U(ω) can take values from s₁ to sₖ and m, the resulting expressions for equation (3.40) are not unique. Using bᵢ, cⱼᵢ, and Qᵢ as dummy variables, equation (3.40) can be written as,

$$\begin{matrix}{T}_{1} ( {ω}_{s} ) = {a}_{s}^{*} {s}_{1} + {b}_{1} m + {b}_{2} {s}_{2} + {b}_{3} {s}_{3} + … + {b}_{k} {s}_{k} + {\sum }_{i = 1}^{Q 1} {c}_{1 i} m + \\ {\sum }_{i = 1}^{Q 2} {c}_{2 i} m + {\sum }_{i = s + 1}^{Q 3} {c}_{3 i} m + {\sum }_{i = s + 1}^{Q 4} {c}_{4 i} m \\ = {a}_{s}^{*} {s}_{1} + {\sum }_{i = 2}^{p} {b}_{i} {s}_{i} + m ( \begin{matrix}{b}_{1} + {\sum }_{i = 1}^{Q 1} {c}_{1 i} + {\sum }_{i = 1}^{Q 2} {c}_{2 i} + \\ {\sum }_{i = s + 1}^{Q 3} {c}_{3 i} + {\sum }_{i = s + 1}^{Q 4} {c}_{4 i}\end{matrix} ) \\ = {a}_{s}^{*} {s}_{1} + {\sum }_{i = 2}^{p} {b}_{i} {s}_{i} + {c}_{i} m ,\end{matrix} \qquad ( 3.41 )$$

where cᵢ=b₁+Σᵢ₌₁^{Q1}c₁ᵢ+Σᵢ₌₁^{Q2}c₂ᵢ+Σᵢ₌ₛ₊₁^{Q3}c₃ᵢ+Σᵢ₌ₛ₊₁^{Q4}c₄ᵢ; aᵢ's are spatial harmonics in a(n); b₁ and cⱼᵢ can take values among 0, aᵢ, aᵢ* or summation of aᵢ and aᵢ*; and b₂, b₃, . . . , bₖ can take values among 0, aᵢ and aᵢ*.

Compared to the magnitude of the fundamental frequency, aᵢ, bᵢ, cⱼᵢ, and m are very small. Further, assume aₛ, bᵢ, and cᵢ have comparable values. Using equation (3.39), equation (3.41) becomes,

T₁(ωₛ)≈aₛ*s₁, (3.42)

Following the same procedure, T₂ can be written as,

T₂(ωₛ)≈aₛs₁ (3.43)

Signature frequencies caused by bearing generalized faults are distributed in wide frequency bands. They are mostly located in inter-harmonics. Integer harmonics of the supply fundamental frequency usually have big magnitudes compared with other inter-harmonics. In order to detect variations in inter-harmonics, the integer harmonics must be removed from the final AMD spectrum. Hence, the integer harmonics of the fundamental frequency are not present in the spectrum of a(n). Hence,

ωᵢ≠qω₀, q=1, 2, . . . , p, (3.44)

U(ω₀±ωᵢ)=m, (3.45)

where ωᵢ's are spatial harmonics in a(n). Based on the above simplification, at frequency ωₛ, equations (3.33), (3.34), and (3.35) can be re-written as,

$$\begin{matrix}{Y}^{*} ( {ω}_{0} ) = {A}_{0} {s}_{1}^{*} + \frac{1}{2} {m}^{*} {\sum }_{i = 1}^{k} [ {a}_{i}^{*} + {a}_{i} ] \\ = {A}_{0} {s}_{1}^{*} + {m}^{*} {\sum }_{i = 1}^{k} {A}_{i} cos {φ}_{i} \\ \approx {A}_{0} {s}_{1}^{*} .\end{matrix} \qquad ( 3.46 )$$

The term, m* Σᵢ₌₁^{k} Aᵢ cos φᵢ, can be ignored compared with A₀s₁*, so,

$$\begin{matrix}Y ( {ω}_{0} + {ω}_{s} ) = {A}_{0} m + \frac{1}{2} {T}_{1} \approx {A}_{0} m + \frac{1}{2} {a}_{s}^{*} {s}_{1} \approx \frac{1}{2} {a}_{s}^{*} {s}_{1} , \\ and , & ( 3.47 ) \\ Y ( {ω}_{0} - {ω}_{s} ) = {A}_{0} m + \frac{1}{2} {T}_{2} \approx {A}_{0} m + \frac{1}{2} {a}_{s} {s}_{1} \approx \frac{1}{2} {a}_{s} {s}_{1} . & ( 3.48 )\end{matrix}$$

The composite AMD estimator at frequency ωₛ becomes,

$${AMD}^{⋒} ( {ω}_{s} ) = Y ( {ω}_{0} + {ω}_{s} ) Y ( {ω}_{0} - {ω}_{s} ) {Y}^{*} ( {ω}_{0} ) {Y}^{*} ( {ω}_{0} ) \approx \frac{1}{4} {A}_{0}^{2} {\vert {a}_{s} \vert}^{2} {\vert {s}_{1} \vert}^{4} . \qquad ( 3.49 )$$

Various forms of this AMD indicator are used in this research to obtain the experimental results presented in later chapters.

### E. Mechanical Vibration Indicator

In this research, mechanical vibration signals are also collected with the electrical signals. The vibration signals are used for two purposes.

First, vibration signals are used to monitor the bearing damage process. During the experiment, vibration level is changing with the deterioration of the bearing. By looking at the vibration level, the experiment can be controlled.

Second, the vibration fault indicator is used as a reference for the fault detection capability of the electrical AMD indicator.

In this research, the aggregate RMS values of the vibration signals are calculated as the vibration indicator.

The RMS of vibration signal is defined as follows,

$$Indicator\_vib = \sqrt{\frac{1}{N} {\sum }_{i = 1}^{N} {x ( i )}^{2}} , \qquad ( 3.50 )$$

where x(i) is the vibration sample and N is the total number of samples used in the RMS calculation,

### F. Chapter Summary

Bearing failures can be captured in frequencies that are modulated with the fundamental frequency and all other harmonics of the supply. This modulation relationship can be isolated using the phase coupling between the bearing fault frequencies and the supply fundamental frequency. An Amplitude Modulation Detector (AMD), which is developed from the higher order spectrum estimation, can correctly capture the phase coupling and isolate these modulation relationships. This is the proposed approach for this research.

In this chapter, estimation procedures of the AMD are introduced. Effects of supply voltages on stator currents are discussed both for motors energized by power supply mains and VSI type drives. Based on this, the modulation model and electrical AMD indicator are derived. Moreover, a mechanical vibration indicator is also provided. This indicator is used to control the bearing damage experiments, and as a reference for testing the fault detection capability of the electrical AMD indicator.

### REFERENCES

[1] R. R. Schoen and T. G. Habetler. “Effects of Time-Varying Loads on Rotor Fault Detection in Induction Machines,” IEEE Transactions on Industry Applications, vol. 31, no. 4, pp. 900-906, July 1995.
[2] P. F. Albrecht, J. C. Appiarius, R. M. McCoy, E. L. Owen, and D. K. Sharma, “Assessment of the Reliability of Motors in Utility Applications—Updated,” IEEE Transactions on Energy Conversion, vol. EC-1, no. 1, pp. 39-46, March 1986.
[3] IAS Motor Reliability Working Group, “Report of Large Motor Reliability Survey of Industrial and Commercial Installations, Part I,” IEEE Transactions on Industry Applications, vol. IV-21, no. 4, pp. 853-864, July 1985.
[4] M. E. H. Benbouzid, “What Stator Current Processing-Based Technique to Use for Induction Motor Rotor Faults Diagnosis,” IEEE Transactions on Engergy Conversion, vol. 18, no. 2, June. 2003.
[5] P. J. Tavner and J. Penman, Condition Monitoring of Electrical Machines, Letchworth, UK: Research Studies Press, 1987.
[6] K. Kim, A. G. Parlos and R. M. Bharadwaj, “Sensorless Fault Diagnosis of Induction Motors,” IEEE Transactions on Industrial Electronics, vol. 50, no. 5, pp. 1038-1051, October, 2003.
[7] P. M. Frank, “Robust Model-Based Fault Detection in Dynamic Systems,” in On-Line Fault Detection and Supervision in the Chemical Process Industries, P. S. Dhurjati and G. Stephanopoulos, Oxford, UK: Pergamon Press, 1993, vol. 1, pp. 1-13.
[8] G. B. Kliman and J. Stein, “Methods of Motor Current Signature Analysis,” Electric Machines and Power Systems, vol. 20, no. 5, pp. 463-474, September 1992.
[9] J. R. Cameron, W. T. Thomson, and A. B. Dow, “On-Line Current Monitoring of Induction Motors—A Method for Calculating the Level of Air-Gap Eccentricity,” in IEEE 3rd International Conference on Electric Machines and Drives, pp. 173-177, IEE Publication no. 282, November 1987.
[10] A. J. Marques-Cardoso and E. S. Saraiva, “Computer-Aided Detection of Air-Gap Eccentricity in Operating Three-Phase Induction Motors, by Park's Vector Approach,” IEEE Transactions on Industry Applications, vol. 29, no. 5, pp. 165-171, September 1993.
[11] P. Torasso and L. Console, Diagnostic Problem Solving, Oxford, UK: North Oxford Academic, 1989.
[12] L. F. Pau, “Survey of Expert Systems for Fault Detection, Test Generation, and Maintenance,” Expert Systems, vol. 3, no. 2, pp. 100-111, April 1986.
[13] S. L. Fulton and C. O. Pepe, “An Introduction to Model-Based Resoning,” AI Expert, pp. 48-55, January 1990.
[14] A. S. Willsky, “A Survey of Design Methods for Failure Detection in Dynamic Systems,” Automatica, vol. 12, pp. 601-611, 1976.
[15] R. Isermann and P. Ball, “Trends in the Appication of Model-Based Fault Detection and Diagnosis of Technical Processes,” in Proc. of the 13th IFAC World Congress, pp. 1-12, Piscataway, N.J.: IEEE Press, 1996.
[16] R. O. Duda and P. E. Hart, Pattern Classification and Scene Analysis, New York: John Wiley & Sons, 1973.
[17] T. Asakura, T. Kobayashi, and S. Hayashi, “A Study of Fault Diagnosis System Using Neural Networks,” in Proc. of the 29th ISCIE International Symposium on Stochastic Systems Theory and Its Applications, pp. 19-24, Tokyo, Japan, 1998.
[18] D. M. Himmelblau, “Use of Artificial Neural Networks to Monitor Faults and for Troubleshooting in the Process Industries,” in IFAC Symposium On-Line Fault Detection and Supervision in the Chemical Process Industry, pp. 89-99, Oxford, UK: Pergamon Press, 1992.
[19] S. Becker, “Unsupervised Learning Procedures for Neural Networks,” International Journal of Neural Systems, vol. 2, no. 1, pp. 17-33, Spring 1991.
[20] J. R. Stack, “Fault Classification and Fault Signature Production for Rolling Element Bearings in Electric Machines,” IEEE Transactions on Industry Applications, vol. 40, no. 3, May/June 2004.
[21] R. R. Schoen, “Motor Bearing Damage Detection Using Stator Current Monitoring,” IEEE Transactions on Inductry Applications, vol. 31, no. 6, November/December 1995.
[22] J. R. Stack, “An Amplitude Modulation Detector for Fault Diagnosis in Rolling Element Bearings,” IEEE Transactions on Industrial Electronics, vol. 51, no. 5, October 2004.
[23] R. R. Obaid, Thomas G. Habetler, and J. R. Stack, “Stator Current Analysis for Bearing Damage Detection in Induction Motors,” Symposium on Diagnostics for Electric Machines, Power Electrionics and Drives, Atlanta, Ga., 24-26 Aug. 2003.
[24] I. Y. Onel, K. B. Dalci and I. Senol, “Detection of Outer Raceway Bearing Defects in Small Induction Motors Using Stator Current Analysis,” Sadhana, vol. 30, Part. 6, pp. 713-722, December 2005.
[25] M. Blodt, P. Granjon, B. Raiso and G. Rostaing, “Models for Bearing Damage Detection in Induction Motors Using Stator Current Monitoring,” IEEE International Symposium, vol. 1, pp. 383-388, May 2004.
[26] B. Yazici and, G. B. Kilman, “An Adaptive Statistical Time-frequency Method for Detection of Broken Bars and Bearing Faults in Motors Using Stator Current,” IEEE Transaction on Industry Applications, vol. 35, pp. 442-452, March/April 1999.
[27] L. Eren and M. J. Devaney, “Bearing Damage Detection via Wavelet Packet Decomposition of the Stator Current,” IEEE Transaction on Instrumentation and Measurement, vol. 53, no. 2, April 2004.
[28] J. R. Stack, “Bearing Fault Detection via Autoregressive Stator Current Modeling,” IEEE Transactions on Industry Applications, vol. 40, no. 3, May/June 2004.
[29] D. N. Zmood and D. G. Holmes, “Improved Voltage Regulation for Current Source Inverters,” In Conference Record of the 2000 IEEE Industry Applications Conference Thirty-fifth IAS Annual Meeting, Rome, Italy, vol. 4, pp. 2353-2360, 2000.
[30] R. Wieser, M. Schagginger, et al, “The Integration of Machine Fault Detection into an Indirect Field Oriented Induction Machine Drive Control Scheme, the Vienna Monitoring Method”, Industry Applications Conference, Chicago, Ill., vol. 1, pp. 12-15, October 1998.
[31] R. Wieser and C. Kral, et al, “Online Rotor Cage Monitoring of Inverter Fed Induction Machines by Means of an Improved Method”, IEEE Transactions on Power Electronics, vol. 14, no. 5, September 1999.
[32] C. Kral, R. Wieser, et al, “Sequences of Field Oriented Control for the Detection of Faulty Rotor Bars in Induction Machines—the Vienna Monitoring Method”, IEEE Transactions on Industrial Electronics, vol. 47, no. 5, October 2000.
[33] A. Bellini and F. Filippetti, et al, “Classification of Diagnostic Indexes far Field Oriented Induction Motor Drives”, Symposium on Diagnostics for Electric Machines, Power Electronics and Drives, Atlanta, Ga., 24-26, August 2003.
[34] A. Bellini and F. Filippetti, et al, “Closed Loop Control Impact on the Diagnosis of Induction Motors Faults”, IEEE Transactions on Industry Applications, vol. 36, no. 5, September-October 2000.
[35] C. M Chen and K. A. Loparo, “Electric Fault Detection for Vector Controlled Induction Motors Using the Discrete Wavelet Transform”. Proceedings of the American Control Conference, Philadelphia, Pa., June 1998.
[36] R. M. Tallam, T. G. Habetler and R. G. Harley, “Stator Winding Turn-fault Detection for Closed Loop Induction Motor Drives”, IEEE Transactions on Industry Applications, vol. 39, Issue: 3, May-June 2003, p 720-724.
[37] J. Blattner, H. Gutt and V. Schlechter, “Sensorless Detection of Rotor Cage Defects for Inverter Fed Induction Motors”, Industrial Electronics Society, Proceedings of the 24th Annual Conference of the IEEE, vol. 4, pp. 2311-2315, August-September 1998.
[38] J. R. Stack, “Experimentally Generating Faults in Rolling Element Bearings Via Shaft Current,” IEEE Transactions on Industry Applications, vol. 41, no. 1, January/February 2005.
[39] H. Prashad, “Diagnosis of Rolling-element Bearings Failure by Localized Electrical Current between Track Surfaces of Races and Rolling-elements,” Journal of Tribology, vol. 124, no. 3, pp. 468-473, July 2002.
[40] D. F. Busse, J. M. Erdman, R. J. Kerkman, D. W. Schlegel, and G. L. Skibinski, “The Effects of PWM Voltage Source Inverters on the Mechanical Performance of Roller Bearings,” IEEE Transactions on Industry Applications, vol. 33, no. 2, pp. 567-576, March/April 1997.
[41] J. M. Erdman, R. J. Kerkman, D. W. Schlegel, and G. L. Skibinski, “Effect of PWM Inverts on AC Motor Bearing Currents and Shaft Voltages,” IEEE Transactions on Industry Applications, vol. 32, no. 2, pp. 250-259, March/April 1996.
[42] J. W. Choi, “Analysis of Electrical Signatures in Synchronous Generators Characterized by Bearing Faults,” M. S. Thesis, Mechanical Engineering, Texas A&M University. College Station, Texas, August 2006.
[43] C. L. Nikias and M. R. Raghuveer, “Bispectrum Estimation: A Digital Signal Processing Framework,” Proceedings of the IEEE., vol. 75, no. 7, July 1987.
[44] G. K. Dubey, Fundamentals of Electrical Drives, 2nd, Pangbourne, UK, Alpha Science International Ltd., 2001.
[45] S. J. Chapman, Electric Machinery Fundamentals, 3rd, New York, N.Y., McGraw-Hill, 1999.
[46] M. H. Rashid, Power Electronics Handbook, Burlington, Mass., Academic Press, 2001.
[47] P. C. Krause, O. Wasynczuk and S. D. Sudhoff, Analysis of Electric Machinery, New York. N.Y., IEEE Press, 1995.

1-8. (canceled)

9. A method for diagnosing conditions of rotating machines having respective operating voltages and operating currents, the method comprising the steps of:
receiving measured bus voltage and measured bus current by a device, wherein the bus voltage and bus current include operating voltage and operating currents to or from a group of rotating machines operating remote from a bus;
disaggregating the bus current by the device into disaggregated currents having correspondences with the operating currents to or from the respective rotating machines, wherein the disaggregating is responsive to the measured bus current; and
diagnosing deteriorating conditions of the respective rotating machines automatically by a device, wherein the operating voltage and disaggregated currents are the only operating conditions to which the diagnosing is responsive that are measured concurrently with the diagnosing.

10. The method of claim 9, wherein the diagnosing includes diagnosing deteriorating electrical conditions.

11. The method of claim 9, wherein the diagnosing includes diagnosing deteriorating mechanical conditions.

12. The method of claim 9, wherein the diagnosing includes diagnosing deteriorating electrical and mechanical conditions.

13. The method of claim 9, wherein the method comprises:
predicting remaining useful life for a respective rotating machine automatically by a device responsive to the diagnosed mechanical and electrical conditions of the respective rotating machine.

14. The method of claim 9, wherein the rotating machines include one or more motors.

15. The method of claim 14, wherein the rotating machines include one or more devices driven by the respective one or more motors.

16. The method of claim 9, wherein the rotating machines include one or more generators.

17. The method of claim 16, wherein the rotating machines include one or more drivers for the respective one or more generators.

18. The method of claim 9, wherein the disaggregating includes disaggregating by a device mounted local to the bus.

19. The method of claim 9, wherein the automatic diagnosing includes diagnosing by a device.mounted local to the bus.

20. The method of claim 9, wherein the device disaggregating the bus current includes a first logic element of an apparatus and the device diagnosing the mechanical conditions includes a second logic element of the apparatus.

21. The method of claim 9, wherein the method further comprises:
sending one or more signals by the device performing the automatic diagnosing, wherein the one or more signals indicate health of each of the rotating machines for presenting to a user or saving in a storage device.

22. The method of claim 9, comprising:
storing or presenting to a user an indication of health of each of the rotating machines by the device performing the automatic diagnosing.

23. A method for diagnosing at least one condition of a rotating machine having an operating voltage and operating current, the method comprising the steps of:
receiving a measured voltage and a measured current by a device, wherein the voltage and current include operating voltage and operating current to or from an operating rotating machine; and
diagnosing a deteriorating condition of the rotating machine automatically by a device, wherein the operating voltage and operating currents are the only operating conditions to which the diagnosing is responsive that are measured concurrently with the diagnosing.

24. The method of claim 23, wherein the diagnosing includes diagnosing a deteriorating electrical condition.

25. The method of claim 23, wherein the diagnosing includes diagnosing a deteriorating mechanical condition.

26. The method of claim 23, wherein the diagnosing includes diagnosing deteriorating electrical and mechanical conditions.

27. The method of claim 23, wherein the method comprises;
predicting remaining useful life for the rotating machine automatically by a device responsive to the dia_{g}nosed mechanical and electrical conditions of the rotating machine.

28. The method of claim 23, wherein the rotating machine includes a motor.

29. The method of claim 28, wherein the rotating machine includes a device driven by the motor.

30. The method of claim 23, wherein the rotating machine includes a generator.

31. The method of claim 30, wherein the rotating machine includes a driver for the generator.

32. The method of claim 23, wherein the automatic diagnosing includes diagnosing by a device mounted local to a bus supplying the operating voltage and operating current to the rotating machine.

33. The method of claim 23, wherein the method further comprises:
sending one or more signals by the device performing the automatic diagnosing, wherein the one or more signals indicate health of the rotating machine for presenting to a user or saving in a storage device.

34. The method of claim 23, comprising:
storing or presenting to a user an indication of health of the rotating machine by the device performing the automatic diagnosing.
